(19) United States
(12) Patent Application Publication
(10) Pub. No.: US 2026/0161208 A1
(43) Pub. Date: Jun. 11, 2026

(54) AC POWERED NANO-PROCESSOR

(71) Applicant: PI Invent Inc., Parker, TX (US)

(72) Inventors: Rashad Ramzan, Islamabad (PK); Haziq Rohail, Faisalabad (PK); Zahid Abbas, Sharjah (AE); Muddassar Farooq, Islamabad (PK); Azam Beg, Sacramento, CA (US); Kenneth Stanwood, Vista, CA (US)

(73) Assignee: PI Invent Inc., Parker, TX (US)

(21) Appl. No.: 18/972,911

(22) Filed: Dec. 7, 2024

(51) Int. Cl. G06F 1/26; H01F 29/02; H03K 17/687

(52) U.S. Cl. CPC G06F 1/26; H01F 29/02; H03K 17/6871

(57) ABSTRACT

An apparatus of an AC-powered nano-processor including AC-powered components in the data path. The AC-powered nano-processor comprising an IQ power supply including one or more pull-up networks having a plurality of quadrature phase signals, wherein a first quadrature phase signal of the plurality of quadrature phase signals is a power signal and a second quadrature phase signal of the plurality of quadrature phase signals is a gating signal; and an AC logic circuit coupled to the IQ power supply, wherein the AC logic circuit is powered by the IQ power supply. The AC logic circuit includes AC-powered logic gates such as AND, OR, NOT, NAND, NOR, XOR, AC-powered multiplexers, AC-powered demultiplexers, AC-powered ring oscillator, AC-powered register file, AC-powered arithmetic logic unit, AC-powered data memory, AC-powered instruction memory, and AC-powered program counter.

### TECHNICAL FIELD

At least one example generally relates to nano-processors, and more particularly to an ultra-low power multiphase AC-powered nano-processor, employing AC-powered logic circuitry, for low power IoT nodes and smart dust systems.

### BACKGROUND

Wirelessly powered microchips harvest RF signals from the environment to power internal circuitry. Traditional logic circuits require DC power, wherein microchips are configured to rectify the harvested RF signals using diode-based rectifiers. The rectified power is then used for operations such as computing and processing. However, the voltage supplied by these RF signals is typically so low that it may not power up processors. Furthermore, diode rectifiers, which convert AC to DC power, exhibit high impedance at lower voltages, resulting in significantly reduced conversion efficiency. Therefore, rectifiers in the data path are a significant bottleneck for designing energy efficient Internet of Things (IoT) sensors, processors, and associated circuitries, especially in operating environments where AC/RF signals need to be harvested from the ambient environment.

The background description provided here is for the purpose of generally presenting the context of the disclosure. Unless otherwise indicated here, the material described in this section is not prior art to the claims in this application and is not admitted to be prior art by inclusion in this section.

### BRIEF DESCRIPTION OF THE DRAWINGS

At least one embodiment may be understood more fully from detailed description given below and from accompanying drawings, which, however, should not be taken to be limiting, but are for explanation and understanding. In this disclosure the terms “AC-powered nano-processor,” “AC nano-processor,” “AC processor,” “AC-powered processor,” and “nano-processor” are interchangeably used, and all refer to the disclosed AC-powered nano-processor. Similarly, AC-powered X and AC X are also interchangeably used where X is a component that is powered by the AC.

FIG. 1A is a schematic that illustrates a wireless power transfer from an IQ transmitter to an IQ power supply, which uses 90-degree out-of-phase quadrature signals—VI+, VI−, VQ+, and VQ−—to power an AC logic circuit, in accordance with at least one example.

FIG. 1B is a block diagram of an IQ power supply that powers a pull up network to form an IQ power port, in accordance with at least one example.

FIG. 1C is a plot illustrating different phases of 90-degree out-of-phase quadrature signals that power various AC circuits of an AC-powered nano-processor of FIG. 1A, in accordance with at least one example.

FIG. 1D is a block diagram of an IQ power supply that powers an AC-powered nano-processor, in accordance with at least one example.

FIG. 1E is a block diagram of various examples of an AC-powered logic circuit, in accordance with at least one example.

FIG. 2A is a block diagram of an IQ power supply that powers an AC-powered nano-processor, a ring oscillator generating a clock signal for the AC-powered nano-processor, and a plurality of sensors, in accordance with at least one example.

FIG. 2B is a circuit of wireless power transfer, and data transmitting and receiving blocks using backscattering, in accordance with at least one example.

FIG. 2C is a schematic that illustrates an example IQ power port that uses three quadrature phase signals to power AC logic circuits, in accordance with at least one example.

FIG. 2D is a schematic that illustrates an example IQ power port that uses two quadrature phase signals to power AC logic circuits, in accordance with at least one example.

FIG. 3A and FIG. 3B illustrate symbols of different circuitries used in an AC-powered nano-processor, in accordance with at least one example.

FIG. 3C is a schematic of an IQ power scheme comprising a pull-up network to power a NOT gate, in accordance with at least one example.

FIG. 4 is a plot illustrating noise margin of AC logic gates of an AC-powered nano-processor, in accordance with at least one example.

FIG. 5 is a circuit of an AC-powered MUX, in accordance with at least one example.

FIG. 6 is a plot of an output of the AC-powered MUX of FIG. 5, in accordance with at least one example.

FIG. 7 is a circuit of an AC-powered DEMUX, in accordance with at least one example.

FIG. 8 is a plot of an output of the AC-powered DEMUX of FIG. 7, in accordance with at least one example.

FIG. 9 is a circuit of an AC-powered ring oscillator that is used to generate a master clock for an AC-powered nano-processor, in accordance with at least one example.

FIG. 10 is a plot of outputs of the AC-powered ring oscillator circuit of FIG. 9, in accordance with at least one example.

FIG. 11 is a circuit of a program counter that addresses a data path of an AC-powered nano-processor by executing instructions, in accordance with at least one example.

FIG. 12 is a plot of an output of the program counter of FIG. 11, in accordance with at least one example.

FIG. 13 is a circuit of an AC-powered full adder, in accordance with at least one example.

FIG. 14 is a plot of an output of the AC-powered full adder of FIG. 13, in accordance with at least one example.

FIG. 15 is a circuit of an AC-powered 4-bit adder/subtractor that is used to add or subtract signals depending on an add/sub signal, in accordance with at least one example.

FIG. 16 is a plot of an output of the AC-powered 4-bit adder/subtractor of FIG. 15, in accordance with at least one example.

FIG. 17 is a circuit of a branch controller that is used for instruction jumping in a data path of an AC-powered nano-processor, in accordance with at least one example.

FIG. 18 is a schematic of an AC-powered arithmetic-logic unit (ALU), in accordance with at least one example.

FIG. 19 is a plot of an output of the AC-powered ALU of FIG. 18, in accordance with at least one example.

FIG. 20A is a circuit of an AC-powered memory that can store instructions for an AC-powered nano-processor, in accordance with at least one example.

FIG. 20B is a schematic of a memory instance illustrating programmed instruction bits, in accordance with at least one example.

FIG. 21 is a plot of an output of the AC-powered memory of FIG. 20A, in accordance with at least one example.

FIG. 22 is a circuit of an example structure of an AC-powered memory that can store instructions for an AC-powered nano-processor, in accordance with at least one example.

FIG. 23 is a circuit of an AC-powered memory based on static random-access memory (SRAM) architecture, in accordance with at least one example.

FIG. 24 is a circuit of an AC-powered SRAM inverter that may be used as a storage cell in the AC-powered memory of FIG. 23, in accordance with at least one example.

FIG. 25 is a plot of an output of the AC-powered memory of FIG. 23, in accordance with at least one example.

FIG. 26 is a block diagram of an AC-powered register file that is used in an AC-powered nano-processor, in accordance with at least one example.

FIG. 27 is a circuit of an AC-powered register file that is used in an AC-powered nano-processor, in accordance with at least one example.

FIG. 28 is a circuit of an AC-powered operation selector of FIG. 27, in accordance with at least one example.

FIG. 29 is a plot of an output of the AC-powered operation selector of FIG. 28, in accordance with at least one example.

FIG. 30 is a plot of a writing operation executed in the AC-powered register file of FIG. 27, in accordance with at least one example.

FIG. 31 is a plot of a read operation executed by the AC-powered register file of FIG. 27, in accordance with at least one example.

FIG. 32 is a table of an instruction set that is used in a 4-bit AC nano-processor, in accordance with at least one example.

FIG. 33 is a table of sample instructions that are used to load data into registers and perform arithmetic operations using the instruction set of FIG. 32, in accordance with at least one example.

FIG. 34 is a method of loading and storing data in an AC-powered nano-processor, in accordance with at least one example.

FIG. 35 is a method of executing addition and subtraction operations in an AC-powered nano-processor, in accordance with at least one example.

FIG. 36 is a table of the control circuit that generates signals that correspond to specific tasks, in accordance with at least one example.

FIG. 37A is a circuit of a first half of a control circuit for an AC-powered nano-processor, in accordance with at least one example.

FIG. 37B is a circuit of a second half of the control circuit for an AC-powered nano-processor, in accordance with at least one example.

FIG. 38 is plot of an output of control circuits of FIG. 37A and FIG. 37B, in accordance with at least one example.

FIG. 39 is a block diagram of an AC-powered data path comprising AC-powered control blocks, comprising AC-powered memory blocks, and comprising AC-powered arithmetic-logic unit (ALU), in accordance with at least one example.

FIG. 40 is a circuit of an AC-powered data path for a first instruction of FIG. 33, in accordance with at least one example.

FIG. 41 is a plot of an output of the AC-powered data path of FIG. 40, in accordance with at least one example.

FIG. 42 is a circuit of an AC-powered data path for a second instruction of FIG. 33, in accordance with at least one example.

FIG. 43 is a plot of an output of the AC-powered data path of FIG. 42, in accordance with at least one example.

FIG. 44 is a circuit of an AC-powered data path for a third instruction of FIG. 33, in accordance with at least one example.

FIG. 45 is a plot of an output of the AC-powered data path of FIG. 44, in accordance with at least one example.

FIG. 46 is a circuit of an AC-powered data path for a fourth instruction of FIG. 33, in accordance with at least one example.

FIG. 47 is a plot of an output of the AC-powered data path of FIG. 46, in accordance with at least one example.

FIG. 48 is a circuit of an AC-powered data path for a fifth instruction of FIG. 33, in accordance with at least one example.

FIG. 49 is a plot of an output of the AC-powered data path of FIG. 48, in accordance with at least one example.

FIG. 50 is a circuit that illustrates an example structure of an AC-powered nano-processor, wherein a pull-up network is used with large transistors to power the data path of FIG. 39, in accordance with at least one example.

FIG. 51 is a schematic of an AC-powered full adder, wherein all logic gates of the AC-powered full adder of FIG. 13 share a single pull-up network, in accordance with at least one example.

FIG. 52 is a schematic of an AC-powered instruction memory circuit, wherein each bit line of instruction memory of FIG. 20A shares a single pull-up network, in accordance with at least one example.

FIG. 53 is a plot of a power consumption of the AC-powered nano-processor of FIG. 39, while executing the instruction set of FIG. 32, in accordance with at least one example.

FIG. 54 is a plot of a power consumption of the AC-powered nano-processor of FIG. 50, while executing the instruction set of FIG. 32, in accordance with at least one example.

FIG. 55 is a plot of a power consumption of an 8-bit AC-powered nano-processor while executing the instruction set of FIG. 32, in accordance with at least one example.

FIG. 56 is a circuit of a quadrature RF inverter circuit, in accordance with at least one example.

FIG. 57 is a plot of the output of the quadrature RF inverter circuit of FIG. 56, in accordance with at least one example.

FIG. 58 is a circuit of an example structure of a quadrature RF inverter circuit, in accordance with at least one example.

FIG. 59 is a plot of the output of the quadrature RF inverter circuit of FIG. 58, in accordance with at least one example.

FIG. 60 is a circuit of a 180° AC-powered RF inverter circuit, in accordance with at least one example.

FIG. 61 is a plot of the output of the AC-powered RF inverter circuit of FIG. 60, in accordance with at least one example.

FIG. 62 is a circuit of a quadrature RF NAND gate, in accordance with at least one example.

FIG. 63 is a plot of the output of the quadrature RF NAND gate of FIG. 62, in accordance with at least one example.

FIG. 64 is a circuit of an example structure of a quadrature RF NAND gate, in accordance with at least one example.

FIG. 65 is a plot of the output of the quadrature RF NAND gate of FIG. 64, in accordance with at least one example.

FIG. 66 is a circuit of a 180° AC-powered RF NAND gate, in accordance with at least one example.

FIG. 67 is a plot of the output of the AC-powered RF NAND gate of FIG. 66, in accordance with at least one example.

FIG. 68 is a circuit of a quadrature RF NOR gate, in accordance with at least one example.

FIG. 69 is a plot of the output of the quadrature RF NOR gate of FIG. 68, in accordance with at least one example.

FIG. 70 is a circuit of an example structure of a quadrature RF NOR gate, in accordance with at least one example.

FIG. 71 is a plot of the output of the quadrature RF NOR gate of FIG. 70, in accordance with at least one example.

FIG. 72 is a circuit of a 180° AC-powered RF NOR gate, in accordance with at least one example.

FIG. 73 is a plot of the output of the AC-powered RF NOR gate of FIG. 72, in accordance with at least one example.

FIG. 74 is a circuit of a quadrature RF D Flip Flop, in accordance with at least one example.

FIG. 75 is a plot of the output of the quadrature RF D Flip Flop of FIG. 74, in accordance with at least one example.

FIG. 76 is a circuit of an example structure of a quadrature RF D Flip Flop, in accordance with at least one example.

FIG. 77 is a plot of the output of the quadrature RF D Flip Flop of FIG. 76, in accordance with at least one example.

FIG. 78 is a circuit of a 180° AC-powered RF D Flip Flop, in accordance with at least one example.

FIG. 79 is a plot of the output of the AC-powered RF D Flip Flop of FIG. 78, in accordance with at least one example.

FIG. 80 is a circuit of a quadrature RF XOR gate, in accordance with at least one example.

FIG. 81 is a plot of the output of the quadrature RF XOR gate of FIG. 80, in accordance with at least one example.

FIG. 82 is a circuit of an example structure of a quadrature RF XOR gate, wherein XOR logic is implemented using signals IN1_XOR, IN2_XOR, and their inverted counterparts IN1_XOR′ and IN2_XOR′, in accordance with at least one example.

FIG. 83 is a plot of the output of the quadrature RF XOR gate of FIG. 82, in accordance with at least one example.

FIG. 84 is a circuit of a 180° AC-powered RF XOR circuit, in accordance with at least one example.

FIG. 85 is a plot of the output of the 180° AC-powered RF XOR circuit of FIG. 84, in accordance with at least one example.

FIG. 86 is a circuit of an example structure of a quadrature RF XOR gate, wherein XOR logic is implemented using signals IN1_XOR and IN2_XOR, in accordance with at least one example.

FIG. 87 is a plot of the output of the quadrature RF XOR gate of FIG. 86, in accordance with at least one example.

FIG. 88 is a circuit of an example structure of a quadrature RF XOR gate, wherein XOR logic is implemented using signals IN1_XOR and IN2_XOR, in accordance with at least one example.

FIG. 89 is a plot of the output of the quadrature RF XOR gate of FIG. 88, in accordance with at least one example.

FIG. 90 is a circuit of an example structure of a 180° AC-powered RF XOR gate, in accordance with at least one example.

FIG. 91 is a plot of the output of the 180° AC-powered RF XOR gate of FIG. 90, in accordance with at least one example.

FIG. 92 is a schematic that illustrates an application use case of an AC-powered nano-processor in biomedical applications, in accordance with at least one example.

FIG. 93 is a schematic that illustrates a wireless power transfer link between a transmitter and a receiver for biomedical applications, in accordance with at least one example.

FIG. 94 is a schematic that illustrates an application use case that illustrates a use of an AC-powered nano-processor in the civil and/or construction industry, in accordance with at least one example.

### GLOSSARY OF SYMBOLS

| | |
|---|---|
| IoT | Internet of Things |
| RF | Radio Frequency |
| AC | Alternating Current |
| DC | Direct Current |
| WPT | Wireless Power Transfer |
| RWPT | Resonant Wireless Power Transfer |
| IQ | In-Phase/Quadrature-Phase |
| MUX | Multiplexer |
| DEMUX | Demultiplexer |
| ALU | Arithmetic Logic Unit |
| SRAM | Static Random-Access Memory |
| VI+ | In-phase Voltage Signal |
| VI− | Inverted In-phase Voltage Signal |
| VQ+ | Quadrature-phase Voltage Signal |
| VI− | Inverted Quadrature-phase Voltage Signal |
| PTBR | Power Transferring and Backscattering Data Receiving |
| PRBT | Power Receiving and Backscattering Data Transferring |
| V_{IH} | Input high voltage range |
| V_{IL} | Input low voltage range |
| V_{OH} | Output high voltage range |
| V_{OL} | Output low voltage range |
| NM_{H} | High voltage noise margin |
| NM_{L} | Low voltage noise margin |
| ISA | Instruction Set Architecture |
| PC | Program Counter |
| CLK | Clock Signal |
| CPN | Common Pull-up Network |

### DETAILED DESCRIPTION

Some examples relate to an apparatus comprising an AC-powered nano-processor and its associated data path circuits that may be used for edge internet of things (IoT) nodes, biomedical implants, smart dust systems, and various other low-power, intelligent sensing applications. The disclosed nano-processor is a low-power electronics device that can directly utilize AC power, eliminating conventional AC-to-DC power rectification circuits. This AC-powered design allows for a significant reduction in the size and complexity of an electronic or computing device or system, providing a more efficient and scalable approach to power management and signal processing in miniaturized systems, as sensors, processors, and associated circuitry may operate directly on the AC/RF signals that may be harvested from an ambient environment.

An AC nano-processor in this disclosure may comprise an IQ power supply that generates quadrature phase signals, which are used to directly power the AC logic circuits that may form the core of processing and compute unit of the system. The IQ power supply may include pull-up networks that operate on multiple quadrature phase signals, where one signal may function as a power signal and another signal may act as the gating signal. These quadrature signals are generated from interactions between power receiving and backscattering data transfer circuits (PRBT circuits), which may capture wireless IQ voltage signals from external devices. This may allow for seamless energy harvesting from RF sources without using complex power rectification circuitries. The power supply and logic circuit can be designed to ensure that the system can be highly efficient in both power consumption and compute operations, which may support the applications that may use ultra-low-power for their operations.

The AC logic circuit may include several AC-powered components, such as multiplexers, demultiplexers, adders, inverters, oscillators, and an arithmetic logic unit (ALU). Each component is designed to function directly on an AC power, hence associated signals may be processed and controlled using AC-powered logic gates, including AC-powered NAND, XOR, AND, OR, and NOR gates. The AC multiplexing circuits may manage data flow between various components, which may enable flexible operations using incoming select signals. Similarly, AC ring oscillators can generate clock signals to enable synchronous operations in an AC-powered nano-processor. Using operations of AC-powered components, an AC-powered nano-processor may operate efficiently with optimum power in a frequency band of varying input signal frequencies, which may make an AC nano-processor suitable for a broad range of dynamic environments.

In this disclosure, an AC-powered nano-processor may address various limitations of conventional DC-powered processors, particularly in the context of IoT sensor devices, smart dust devices, and biomedical implants etc., that may have limited supply of power. Conventional DC-powered processors may utilize large and complex rectification circuits to convert incoming AC or RF power into a usable DC power. The conversion circuits may add complexity to a processor architecture that may increase its power losses and also put limitations on its size. By eliminating the need for AC-to-DC rectification, a power-efficient AC-powered nano-processor may significantly reduce its overall carbon footprint, allowing for higher integration densities, which may enable building green electronic devices. Its advantage can be particularly useful in miniaturized applications, such as smart dust systems, where sensors and associated electronics need to be packaged in a small space, and they should consume low-power for a long operational life.

An AC-powered nano-processor may further reduce its power consumption by using its backscattering data communication system for communications. Data in an AC-powered nano-processor may be transferred by modulating the impedance of a nano-processor's components, enabling the wireless transmission of data without the need for physical pins, IO buffers, or bond wires. Consequently, the need for complex pin-based manufacturing processes for complex packaging and bonding, used in classical chips, is also eliminated. Consequently, AC-powered nano-processors, having no packaging and pins, may be mass produced at a significantly less cost because of simple and efficient manufacturing processes.

Smart dust systems, which may use ultra-small, autonomous sensors, can benefit from the small size of an AC-powered nano-processor that has no pins. An AC-powered nano-processor may operate continuously, using its self-sustaining power supply by harvesting RF energy, from its ambient environment, eliminating the need for large batteries. The features of a nano-processor may make them suitable for a large scale deployment in environmental sensing, monitoring, and industrial control applications. Moreover, the features may also be particularly useful in biomedical implants, which do monitoring of patients' vitals and run early diagnostic methods on them. The biomedical implants are expected to generate less heat and consume less power consumption that may reduce hazardous effects on patients' bodies hence enhancing patients' safety. Moreover, the implants may not need to be removed just to replace batteries, as AC-power nano-processor biomedical implants do not have batteries.

An AC logic circuit may also enable a modular and scalable architecture. Each component, from an arithmetic logic unit to program counters and multiplexers, is powered by separate pull-up networks of an IQ power supply known as IQ power port, enabling fine-grained control over the power distribution in the processor. This modular architecture of an AC-powered nano-processor may result in easy adaption of a nano-processor in different resource constrained applications. For example, in applications that may use higher computational resources, additional AC inverters and oscillators can be added to enhance clock speeds to increase throughput of computational workloads. In comparison for low-power applications, certain components can be disabled or scaled down to conserve and save power.

Furthermore, an AC-powered nano-processor may use an AC-powered arithmetic logic unit (ALU), which can perform desired arithmetic and logical operations such as addition, subtraction, logical AND, OR, XOR, etc. An ac ALU operates on quadrature phase signals, receiving two inputs and performing computations using AC NAND gates and XOR circuits. An ALU can be configured for various bit-width operations, which may enable it to perform simple and complex calculations. An AC program counter, AC memory circuits, and an AC control unit complement the ALU and may provide an AC-powered nano-processor with control logic circuits and memory management operations to execute instructions on data storage.

Some examples disclose an AC-powered nano-processor that is designed for energy-efficient, low-power applications. An AC-powered nano-processor operates using an AC logic in which quadrature phase signals may be captured by inductors and can be used to power components such as AC multiplexers (MUXes), AC demultiplexers (DEMUXes), and AC ring oscillators. These AC components may select signals and route them and generate clock for enabling synchronized operations across the data path of an AC-powered nano-processor.

In at least one example, the AC-powered nano-processor may include an AC-powered memory system comprising both instruction and data memory. AC-powered memory circuits, based on static random-access memory (SRAM) cells, may be programmed to store instructions and data that is needed for executing arithmetic and logic operations. An AC control unit may generate specific signals to manage tasks like data loading, storing, and branching. By efficiently utilizing AC logic, an AC memory system may minimize power consumption while reliably running computational workloads.

In at least one example, a data path of an AC-powered nano-processor, which is configured to process instructions, interacts with various AC-powered components to execute instructions. Integration of AC-powered circuits throughout the data path, control unit, and memory system may result in a power-efficient execution of instructions.

In the following description, numerous details are provided about different examples of an AC-powered nano-processor and its various submodules. It will be apparent, however, to one skilled in the art, that the examples of the present disclosure may be practiced without these specific details. In other instances, well-known structures and devices are shown in a block diagram form, rather than in detail, to avoid obscuring examples of the present disclosure.

Note that in the corresponding drawings of the examples, curves are represented with lines. Some lines may be thicker or dashed to differentiate between them. Such indications are not intended to be limiting. Rather, the lines are used in connection with one or more examples to facilitate easier understanding of a plot.

It is pointed out that those elements of the figures having the same reference numbers (or names) as the elements of any other figure can operate or function in any manner like that described but are not limited to such.

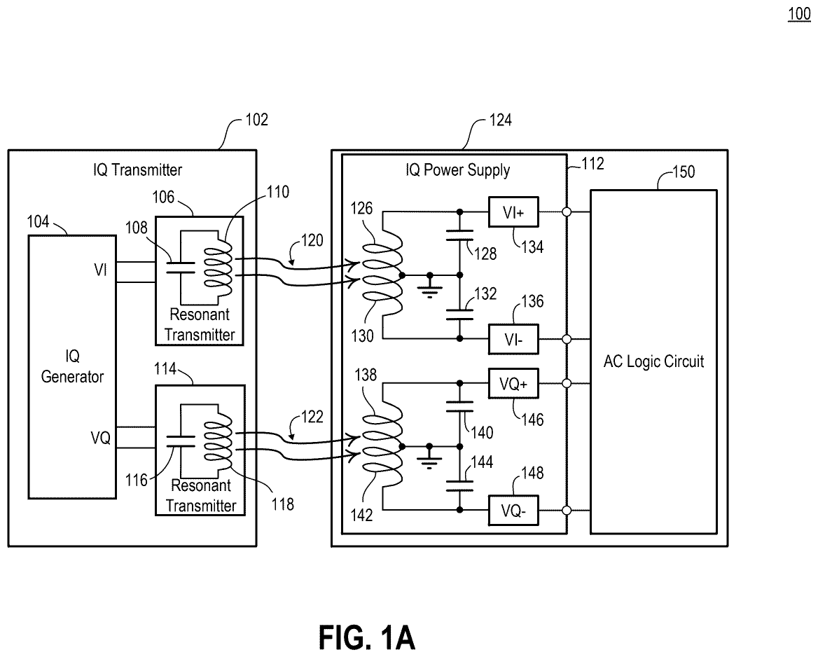

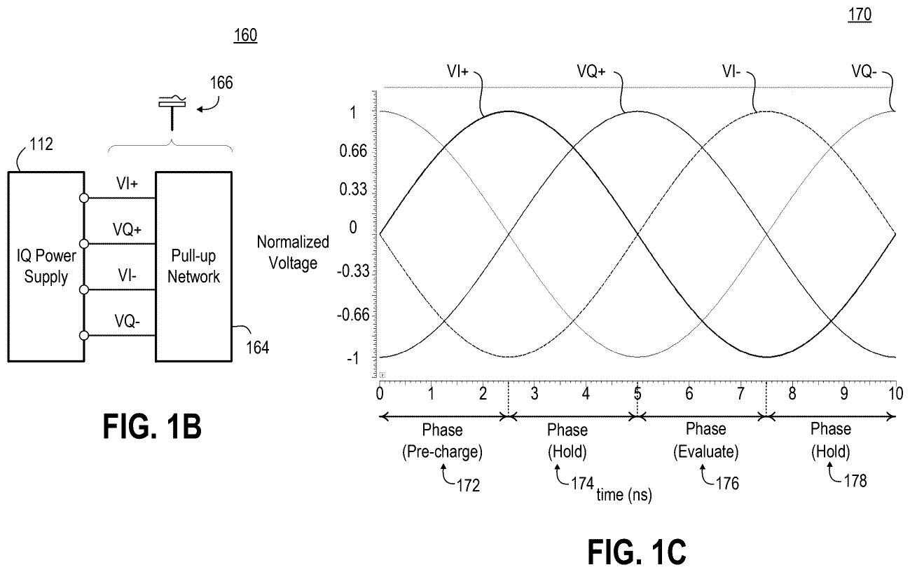

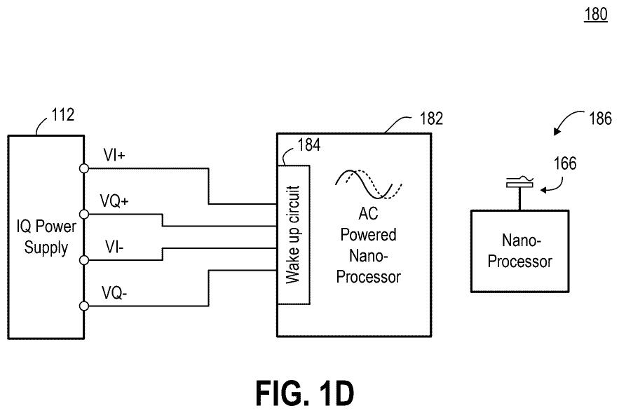

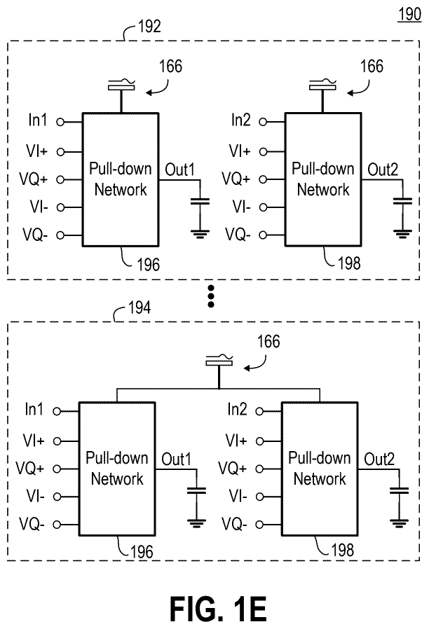

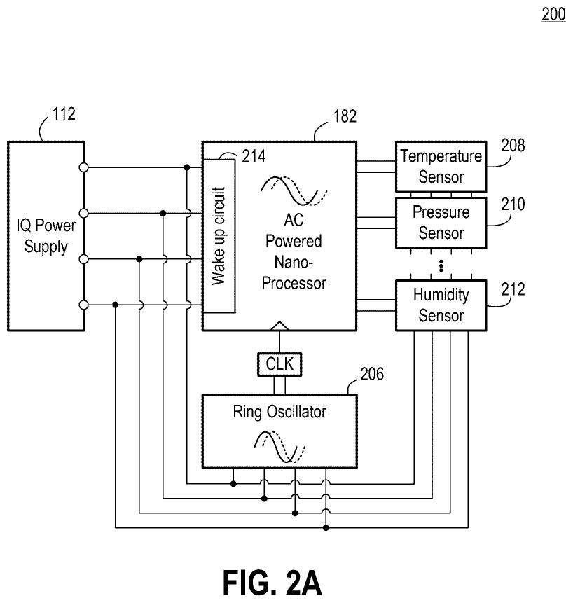

FIG. 1A is a schematic 100 illustrating wireless power transfer from an IQ transmitter 102 to an IQ power supply 112. IQ power supply 112 receives quadrature (IQ) power from IQ transmitter 102 comprising IQ generator 104 and resonant transmitters 106 and 114, which include inductors 110 and 118 and capacitors 108 and 116. Quadrature signals 120 and 122, generated by IQ generator 104, are transmitted by resonant transmitters 106 and 114 using resonant wireless power transfer (RWPT), and are received by IQ power supply 112. IQ power supply 112, which include on-chip inductors 126, 130, 138, and 142 and capacitors 128, 132, 140, and 144, may generate 90-degree out-of-phase quadrature signals—VI+ 134, VI− 136, VQ+ 146, and VQ− 148—for AC logic circuit 150 of smart dust node 124. In at least one example, inductor 142 and capacitor 144 may be omitted, generating three signals: VI+ 134, VI− 136, and VQ+ 146.

FIG. 1B is a block diagram 160 of an IQ power supply 112 that may power a pull-up network 164 to form an IQ power port 166, in accordance with at least one example. IQ power supply 112 may generate four signals—VI+ 134, VI− 136, VQ+ 146, and VQ− 148—as illustrated in FIG. 1A. Block diagram 160 illustrates that at least two signals of four signals VI+ 134, VI− 136, VQ+ 146, and VQ− 148 may power any AC-powered circuitry, such as pull-up network 164. In at least one example, IQ power supply 112 coupled with pull-up network 164 may form a power source for an individual or multiple logic gate circuits, which may be called IQ power port 166. In at least one example, a pull-down circuit may also be powered by four quadrature phase signals VI+ 134, VI− 136, VQ+ 146, and VQ− 148. In at least one example, IQ power port 166 may be a pull-up network 164, which may be receiving power by two, three, or four AC signals from IQ power supply 112 and then supplying AC power to various AC logic circuits using two, three, or four AC signals, respectively.

FIG. 1C is a plot 170 of IQ signals VI+ 134, VI− 136, VQ+ 146, and VQ− 148 that may power an AC-powered nano-processor 182, in accordance with at least one example. Signal VQ+ 146 is 90° out of phase from VI+ 134, hence referred to as a quadrature signal, while signal VI− 136 is 180° out of phase from VI+ 134, and signal VQ− 148 is 270° out of phase from VI+ 134. These signals may divide a complete clock cycle of 360° into four distinct phases 172, 174, 176, and 178. An individual phase of these phases may be separated by its predecessor and successor phase by a phase of 90°. A Quadrature-phase technique may allow an AC nano-processor 182 to draw AC power in different phases depending on differences in voltage between AC signals—VI+ 134, VI− 136, VQ+ 146, and VQ− 148. In at least one example, when VI+ 134 may be higher than VQ+ 146 during phase 172, an AC nano-processor 182 may draw power from VI+ 134 to supply it to its various AC circuits, and during phase 174, a voltage value of VQ+ 146 may exceed that of VI− 136, and nano-processor 182 may draw power from VQ+ 146. Hence, alternating phases may provide uninterrupted AC power supply across a complete clock cycle, improving efficiency of AC-powered nano-processor 182 and other AC components. This approach may also enable reliable powering of AC circuits using low-energy RF sources, minimizing interruptions due to signal phase imbalances, and maximizing power transfer efficiency. In at least one example, a first phase is a pre-charge phase 172, a second phase is a hold phase 174, a third phase is an evaluate phase 176, and a fourth phase is another hold phase 178. Different transistors may operate in different phases to perform their respective logic operations. In at least one example, a pull-up network 164 of an IQ power port 166 may be supplied with two, three, or four signals of quadrature signals VI+ 134, VI− 136, VQ+ 146, and VQ− 148 from an IQ power supply 112. IQ power supply 112 coupled with a pull-up network 164 may form an IQ power port 166 that may power various AC powered circuits.

FIG. 1D is a block diagram 180 of an IQ power supply 112 that may power an AC-powered nano-processor 182 using an internal wake-up circuit 184, in accordance with at least one example. Wake-up circuit 184 may help in conserving power, as nano-processor 182 may be powered on when specific conditions are met, such as a sufficient power level or the presence of a triggering signal. IQ power supply 112 may generate four quadrature signals—VI+ 134, VI− 136, VQ+ 146, and VQ− 148—as illustrated in FIG. 1A, which may be used by wake-up circuit 184 to provide AC power to AC-powered nano-processor 182. In at least one example, wake-up circuit 184 may utilize a threshold detection circuit to avoid accidental activation of nano-processor 182, ensuring reliable and efficient operations in low-power IoT/smart dust edge nodes. In at least one example, AC powered nano-processor 186 may be powered by an IQ power port 166.

FIG. 1E is a schematic 190 that illustrates various examples AC logic circuits 192 and 194, in accordance with at least one example. In at least one example, AC logic circuit 192 may include two gate circuits with pull-down networks 196 and 198, where a separate port for IQ power port 166 may individually power pull-down networks 196 and 198. In at least one example, AC logic circuit 194 may include two circuits with pull-down networks 196 and 198, where an IQ power port 166 may power both of pull-down networks 196 and 198. In at least one example, IQ power port 166 may also power any AC logic circuit configured as an AND, OR, NOR, XOR, NAND, or any other logic circuit including an AC-powered processor, highlighting that IQ power port 166 may be dynamically configured to power various types of AC logic circuits. In at least one example, IQ power port 166 may power two or more AC logic gates.

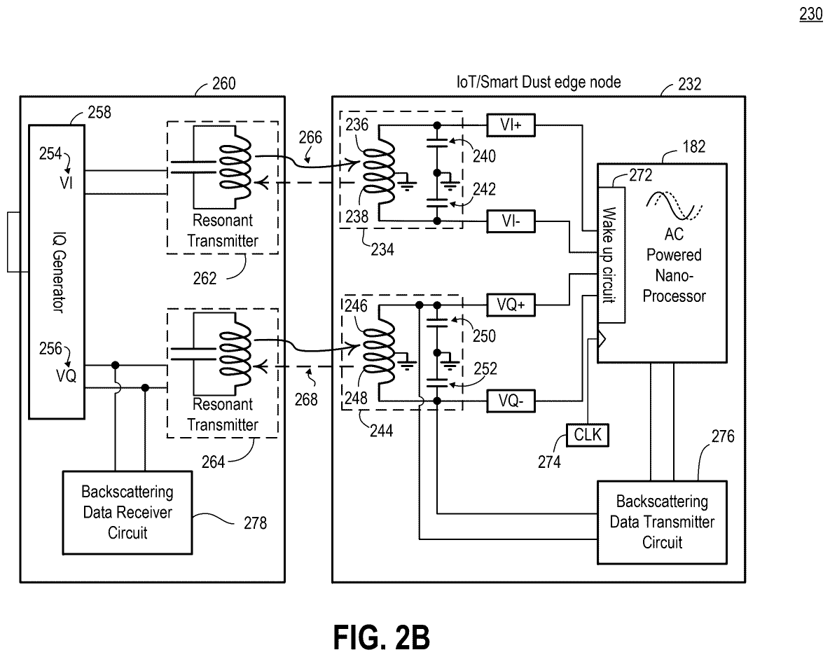

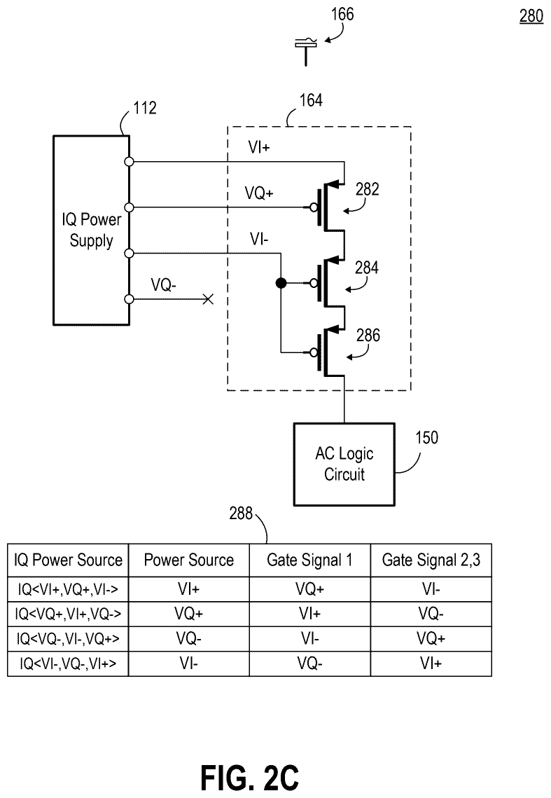

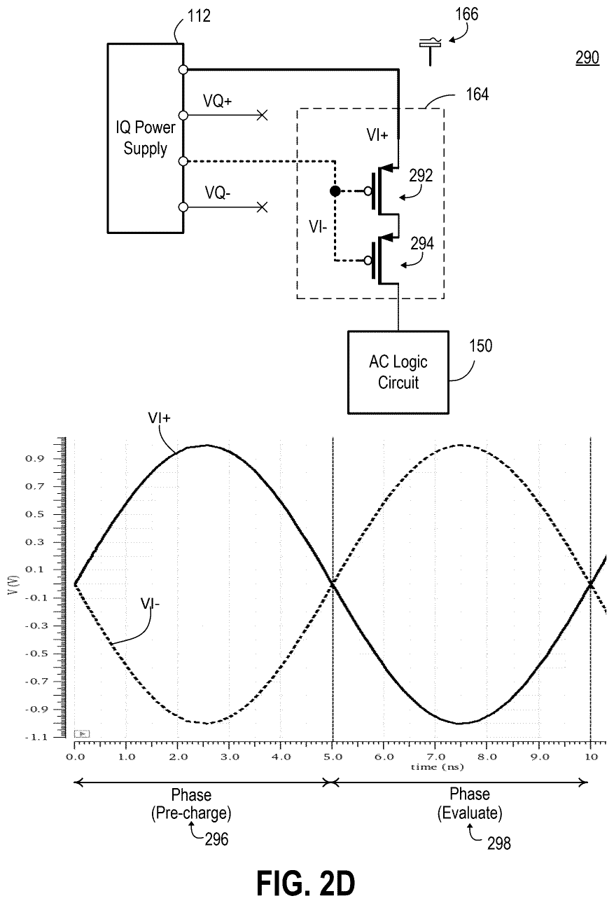

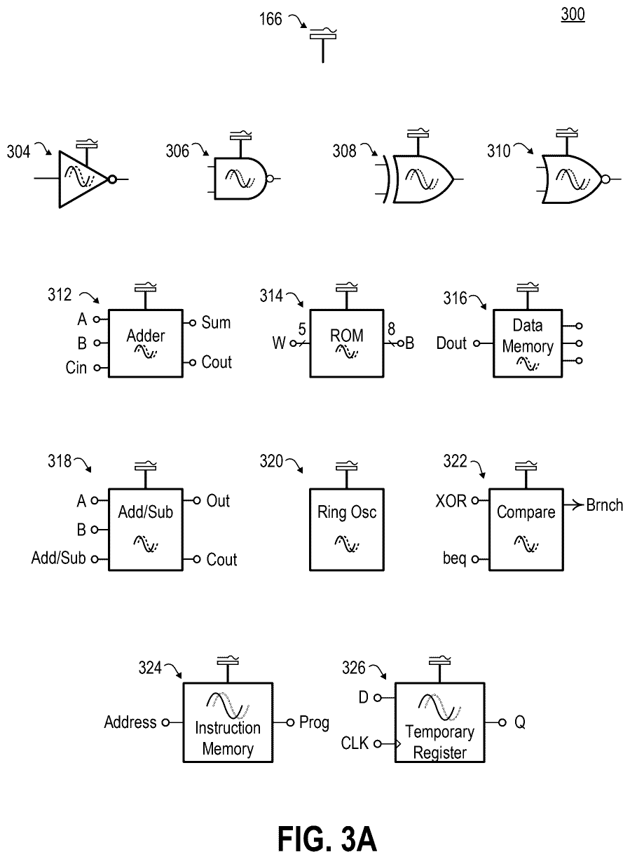

FIG. 2A is a schematic of a block diagram 200 of an IQ power supply 112, which generates signals VI+ 134, VI− 136, VQ+ 146, and VQ− 148 to power an AC-powered nano-processor 182, in accordance with at least one example. AC signals—VI+ 134, VI− 136, VQ+ 146, and VQ− 148—from IQ power supply 112 may eliminate the need for AC to DC conversion. A wake-up circuit 214 may also be integrated in AC-powered nano-processor 182, enabling a selective activation of AC-powered nano-processor 182 and the sensors—temperature sensor 208, pressure sensor 210, and humidity sensor 212—based on predefined trigger conditions, optimizing power efficiency. A ring oscillator 206 may generate a clock signal for AC-powered nano-processor 182, providing a stable and consistent timing reference that is used for synchronous processing. Block diagram 200 illustrates a plurality of sensors—temperature sensor 208, pressure sensor 210, and humidity sensor 212—configured to monitor specific environmental parameters, enabling real-time data acquisition for enhanced responsiveness and adaptability of a system. Integration of these sensors—temperature sensor 208, pressure sensor 210, and humidity sensor 212—may facilitate the gathering of critical information for informed decision-making and control processes within a system, in accordance with at least one example. In at least one example, AC signals—VI+ 134, VI− 136, VQ+ 146, and VQ− 148—from IQ power supply 112 may also power ring oscillator 206 and sensors 208, 210, and 212.

FIG. 2B is a schematic illustrating circuit 230 of wireless power transfer and data transmitting and receiving blocks that may use backscattering to transmit or receive data to or from an IoT/smart dust edge node 232, in accordance with at least one example. Edge node 232 may use RF/AC signals to power its internal circuits. Circuit 230 illustrates two on-chip resonant wireless power receiving and backscattering data transferring (PRBT) circuits: (1) PRBT circuit 234 comprising inductors 236 and 238 and capacitors 240 and 242, and (2) PRBT circuit 244 comprising inductors 246 and 248 and capacitors 250 and 252. PRBT circuits 234 and 244 receive RF/AC signals VI 254 and VQ 256, generated by an IQ generator 258 in an external circuit 260, and transmitted by resonant wireless PTBR circuits 262 and 264 through WPT and backscattering links 266 and 268, respectively. Signals VI 254 and VQ 256 are received by PRBT circuits 262 and 264 to generate 90-degree out-of-phase quadrature signals VI+ 134, VI− 136, VQ+ 146, and VQ− 148, which are used to provide AC power to an AC-powered nano-processor 182. In at least one example, signals VI+ 134, VI− 136, VQ+ 146, and VQ− 148 pass through a wakeup circuit 272 before powering the internal circuits of edge node 232. In at least one example, wakeup circuit 272 may ensure that AC-powered nano-processor 182 is not active at lower power levels. A clock circuit 274 generates a master clock signal for AC-powered nano-processor 182. AC-powered nano-processor 182 processes data or executes specified computational tasks and returns the results via a backscattering data transmitter 276 by changing an impedance of PRBT circuit 244. This change in impedance is reflected at resonant transmitter of PRBT circuit 264 and is detected by a backscattering data receiver 278. In at least one example, backscattering data communication is done by changing an impedance of PRBT circuit 234 instead of PRBT circuit 244. In at least one example, data transfer rate may be increased by using both PRBT circuits 234 and 244 simultaneously. Unless explicitly specified otherwise, in the remaining part of disclosure, all AC logic circuits including nano-processor, may be considered using 4 bit-width components e.g., all inputs and outputs are 4-bits. Similarly, registers and memories may store 4 bits.

FIG. 2C is a schematic 280 illustrating an example of an IQ power port 166 that may use three quadrature phase signals VI+ 134, VI− 136, and VQ+ 146, in accordance with at least one example. Pull-up network 164 is at least one example in which an IQ power supply 112 may be coupled with transistors 282, 284, and 286 to form IQ power port 166 that may supply AC power to AC logic circuit 150. IQ<VI+, VQ+, VI−> notation from table 288 highlights a relationship between different phases of IQ signals, and power distribution across pull-up network 164, ensuring reliable delivery of AC power to AC logic gates at an individual stage of an AC logic circuit 150. Pull-up network 164 may include transistors 282, 284, and 286, which are configured to draw power from signal VI+ 134 during phase 172 of FIG. 1C. Transistors 282, 284, and 286 may be controlled by signals VQ+ 146 and VI− 136 that may be applied to their respective gate terminals, wherein gate signals may consume small amounts of power. Most of AC power is sourced from a drain of transistor 282, which may be connected to VI+ 134. This configuration efficiently utilizes energy that may be available from RF signals to power various AC logic gates.

In at least one example, IQ logic may comprise four distinct phases: VI+ 134, VI− 136, VQ+ 146, and VQ− 148, which may be used to power AC logic gates. In a typical sequential or combinational IQ logic circuit, one power signal and two gating signals may be needed as illustrated in FIG. 2C. To ensure an even distribution of power across different phases, AC powered components of a complex AC circuit (e.g., an AC nano-processor), may be powered using different IQ phases. In at least one example, an AC logic gate might be powered by a signal scheme named IQ<VQ+, VI+, VQ−>, which may draw power from VQ+146 instead of VI+ 134, while VI+ 134 and VQ− 148 may act as gating signals. Similarly, additional power schemes may use phases VI− 136 and VQ− 148 to provide a balanced distribution of AC power. In at least one example, a set of four power schemes may use different IQ power and gating phases as is summarized in table 288. These schemes may be designed to ensure that an individual IQ phase line can be equally loaded, which may help in a uniform distribution of AC power load across IQ coils in PRBT circuits 234 and 244, respectively. IQ power port 166 may indicate a pull-up network configuration, which may vary in terms of transistors' count, complexity, size, and power requirements depending on specifications of an application.

FIG. 2D is a schematic 290 illustrating an example of an IQ power port 166 that may use two quadrature phase signals, in accordance with at least one example. Pull-up network 164 may include two transistors and two 180° out of phase signals to power AC logic circuit 150, in accordance with at least one example. In at least one example, the phase plot illustrates that signals VI+ 134 and VI− 136 may be used to power different AC circuits of an AC-powered nano-processor 182. Signal VI− 136 is 180° out of phase from VI+ 134. Unlike signals in FIG. 1C, a complete signal cycle in FIG. 2D may be divided into two phases 296 and 298. A first phase is a pre-charge phase 296; while a second phase is an evaluate phase 298. A basic operating principle of AC circuits of an AC-powered nano-processor 182 is using an 180° out-of-phase logic. In at least one example, VQ+ 146 and VQ− 148 may be used instead of VI+ 134 and VI− 136, since VQ+ 146 and VQ− 148 are also 180° out of phase signals. In at least one example, pull-up network 164 may be supplied with signals VI+ 134 and VI− 136, to comprise IQ power port 166. Like schematic 280, transistors 292 and 294 may use signal VI− 136 as a gating signal and signal VI+ 134 may be a drain signal for transistor 292.

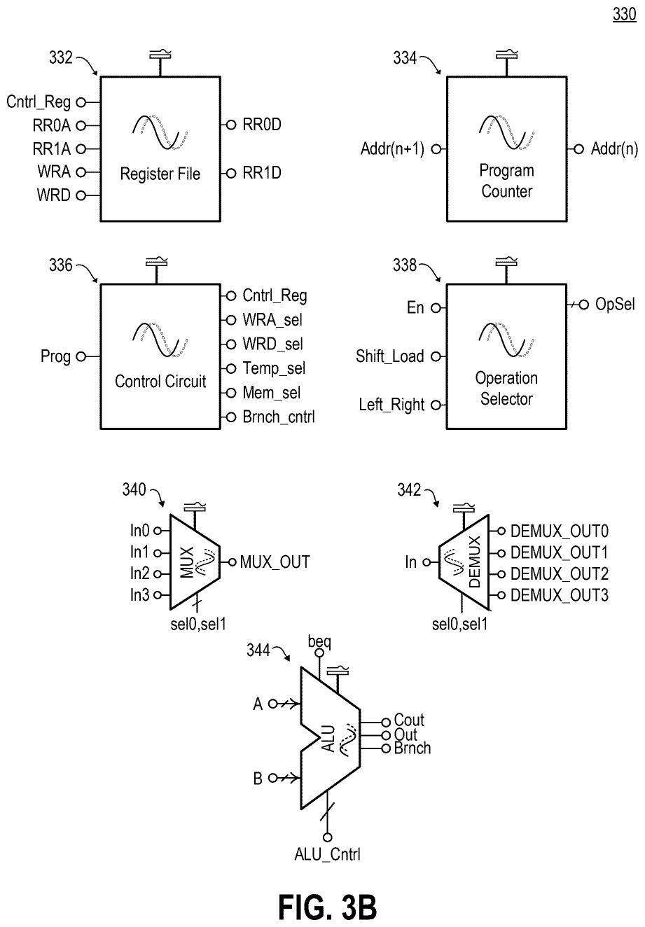

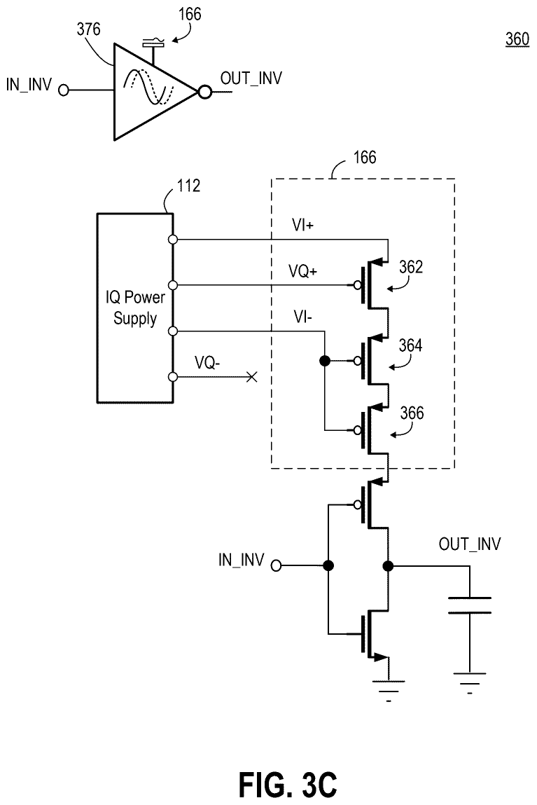

FIG. 3A is a schematic 300 illustrating different symbols used for circuit blocks of an AC-powered nano-processor, in accordance with at least one example. The symbol for IQ power port 166 represents an IQ power supply coupled with a pull-up network, symbol 304 represents a logical NOT gate, symbol 306 represents a logical NAND gate, symbol 308 represents a logical XOR gate, symbol 310 represents a logical NOR gate, symbol 312 represents an AC-powered adder circuit, symbol 314 represents an AC-powered ROM, symbol 316 represents an AC-powered data memory, symbol 318 represents an AC-powered adder or subtractor circuit, symbol 320 represents an AC-powered ring oscillator, symbol 322 represents an AC-powered comparator, symbol 324 represents an AC-powered instruction memory to be used in an AC-powered nano-processor, and symbol 326 represents an AC-powered temporary register, in accordance with at least one example.

FIG. 3B is a schematic 330 that illustrates symbols used for circuit blocks of an AC-powered nano-processor, in accordance with at least one example. Symbol 332 represents an AC-powered register file, symbol 334 represents an AC-powered program counter, symbol 336 represents an AC-powered control circuit, symbol 338 represents an AC-powered operation selector, symbol 340 represents an AC-powered multiplexer, symbol 342 represents an AC-powered demultiplexer, and symbol 344 represents an AC-powered arithmetic logic unit, in accordance with at least one example.

FIG. 3C is a schematic 360 of an IQ power port 166 that may be used to power AC logic gates, in accordance with at least one example. Pull-up network 164 known as an IQ power port powers an inverter 376, wherein pull-up network 164 is at least one example of pull-up network 164. Pull-up network 164 includes transistors 362, 364, and 366, which are configured to draw power primarily from signal VI+ 134 during phase 172 of FIG. 1C. Transistors 362, 364, and 366 are controlled by signals VQ+ 146 and VI− 136 that are applied to their respective gate terminals, wherein gate signals consume small power. Most of the power is sourced from a drain of transistor 362 which is connected to VI+ 134. This configuration efficiently utilizes energy available from RF signals to power AC logic gates.

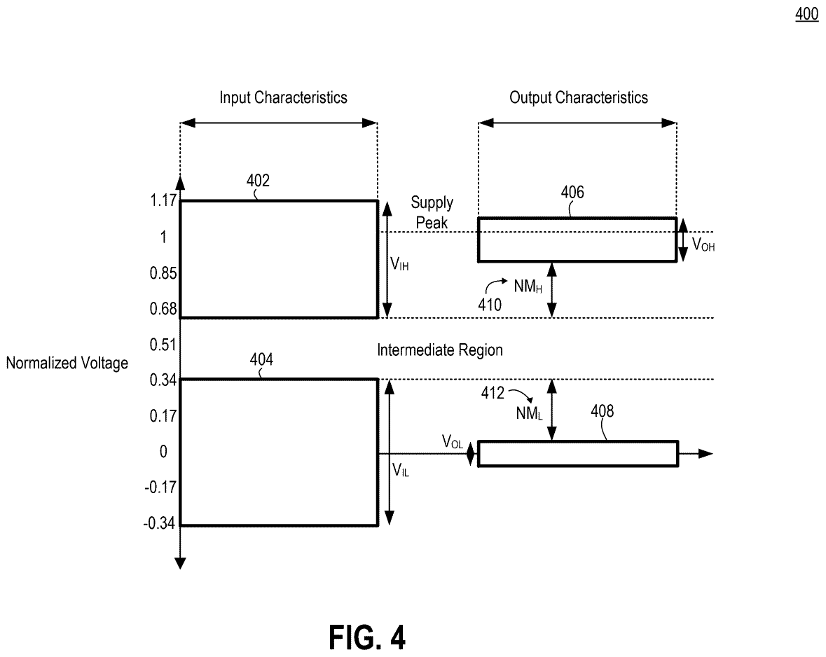

FIG. 4 is a plot 400 illustrating a noise margin of AC logic gates in an AC-powered nano-processor 182, in accordance with at least one example. A vertical axis may represent a normalized voltage range for different power signals VI+ 134, VI− 136, VQ+ 146, and VQ− 148. Region 402 defines an acceptable input high voltage range (V_{IH}), which may indicate a voltage threshold above which an AC logic gate correctly interprets a signal as a high signal. Similarly, region 404 may represent an acceptable input low voltage range (V_{IL}), below which an AC gate may reliably interpret a signal a low signal. Region 406 illustrates an expected output high voltage range (V_{OH}), showing a voltage output level above which a signal may be interpreted as a high signal after it passes through a gate of a transistor. Region 408 defines an expected output low voltage range (V_{OL}), below which a signal may be interpreted as a low signal.

Plot 400 highlights high voltage noise margin (NM_{H}) 410 and low voltage noise margin (NM_{L}) 412. NM_{H} 410 refers to a margin by which a real high input exceeds a predetermined threshold V_{IH}; while NM_{L} 412 represents a margin by which an input stays below a predetermined threshold V_{IL}, ensuring a stable low-level detection. These noise margins may enable reliable operations of AC logic circuits, as they ensure tolerance to variations in input signals due to environmental or process-related factors. Plot 400 demonstrates the contribution of an individual power signal phase towards stable AC logic operations, ensuring that an AC nano-processor may remain resilient against fluctuations in voltage levels of AC signals.

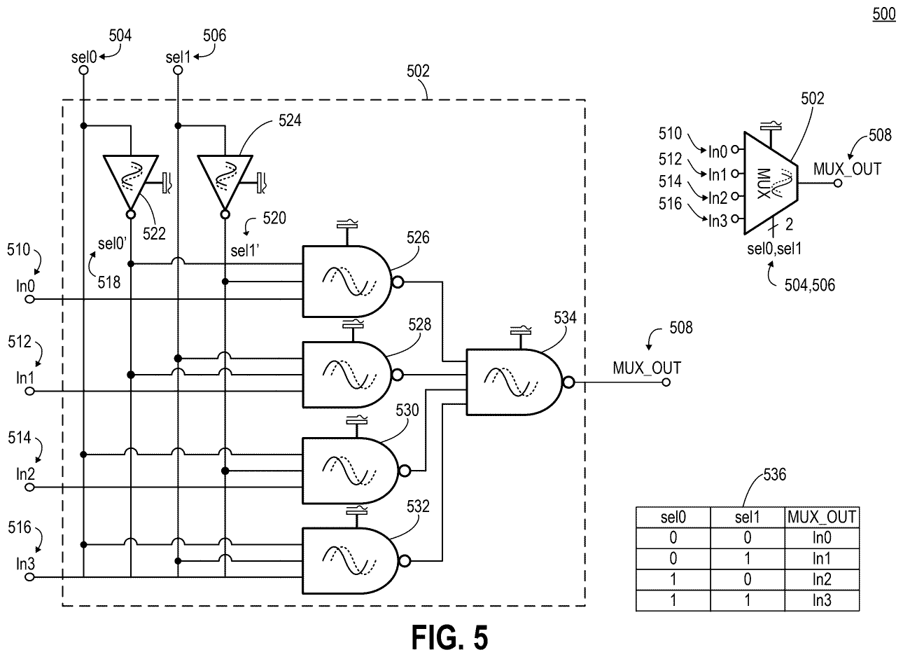

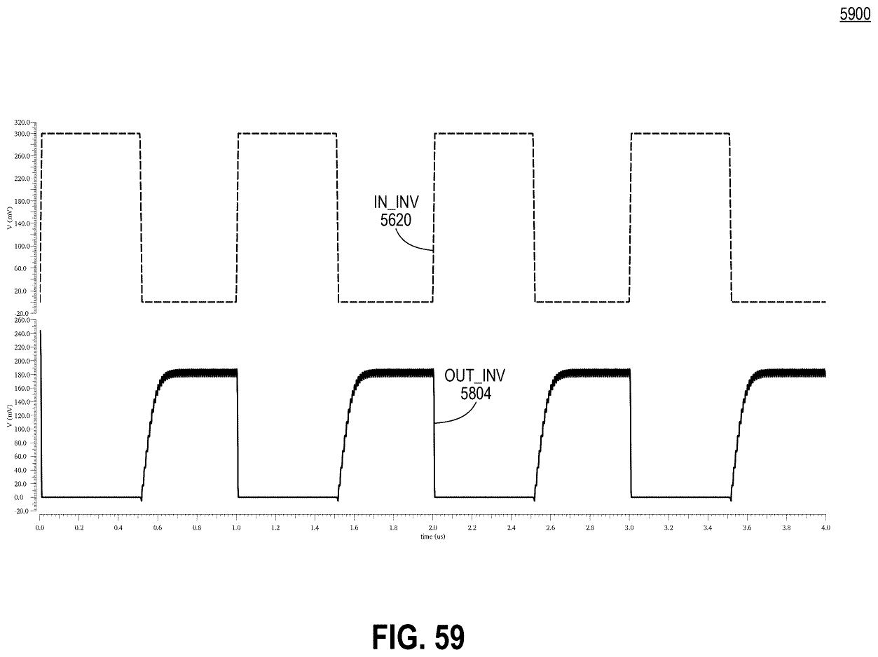

FIG. 5 is a schematic of a circuit 500 of an AC-powered multiplexer (MUX) 502 that may be utilized in a data path of nano-processor 182, in accordance with at least one example. A schematic of circuit 500 of AC-powered MUX 502 may include AC logic gates instead of DC logic gates. An example circuit of AC-powered MUX 502 may include inverters 522 and 524, along with NAND gates 526, 528, 530, 532, and 534, all powered by AC signals using IQ power port 166. Select signals sel0 504, sel1 506, se0′ 518, and sel1′ 520 control a selection process, enabling one of four input signals—In0 510, In1 512, In2 514, and In3 516—to be routed to an output signal MUX_OUT 508. This functionality may allow for dynamic signal selection based on values of control signals. In at least one example, NAND gates 526, 528, 530, 532, and 534 may be implemented as AC-powered NAND gate 5900 of FIG. 59.

In at least one example, table 536 summarizes an expected output behavior of signal MUX_OUT 508 based on various combinations of control signals sel0 504 and sel1 506. For instance, when both sel0 504 and sel1 506 are low, an input signal In0 510 is routed to MUX_OUT 508. Conversely, when sel0 504 is low and sel1 506 is high, input signal In1 512 is routed to MUX_OUT 508. Remaining combinations of sel0 and sel1 are also illustrated in table 536, providing a comprehensive overview of an operational logic of an AC MUX. This arrangement ensures that a nano-processor may effectively manage multiple input signals while maintaining integrity and efficiency of distributing AC power to different components.

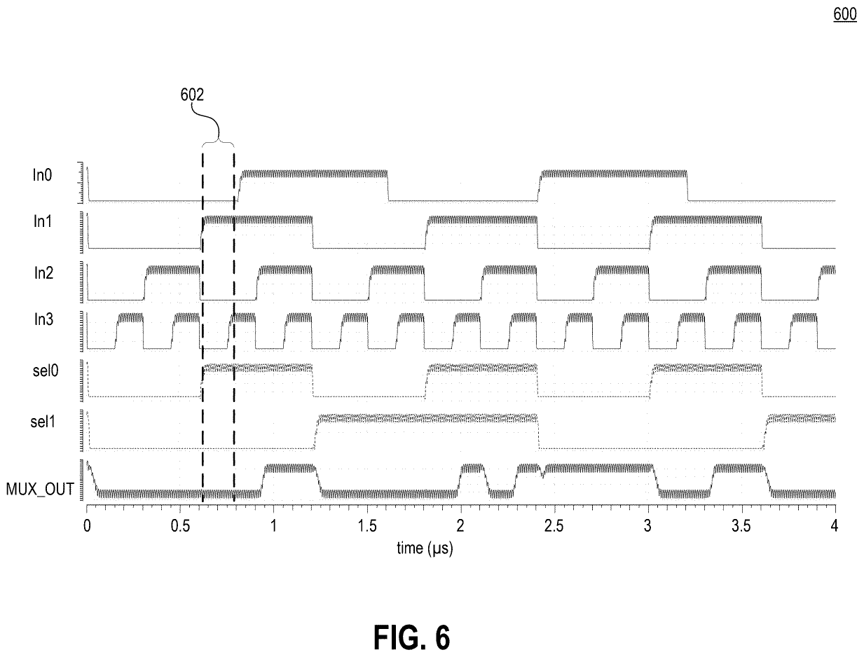

FIG. 6 is a plot 600 illustrating an output signal MUX_OUT 508 of an AC-powered multiplexer (MUX) 502 from FIG. 5 when one of its four input signals—In0 510, In1 512, In2 514, and In3 516—is selected based on values of select signals sel0 504 and sel1 506, in accordance with at least one example. During an interval 602, select signal sel0 504 is high while sel1 506 is low, indicating that an input signal In2 514 may be routed to an output MUX_OUT 508. As shown in this plot, during this specific interval, the value of In2 514 is low, resulting in a corresponding low output at MUX_OUT 508. This behavior confirms that AC MUX 502 is functioning correctly by reflecting the state of a selected input signal at its output. Plot 600 provides a visualization of relationships between select signals and output signal, demonstrating AC MUX's ability to accurately transmit a selected input signal while also illustrating the importance of select signal states in determining which input is routed to an output at any given time.

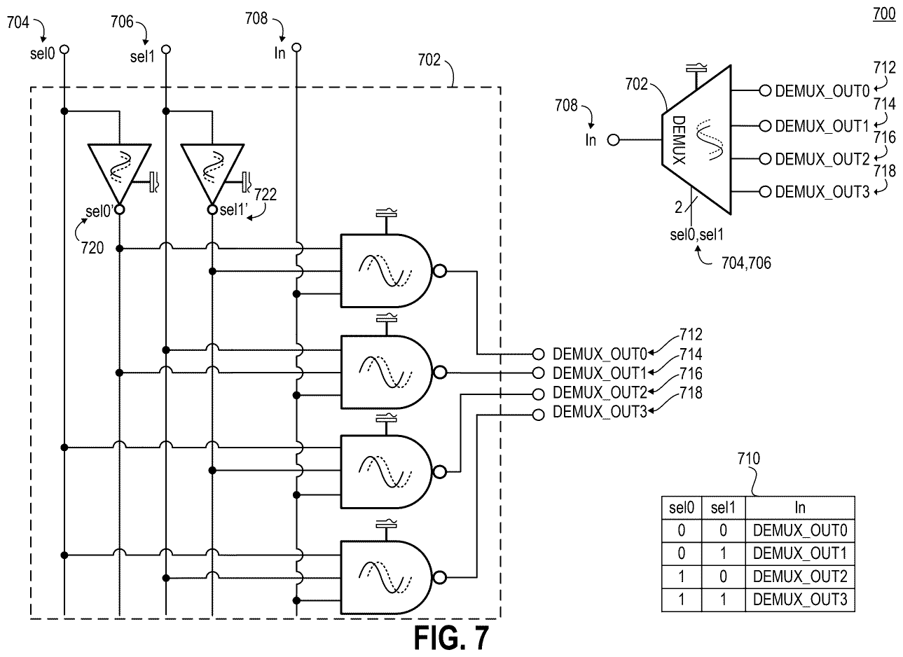

FIG. 7 is a circuit 700 of an AC-powered DEMUX 702, in accordance with at least one example. AC-powered DEMUX 702 is built using a family of AC logic gates instead of DC logic gates. Select signals sel0 704 and sel1 706, along with their inverted versions sel0′ 720 and sel1′ 722, route an input signal In 708 to one of its outputs DEMUX_OUT0 712, DEMUX_OUT1 714, DEMUX_OUT2 716, or DEMUX_OUT3 718, respectively. Table 710 illustrates an expected behavior of AC DEMUX 702 based on various combinations of control signals sel0 704 and sel1 706. For example, when both sel0 704 and sel1 706 are low, an input signal In 708 is routed to DEMUX_OUT0 712. In comparison, when sel0 704 is low and sel1 706 is high, input signal In 708 is routed to DEMUX_OUT1 714. Additional routing scenarios are shown in table 710, illustrating that AC-powered DEMUX 702 can manage switching of an input signal efficiently and effectively to selected outputs.

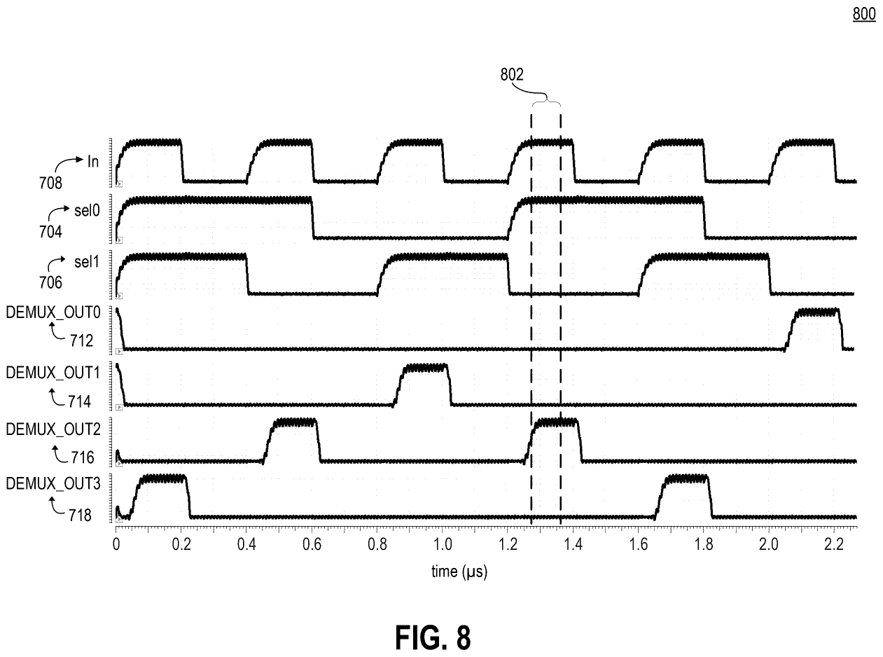

FIG. 8 is a plot 800 illustrating an output of AC-powered DEMUX 702 of FIG. 7, in accordance with at least one example. This circuit routes input signal In 708 to one of four outputs: DEMUX_OUT0 712, DEMUX_OUT1 714, DEMUX_OUT2 716, or DEMUX_OUT3 718 based on values of two select signals, sel0 704 and sel1 706. For example, during an interval 802, select signal sel0 704 is high while sel1 706 is low, resulting in routing input signal In 708 to output DEMUX_OUT2 716, while all other outputs remain low. As shown in FIG. 8, during an interval 802, input signal In 708 is high, leading to a corresponding high output at DEMUX_OUT2 716, whereas outputs DEMUX_OUT0 712, DEMUX_OUT1 714, and DEMUX_OUT3 718 remain low. This behavior demonstrates efficient and effective signal routing capabilities of AC-powered DEMUX 702, ensuring that an input signal is routed to a desired output based on a switching option specified by two select signals sel0 704 and sel1 706.

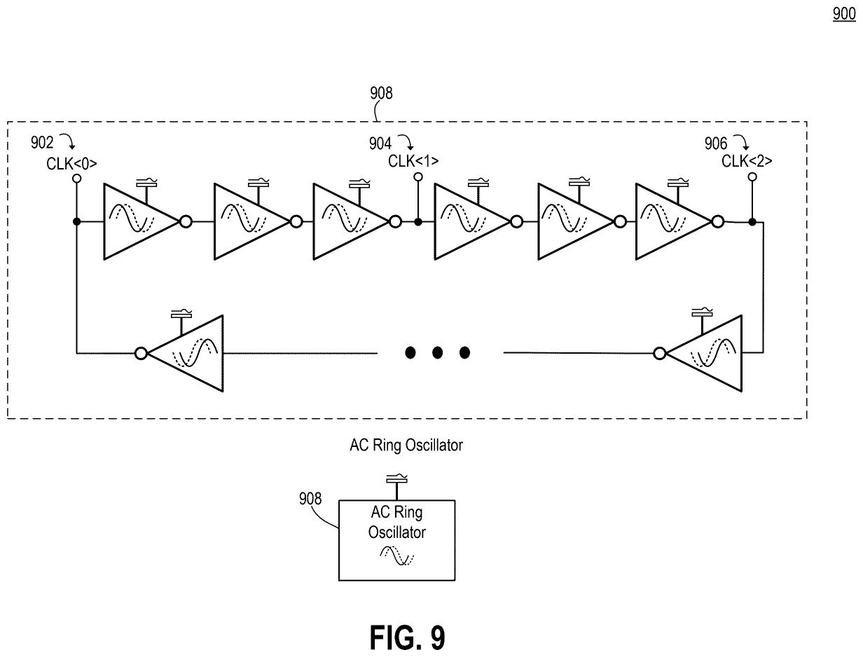

FIG. 9 is a circuit 900 of an AC-powered ring oscillator 908, which may be utilized for generating a master clock in an AC nano-processor 182, in accordance with at least one example. This ring oscillator may employ an odd number of AC inverter stages to produce a square wave signal. A generated square wave signal, denoted as CLK<0> 902, may serve as a primary clock signal for different example embodiments of AC-powered nano-processor 182. Additionally, two further phases, CLK<1> 904 and CLK<2> 906, may be incorporated to mitigate timing violations within a data path of an AC-powered nano-processor 182. For example, an instruction memory can receive an earlier phase signal CLK<0> 902, while a register file may be assigned a delayed phase signal CLK<2> 906. This configuration allows a sufficient amount of time for signals to stabilize in combinatorial and other circuits, ensuring reliable synchronization and operation in an AC-powered nano-processor 182.

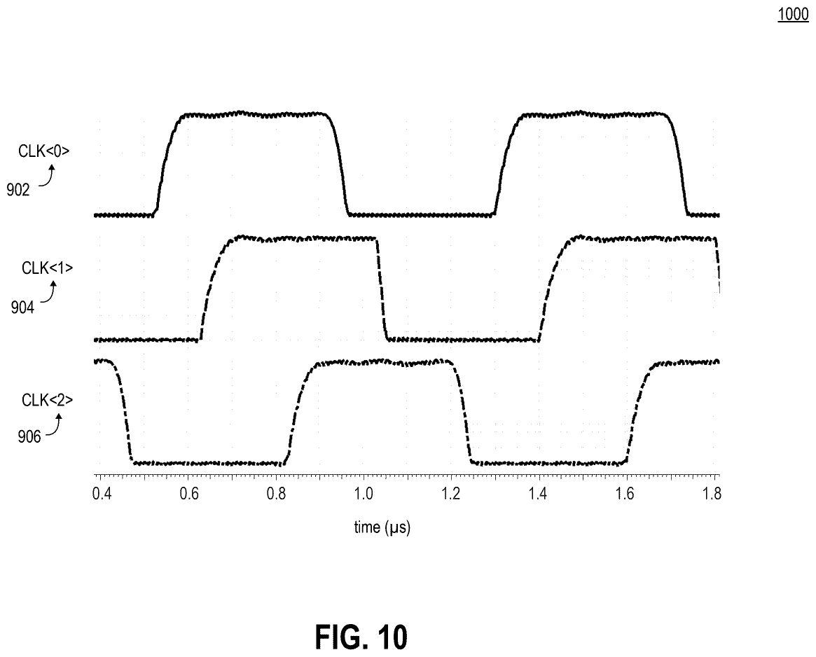

FIG. 10 is a plot 1000 illustrating outputs of AC-powered ring oscillator 908 from FIG. 9, in accordance with at least one example. Signal CLK<0> 902 may represent one phase of a clock signal, while signal CLK<1> 904 and signal CLK<2> 906 may represent a second and third phase of a clock signal, respectively. Within a data path of an example 4-bit AC-powered nano-processor circuit, CLK<0> 902 may function as a clock signal for an instruction memory, facilitating fetching of instructions. Signal CLK<1> 904 may be used by a temporary register, whereas signal CLK<2> 906 may be used by an AC register file of an AC-powered nano-processor. This phased clocking arrangement may optimize data flow and synchronization among different components of a nano-processor, enhancing its performance and efficiency.

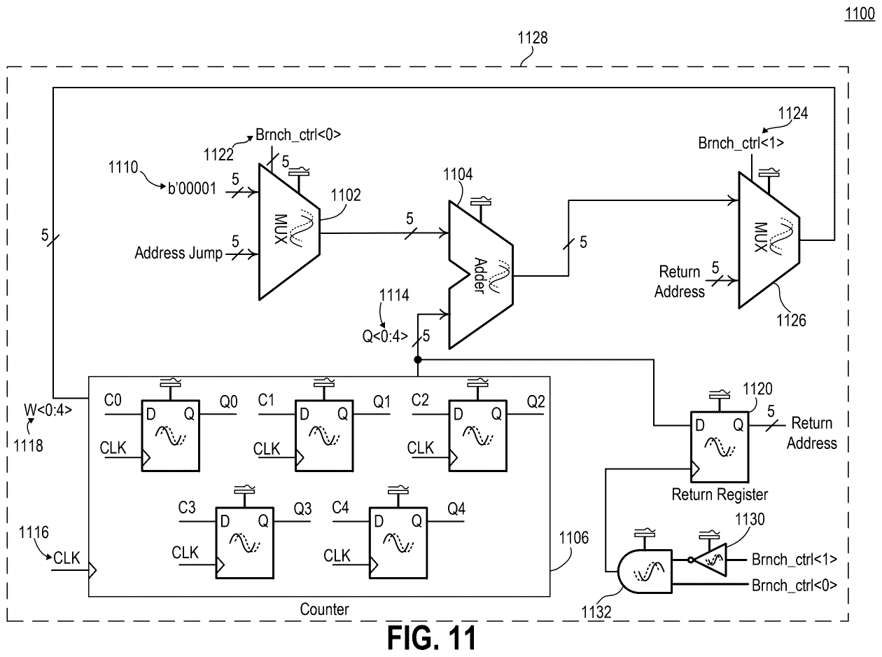

FIG. 11 illustrates a schematic of a circuit 1100 of a program counter 1128 that addresses a data path of an AC-powered nano-processor 182 by executing instructions, in accordance with at least one example. Circuit 1100 includes an AC counter 1106 with address width W<0:4> 1118, an AC adder 1104, branch controlling muxes, MUX 1102 and MUX 1126, and a return register 1120. MUX 1102 and MUX 1126 may use select signals, Brnch_ctrl<0> 1122 and Brnch_ctrl<1> 1124, to control address jumps, which may directly influence a flow of a program that is executing on an AC-powered nano-processor 182. Under normal operating conditions, where both Brnch_ctrl<0> 1122 and Brnch_ctrl<1> 1124 are 0, AC MUX 1102 outputs a binary value b′00001 1110. AC adder 1104 increments AC counter 1106 on each positive edge of a clock signal CLK 1116, and routing newly incremented value using AC MUX 1126.

In at least one example, when Brnch_ctrl<0> 1122 is 1 and Brnch_ctrl<1> 1124 is 0, AC MUX 1102 outputs a target offset address of a given jump instruction, which is added to a current address Q<0:4> 1114 by AC adder 1104 at a positive edge of CLK 1116, redirecting execution flow of a program to newly computed target address. Concurrently, a return address—indicating where the jump is initiated—is stored in return register 1120. Return register 1120 is clocked using a combination of Brnch_ctrl<0> 1122 and Brnch_ctrl<1> 1124 to capture a positive edge when a jump address instruction is received; and this may occur when Brnch_ctrl<1> 1124 is 0 and Brnch_ctrl<0> 1122 transitions from 0 to 1. This functionality may be achieved by using an AND gate 1132 and an inverter 1130, which allow signals to propagate further when both conditions are met. When Brnch_ctrl<1> 1124 value is 1, a return address is routed to program counter 1128 using AC MUX 1126, irrespective of the value of Brnch_ctrl<0> 1122. Additionally, for higher bit-width sized instructions, bit width of program counter 1128 may also be expanded if needed, in accordance with at least one example.

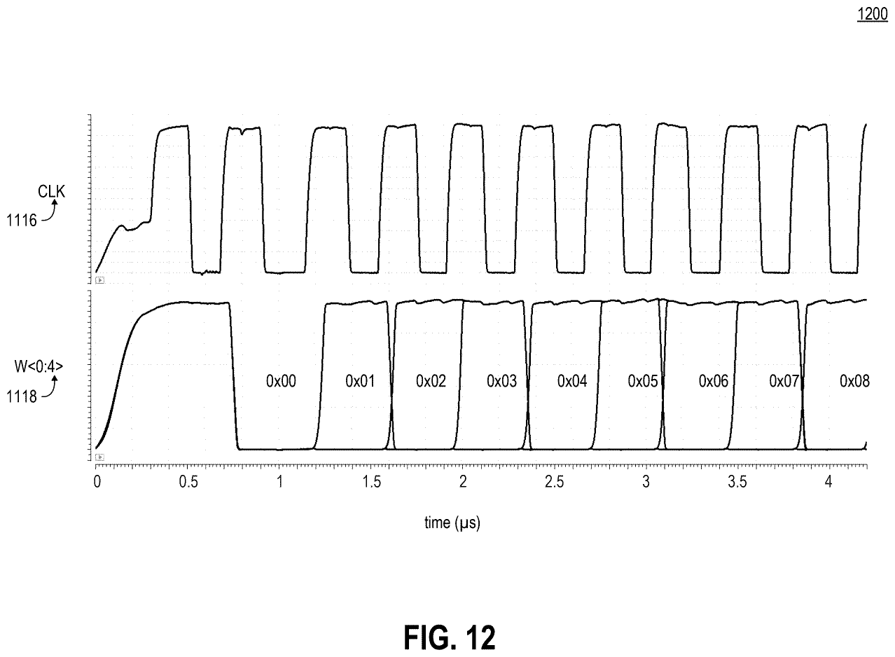

FIG. 12 is a plot 1200 of an output from program counter 1128 of FIG. 11, in accordance with at least one example. Instructions are stored in a read-only memory (ROM) that is addressed using address W<0:4> 1118 from program counter 1128. As illustrated in FIG. 12, instruction address W<0:4> 1118 begins at a first address 0x0 and increments continuously with each edge of clock CLK 1116, indicating a sequential fetching of instructions from ROM. This consistent and reliable incrementing of program counter 1128 demonstrates that a flow of instruction execution may be maintained by an AC-powered nano-processor 182 using program counter 1128.

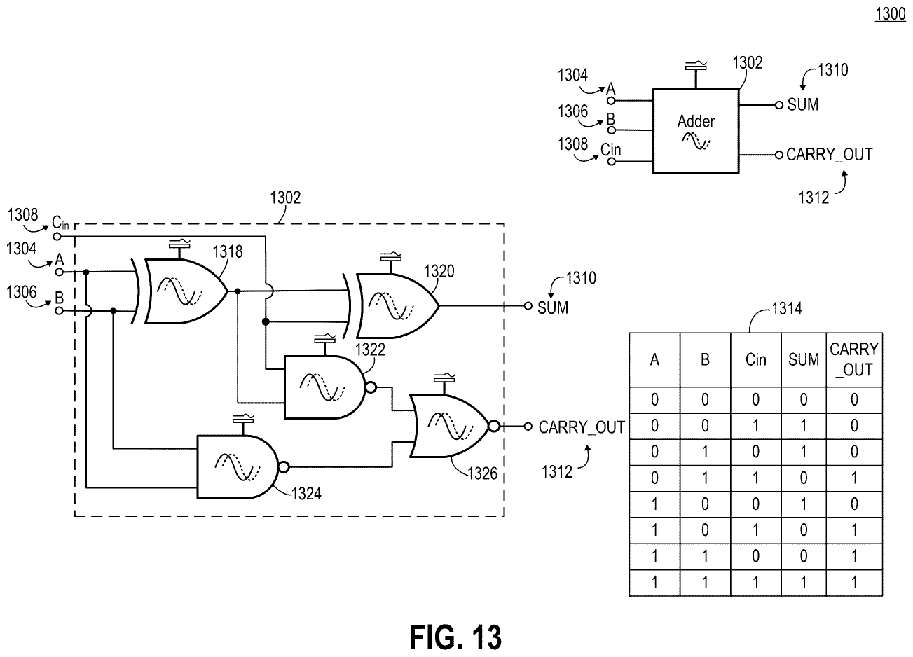

FIG. 13 is a schematic illustrating a circuit 1300 of an AC-powered full adder 1302 used in a data path of AC-powered nano-processor 182 to add two 4-bit numbers, in accordance with at least one example. This adder circuit may use AC XOR gates 1318 and 1320, along with AC NAND gates 1322 and 1324, and an AC NOR gate 1326, to generate desired outputs as specified in input/output characteristics shown in table 1314. AC-powered full adder 1302 receives two 4-bit inputs, A 1304, and B 1306, along with a carry-in input, Cin 1308. It produces two outputs: SUM 1310 and CARRY_OUT 1312. AC logic family of gates are used to design AC-powered full adder 1302, enabling efficient addition operation using an AC power source.

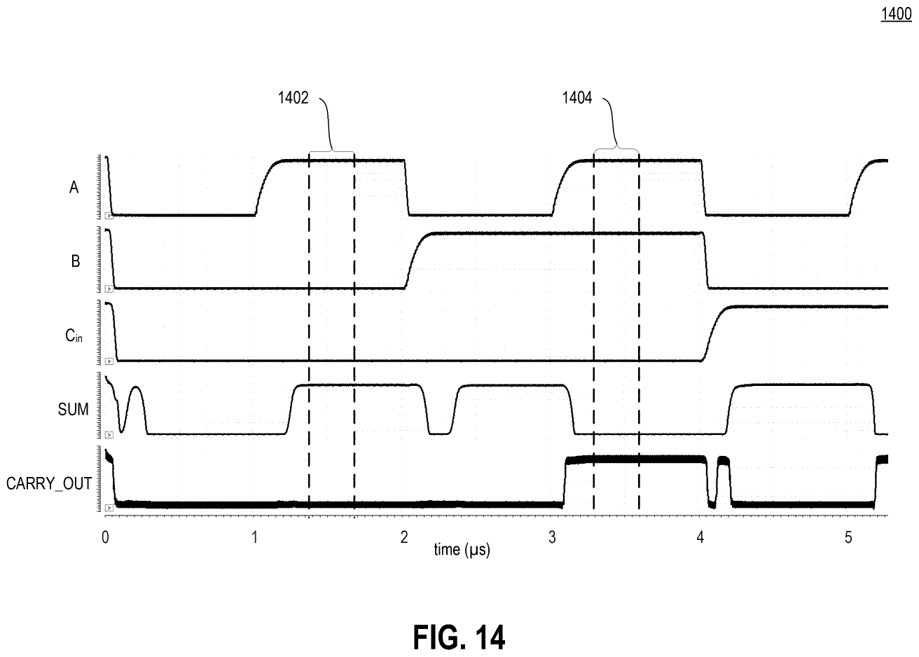

FIG. 14 is a plot 1400 of outputs SUM 1310 and CARRY_OUT 1312 of AC-powered full adder 1302 from FIG. 13, in accordance with at least one example. Operations of AC-powered full adder 1302 can be illustrated by examining its output values for various input scenarios. For example, in time interval 1402, when input signals A 1304 is high, B 1306 is low, and Cin 1308 is low, a sum of these three inputs is equal to 1 and this value is expected at SUM 1310. As shown in FIG. 14, in time interval 1402, SUM 1310 signal is high, while CARRY_OUT 1312 is low. In another example, in time duration 1404, both inputs A 1304 and B 1306 are high, and Cin 1308 is low. Consequently, a sum of three inputs is equal to 2, represented as binary 2′b10, resulting in SUM 1310 signal being low, and CARRY_OUT 1312 being high. This demonstrates a correct functioning of AC-powered full adder 1302 under different input conditions.

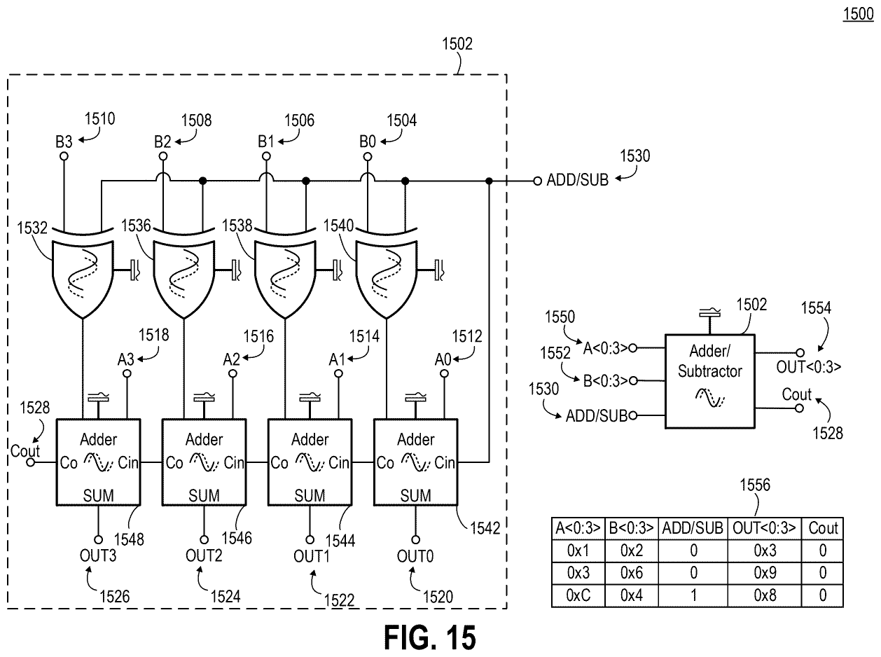

FIG. 15 is a schematic illustrating a circuit 1500 of an AC-powered 4-bit adder/subtractor 1502 used for adding or subtracting 4-bit numbers based on an add/sub signal 1530, in accordance with at least one example. AC-powered 4-bit adder/subtractor circuit 1502 accepts two 4-bit inputs A<0:3> 1550, comprising A0 1512, A1 1514, A2 1516, A3 1518, and B<0:3> 1552, comprising B0 1504, B1 1506, B2 1508, and B3 1510. An addition operation is executed through AC adders 1542, 1544, 1546, and 1548, which are examples of AC-powered full adder 1302 from FIG. 13. ADD/SUB signal 1530 determines whether to perform addition or subtraction operation. When ADD/SUB signal 1530 is set to 1, input signal B<0:3> 1552 is inverted by AC XOR gates 1540, 1538, 1536, and 1532, and carry input to AC adder 1542 is set to 1, resulting in subtraction of B<0:3> 1552 from A<0:3> 1550. Conversely, when ADD/SUB signal 1530 is set to 0, input signals B0 1504, B1 1506, B2 1508, and B3 1510, are passed through XOR gates 1532, 1536, 1538, and 1540, resulting in addition of A<0:3> 1550 and B<0:3> 1552. An output signal OUT<0:3> 1554, comprising OUT0 1520, OUT1 1522, OUT2 1524, and OUT3 1526, represents a 4-bit sum or difference output, with Cout 1528 indicating a status of a Cout 1528 of 4-bit adder/subtractor 1502. A symbol for AC-powered 4-bit adder/subtractor 1502 and associated truth table 1556, illustrating some input-output examples, are also included in FIG. 15.

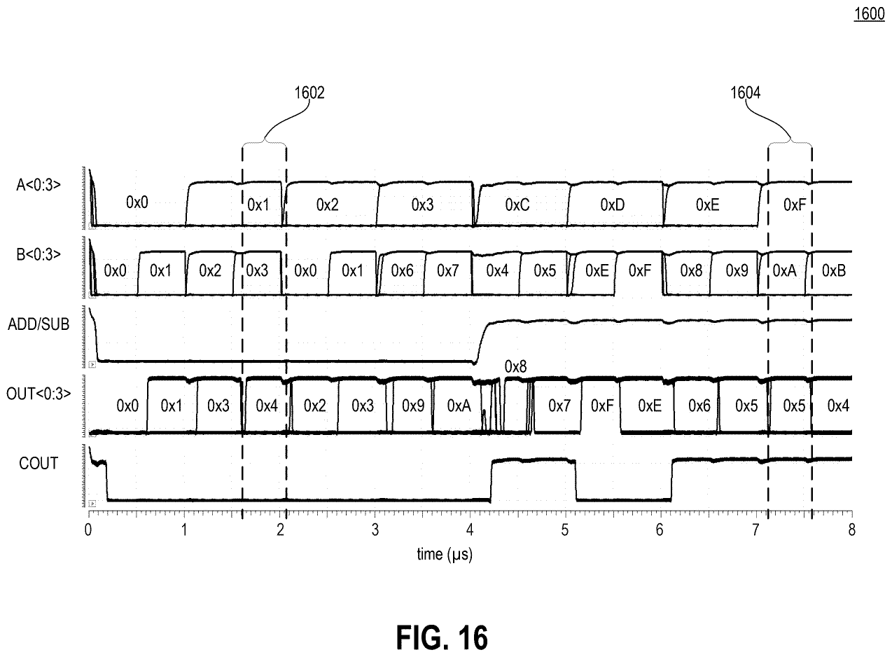

FIG. 16 illustrates a plot 1600 of outputs from AC-powered 4-bit adder/subtractor 1502 of FIG. 15, in accordance with at least one example. Signal 1550 represents first 4-bit input A<0:3>, comprising signals A0 1512, A1 1514, A2 1516, and A3 1518, with its value shown in a hexadecimal format. Similarly, B<0:3> 1552 represents a second 4-bit input B<0:3>, comprising B0 1504, B1 1506, B2 1508, and B3 1510, and its value is also shown in a hexadecimal format. An ADD/SUB signal 1530 along with corresponding output signal OUT<0:4> 1554 is also displayed in a hexadecimal format and includes 4 bits of OUT0 1520, OUT1 1522, OUT2 1524, OUT3 1526, along with a carry out signal represented as Cout 1528. These signals are represented using short symbols for better clarity. Plot 1600 illustrates functional behavior of AC-powered 4-bit adder/subtractor 1502. For instance, during in time interval 1602, when ADD/SUB 1530 signal is low, inputs A<0:3> 1550 and B<0:3> 1552 having values of 0x1 and 0x3 are added, respectively, resulting in an output of 0x4 as shown in OUT<0:3> 1554. In another time interval 1604, when ADD/SUB 1530 signal is high, indicating a subtraction operation, input A<0:3> 1550 having a value of 0xF is subtracted from input B<0:3> 1552 having a value of 0xA. Consequently, a difference result of 0x5 is shown as output signal OUT<0:3> 1554.

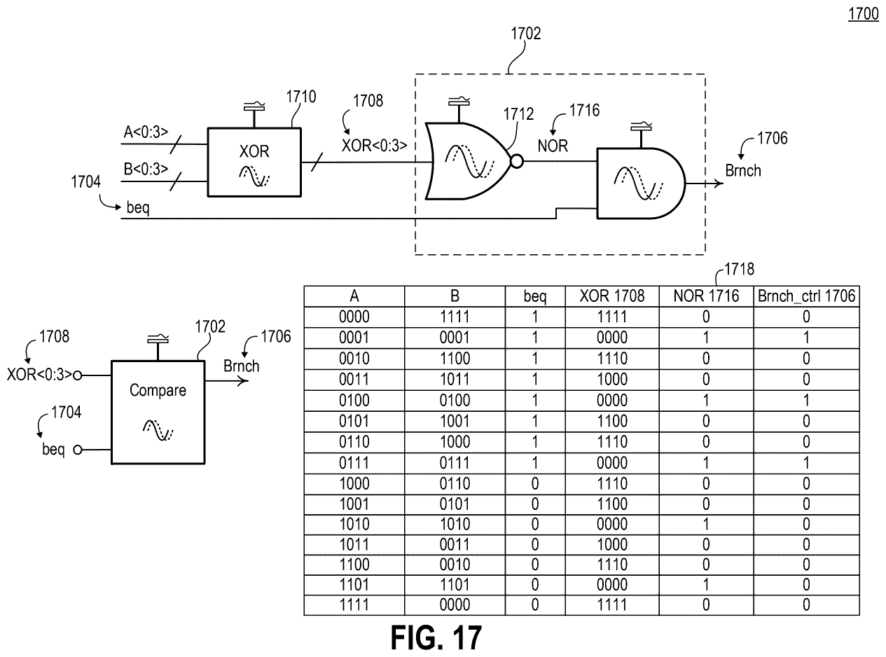

FIG. 17 is a circuit 1700 of a branch controller that may be used for instruction jumping in a data path of AC-powered nano-processor 182, in accordance with at least one example. Circuit 1700 compares two inputs A<0:3> 1550 and B<0:3> 1552 to determine whether to take a branch. If both inputs are equal, a high signal is generated on a Brnch signal 1706, indicating that a branch should be taken. Conversely, if any bits in two inputs differ, a low signal is generated on Brnch signal 1706, indicating that a branch should not be taken. Circuit 1700 utilizes an AC XOR gate 1710 to perform a bitwise comparison of inputs A<0:3> 1550 and B<0:3> 1552, generating an output signal XOR<0:3> 1708. A subsequent AC compare circuit 1702 takes a four-bit NOR 1712 of XOR output 1708, producing a single-bit signal NOR 1716 output, which is ANDed with a beq control signal 1704 to generate a final branch signal Brnch 1706. A combination of an XOR function followed by a NOR function enables a comparison of two input signals. When all corresponding bits in A<0:3> 1550 and B<0:3> 1552 have the same value, output bits of signal XOR<0:3> 1708 will be zeros, resulting in a NOR 1716 output of one by NOR 1712, indicating that A 1550 and B 1552 are equal. Conversely, if any of bits in two inputs differ, output bits of signal XOR<0:3> 1708 will contain ones, resulting in NOR 1716 output of zero by NOR 1712, showing that A 1550 and B 1552 are not equal.

In at least one example, signal NOR 1716 is ANDed with beq control signal 1704, which may serve as an enable signal to generate a final comparison signal Brnch 1706 for branching decisions. Table 1718 illustrates various cases of input signals and their corresponding Brnch 1706 output signals. For example, when input A<0:3> 1550 is 0000 and B<0:3> 1552 is 1111 and a beq control signal is set to 1, output of XOR<0:3> 1708 becomes 1111, resulting in a NOR 1716 output of 0, hence Brnch 1706 becomes. In comparison, when A<0:3> 1550 is 0001 and B<0:3> 1552 is 0001 with a beq control signal set to 1, XOR 1708 output is 0000, yielding a NOR 1716 output of 1; and therefore, resulting in a final Brnch 1706 output of 1. A complete truth table in Table 1718 provides further insights into other input scenarios.

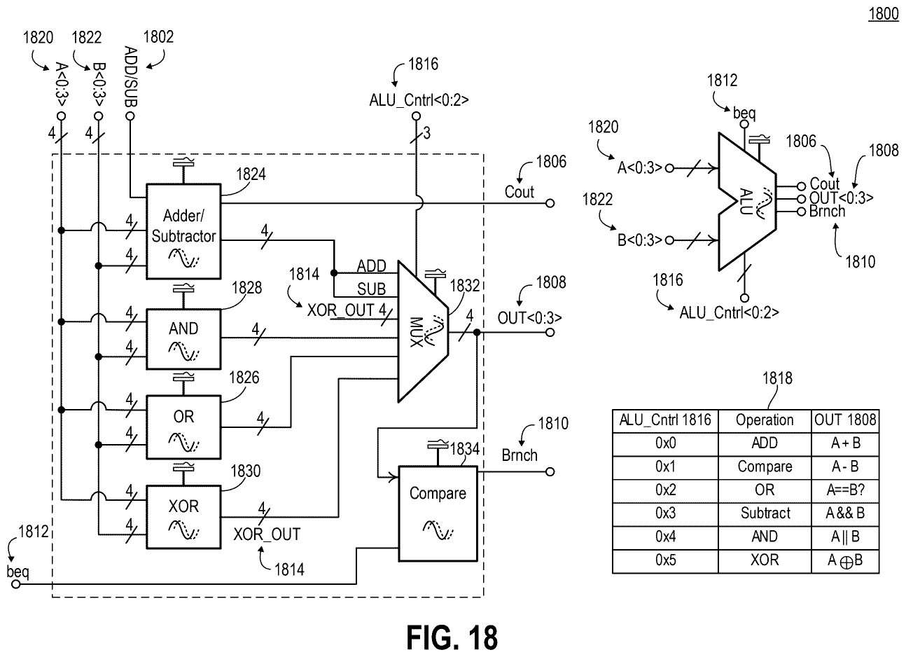

FIG. 18 is a schematic of an AC-powered arithmetic-logic unit (ALU) 1800, in accordance with at least one example. It takes two 4-bit inputs A<0:3> 1820 and B<0:3> 1822, along with an ADD/SUB control signal 1802, a branching control signal beq 1812, and a 3-bit control signal ALU_Cntrl<0:2> 1816 as inputs. ALU 1800 generates a 4-bit output OUT<0:3> 1808, a carry out signal Cout 1806, and a comparison signal Brnch 1810 for branch instructions. A control signal ALU_Cntrl<0:2> 1816 selects among various operations using an 8-input AC MUX 1832. A first operation is addition, which may be performed by a 4-bit AC Adder/Subtractor 1824, which may be an example of AC-powered 4-bit adder/subtractor 1502 from FIG. 15. A second operation may subtract B<0:3> 1822 from A<0:3> 1820 when ADD/SUB signal 1802 is set to high. A third operation may involve a comparison of branch instructions using XOR operations implemented using an AC XOR 1830. A result output, XOR_OUT 1814, is then processed by an AC compare circuit 1834, which may be an example circuit 1702 from FIG. 17. AC compare circuit 1834 may take at its input an XOR 1814 output and a branching control signal beq 1812 to produce a Brnch 1810 signal. In its fourth operation, an AC AND gate 1828 may compute a logical bitwise AND of inputs A<0:3> 1820 and B<0:3> 1822. A fifth operation may use an AC OR gate 1826 to perform a logical bitwise OR operation on inputs A<0:3> 1820 and B<0:3> 1822. Finally, a sixth operation may use an AC XOR gate 1830 to compute a bitwise exclusive OR of input A<0:3> 1820 and B<0:3> 1822. A summary of these operations and their corresponding control signal values is provided in table 1818.

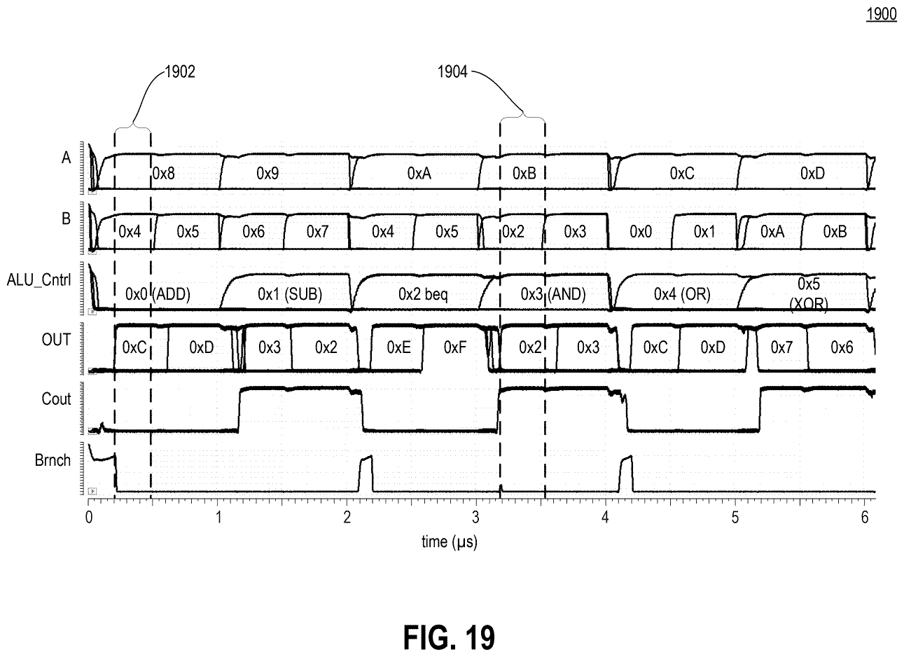

FIG. 19 is a plot 1900 of an output of AC-powered ALU 1800 from FIG. 18 when 4-bit signals A<0:3> 1820 and B<0:3> 1822 are applied at its input, in accordance with at least one example. A selected operation is determined by a 3-bit select signal ALU_Cntrl<0:2> 1816. ALU 1800 generates a 4-bit output OUT<0:3> 1808 based on values of a select signal, along with a 1-bit comparison signal Brnch 1810 that compares two input signals A<0:3> 1820 and B<0:3> 1822. For instance, in time interval 1902, input signal A<0:3> 1820 is 0x8 and input signal B<0:3> 1822 is 0x4. A controlling signal ALU_Cntrl<0:2> 1816 is 0x0, indicating an addition operation. Consequently, an output of ALU 1800, OUT<0:3> 1808, is 0xC. In another in time interval, 1904, input signal A<0:3> 1820 has a value of 0xB and input signal B<0:3> 1822 has a value of 0x2, while controlling signal ALU_Cntrl<0:2> 1816 has a value of 0x3, and this may be translated into an AND operation. Consequently, OUT<0:3> 1808 of ALU 1800 is 0x2.

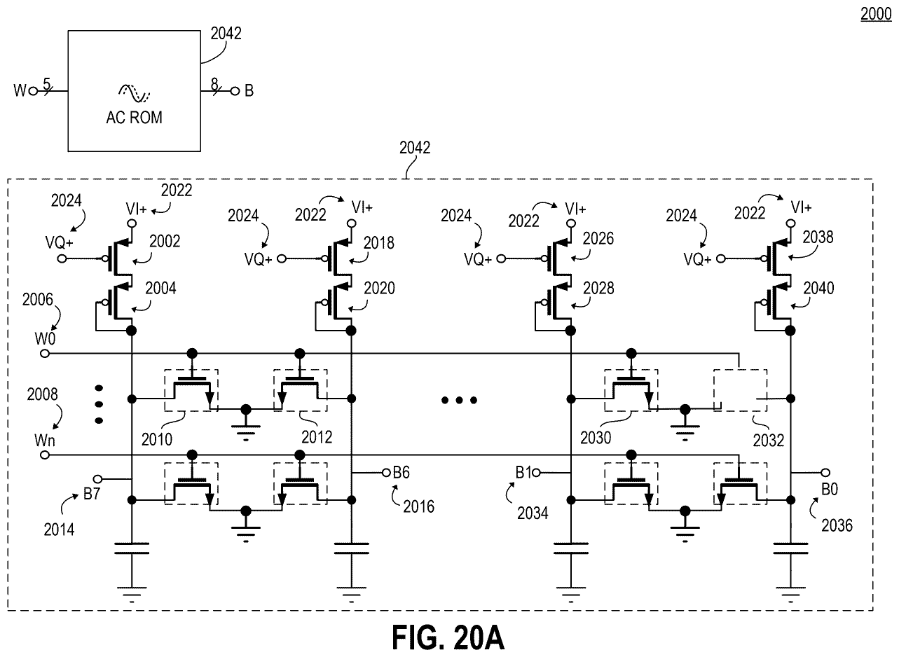

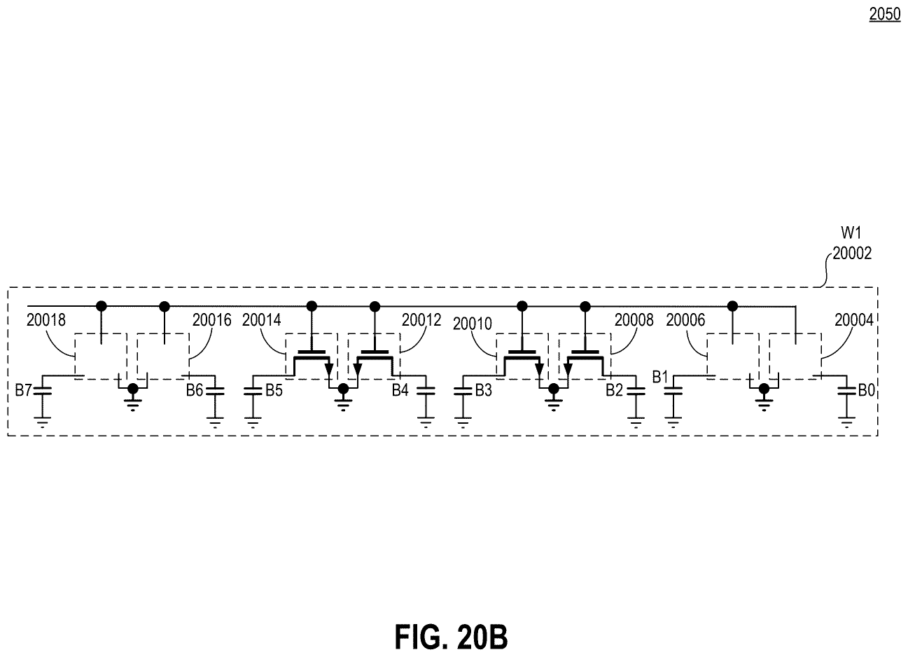

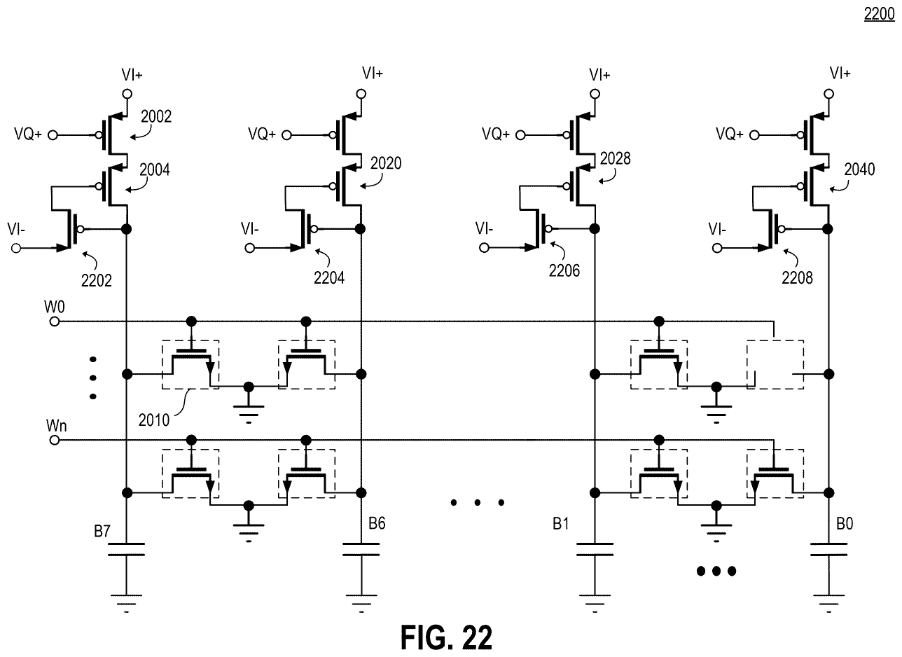

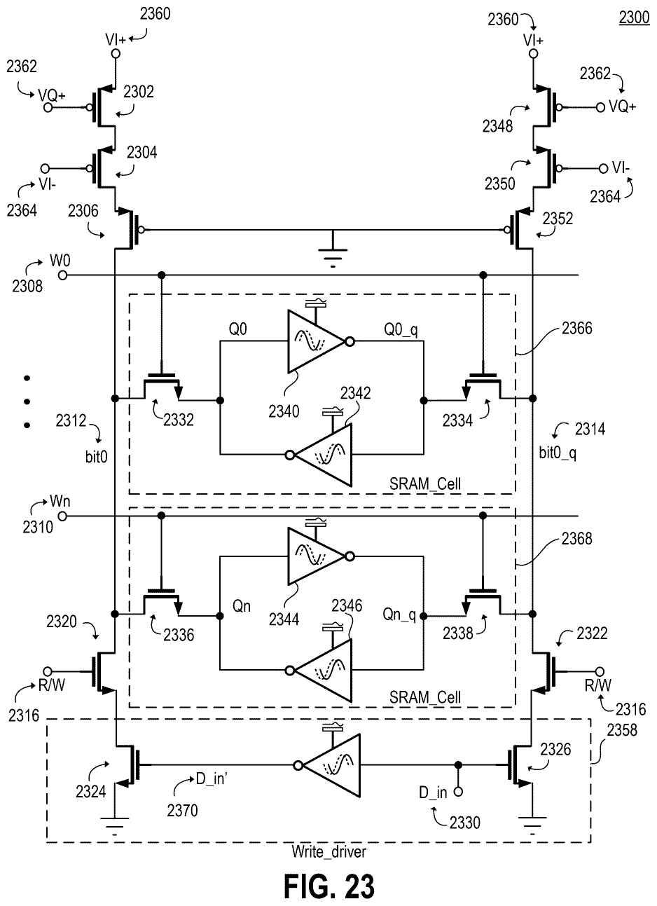

FIG. 20A is a circuit 2000 of an AC-powered ROM 2042 that may be used to store instructions for an AC nano-processor 182, in accordance with at least one example. Circuit 2000 may include bit line capacitances B0 2036 and B1 2034, up to B6 2016 and B7 2014, representing either actual capacitors or parasitic capacitances. Bit line capacitance B7 2014 is charged through transistors 2002 and 2004, and B6 2016 is charged through transistors 2018 and 2020, using phase signals VI+ 2022 and VQ+ 2024. Similarly, using VI+ 2022 and VQ+ 2024, bit line capacitance B1 2034 is charged through transistors 2026 and 2028, and B0 2036 is charged through transistors 2038 and 2040. The remaining bit line capacitances are charged through additional transistors that are not shown in FIG. 20A for clarity. Word lines W0 2006 to Wn 2008 may activate a desired memory address. Data can be stored in at a desired memory address by placing or removing NMOS transistors at data cells such as 2010, 2012, 2030, and 2032. Presence of a data cell transistor stores bit ‘0’, while its absence stores bit ‘1’. During a read operation, bit lines are charged to a high voltage. When a word line is selected, it may activate transistors connected to it. If a data cell transistor is present, such as transistor at data cell 2012 on bit line B6 2016, it pulls a bit line to ground, indicating a 0 output. Conversely, if a transistor is absent, such as in data cell 2032 on bit line B0 2036, then bit line bit line B0 2036 can retain its high voltage, indicating a 1 output. This process may allow AC ROM 2042 to read a desired instruction from a desired address. Memory circuits may use an isolation transistor between IQ power port and bit lines, along with a relatively large capacitance, which may result in significant power consumption. Consequently, these circuits are treated differently from the rest, utilizing separate power circuits as shown in examples of FIG. 20A, FIG. 22, and FIG. 23. These examples show best configurations that are determined by empirical investigations.

FIG. 20B is a schematic 2050 of an example of memory 2042 illustrating programmed instruction bits of a full 8-bit instruction at address W1 20002, in accordance with at least one example. Presence of data cell transistors at locations 20008, 20010, 20012, and 20014 indicates stored values of 0, while absence of transistors at locations 20004, 20006, 20016, and 20018 indicates stored values of 1. Therefore, an instruction that is stored at address W1 20002 may be interpreted as 8′b11000011. To restore signals, bit line outputs are processed through AC inverters, not shown in FIG. 20A and FIG. 20B, before being used.

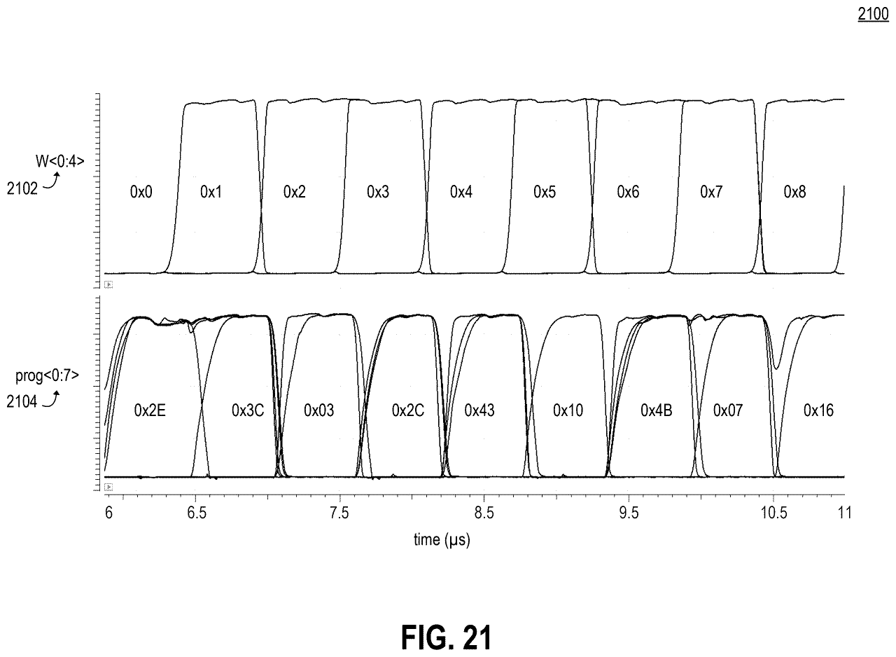

FIG. 21 is a plot 2100 of an output from AC-powered memory 2042 of FIG. 20A, in accordance with at least one example. A five-bit word address W<0:4> 2102 may be used to access an instruction memory, which may store and retrieve instructions for a data path of AC-powered nano-processor 182. Instruction memory 2042 outputs an 8-bit signal prog<0:7> 2104. This eight-bit signal contains encoded instructions that may determine different operations that need to be performed based on a nano-processor's instruction set architecture (ISA). For instance, when a word address W<0:4> 2102 is set to a specified value, a corresponding instruction is fetched and interpreted as prog<0:7> 2104 to control data flow and subsequent processing steps. Instructions fetched may trigger ALU operations, branch instructions, or memory access depending on encoding of instructions, demonstrating how an AC-powered memory 2042 may efficiently interface with other components of a nano-processor 182 to execute programming workloads.

FIG. 22 is a circuit of an example structure of an AC-powered memory 2200 that may be used to store instructions for AC nano-processor 182, in accordance with at least one example. This example is like that of FIG. 20A, except a group of transistors 2202, 2204, 2206, and 2208 are added, which may be used to support pull-up network transistors 2004, 2020, 2028, and 2040. In this configuration, transistors 2002 and 2004 in a charging pull-up network, along with associated active data cell transistors like 2010, may exhibit an inverted logic behavior. Specifically, pull-up network transistors may be used to raise voltage at a bit line, while active data cell transistors may be used to lower it. This opposite behavior leads to leakage currents flowing through a memory circuit, contributing to power dissipation. By integrating additional support transistors in this example, it may effectively reduce leakage currents in charging branches and active data cell transistors. This optimization may enhance power efficiency and also improve an overall performance and reliability of AC-powered memory 2200 in a context of executing compute workloads on a nano-processor.

FIG. 23 is a circuit of an AC-powered memory 2300 based on a static random access memory (SRAM) architecture, in accordance with at least one example. This illustration shows a single bit line for a better comprehension, however, this architecture can be replicated to create a multibit memory. In an example, a 4-bit AC-powered nano-processor 182 utilizes a 4-bit SRAM for data memory. AC-powered memory 2300 employs a traditional six-transistor design that is powered up by AC power. Each bit is stored in an AC SRAM data cell and accessed through a single word line and two bit lines with opposite charges on them, bit0 2312 and bit0_q 2314. These bit lines may be charged using signals VI+ 2360, VQ+ 2362, and VI− 2364 applied at transistors 2302, 2304, 2306, 2348, 2350, and 2352. Each data cell of AC-powered memory 2300 may comprise a pair of cross-coupled AC SRAM inverters for storing data and two access transistors for doing read/write operations. For example, a first SRAM data cell 2366, linked to a word line W0 2308, may include AC SRAM inverters 2340 and 2342 and access transistors 2332 and 2334. An n^{th} SRAM data cell 2368, associated with a word line Wn 2310, may comprise AC SRAM inverters 2344 and 2346 and access transistors 2336 and 2338. Word lines from W0 2308 to Wn 2310 may allow individual access to each SRAM data cell using access transistors for executing data operations. Activating a word line raises a gate voltage of corresponding access transistors, connecting selected bit lines to cross-coupled inverter pair at a selected address. Other word lines remain deactivated, ensuring that one data cell may be accessed at a time.

The R/W signal 2316 controls a read or write operation in a data memory using two NMOS transistors 2320 and 2322. During a read operation, with R/W 2316 low, transistors 2320 and 2322 are off, which may charge bit lines bit0 2312 and bit0_q 2314 using a pull-up network. When a word line is selected to read an SRAM data cell, one of bit lines is charged based on a stored data value. For cells storing a 0, bit0 2312 remains high while bit0_q 2314 discharges. For cells storing a 1, bit0 2312 discharges while bit0_q 2314 is high. Consequently, data is latched onto selected bit lines for reading. In a write mode, an R/W signal 2316 is set high that may turn on transistors 2320 and 2322, allowing a write driver circuit 2358 to access bit lines. Initially, both bit lines are pre-charged to a high voltage. A write driver circuit develops a D_in signal 2330 on bit0 2312 and a complementary D_in′ signal 2370 on bit0_q 2314. When D_in is high and D_in′ is low, NMOS transistor 2326 pulls bit0_q 2314 to ground, while transistor 2324 remains off, keeping bit0 2312 high. Conversely, when D_in is low and D_in′ is high, transistor 2326 turns off, charging bit0_q 2314 to high while transistor 2324 pulls bit0 2312 to a ground. This data is then transferred to a selected SRAM data cell's cross-coupled inverter pair via its access transistors, latching data within a corresponding SRAM data cell. This design may enhance memory access speed and efficiency, resulting in an enhanced performance of AC-powered nano-processor 182.

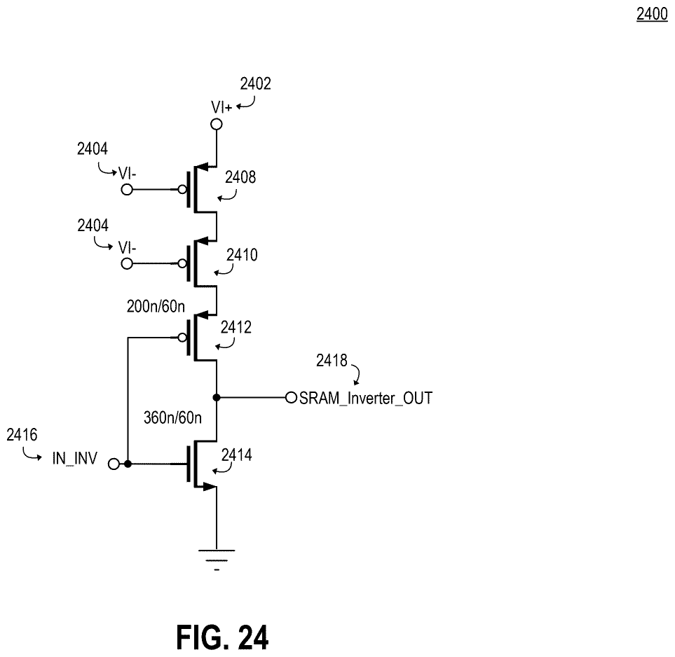

FIG. 24 is a circuit of an AC-powered SRAM inverter 2400, which may be used in a storage cell within an AC-powered memory 2300 of FIG. 23, in accordance with at least one example. SRAM inverter 2400 comprises transistors 2408 and 2410, which may charge a gate through a supply signal VI+ 2402 for enabling AC-powered operations. Signal VI− 2404 may be used as a control signal for transistors 2408 and 2410. Transistors 2412 and 2414 are specifically sized at 200n/60n and 360n/60n for a 65 nm technology node, respectively, to facilitate a proper SRAM operation, enhancing stability and performance when using AC power signals. An input signal to SRAM inverter 2400 is designated as IN_INV 2416, while an output signal is labeled as SRAM_Inverter_OUT 2418. This inverter configuration may maintain an integrity of stored data, enabling effective read/write operations in AC-powered memory 2300. This example circuit enables low-power consumption while also storing data reliably. Furthermore, optimally sized transistors may contribute to improving speed and efficiency, addressing different challenges that may be associated with AC memory circuits.

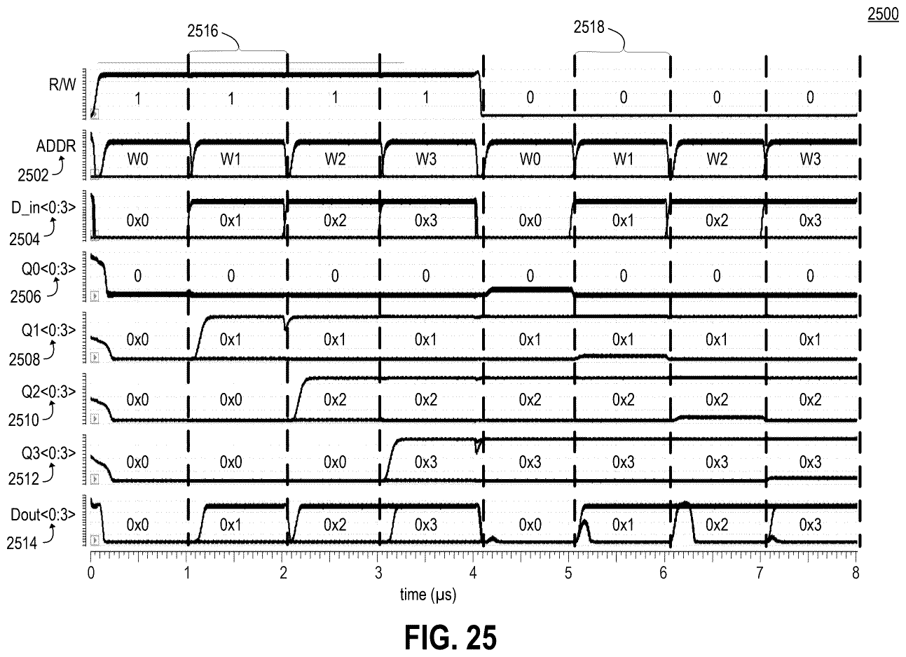

FIG. 25 is a plot 2500 of input, output, and control signals of AC-powered memory 2300 of FIG. 23, in accordance with at least one example. An R/W signal 2316 determines an operational model for AC-powered memory 2300, indicating either a read or write operation is desired. A signal ADDR 2502 specifies a selected word line, while a D_in signal 2504 represents 4-bit data that is being written to AC-powered memory 2300. Signals Q0<0:3> 2506, Q1<0:3> 2508, Q2<0:3> 2510, and Q3<0:3> 2512 illustrate that data may be stored in memory cells, and Dout 2514 represents an output signal from AC-powered memory 2300.

In a write mode, when R/W signal 2316 is set to 1, an input data signal D_in<0:3> 2504 may be written into a memory cell at an address specified in ADDR 2502. For example, during time interval 2516, R/W signal 2316 is 1, and D_in<0:3> 2504 set to 0x1 and ADDR 2502 indicates that W1 is selected. Consequently, a memory location determined by Q1<0:3> 2508 may store value 0x1 and retain it throughout an indicated time duration. During a read mode, when R/W signal 2316 is set to 0, address signal ADDR 2502 may select a memory address from where data needs to be read. For example, in time interval 2518, R/W signal 2316 at 0 and ADDR 2502 indicates W1, a value 0x1 previously stored in a memory location Q1<0:3> 2508 is read and latched on data bus as shown by Dout<0:3> 2514. This behavior demonstrates that AC-powered memory 2300 may effectively store and retrieve data using memory control signals.

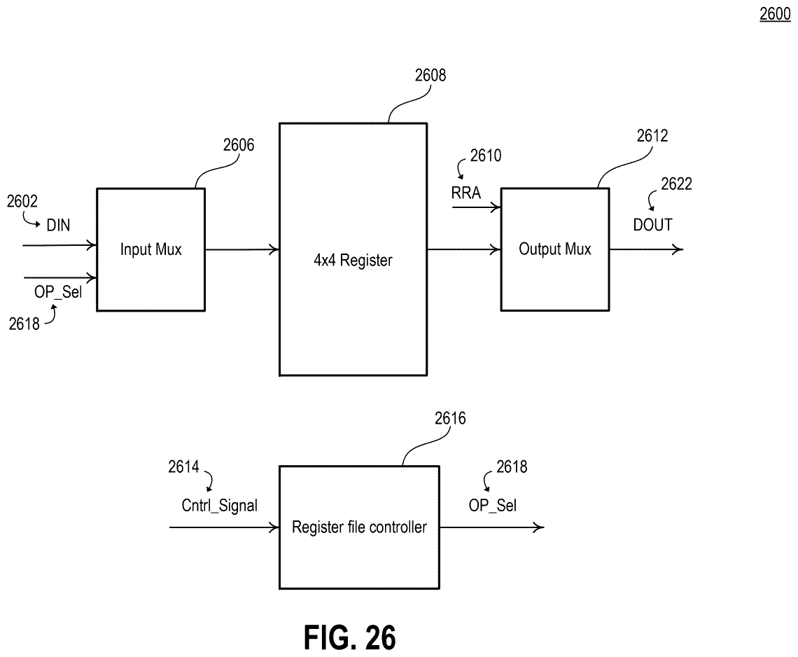

FIG. 26 is a block diagram of an AC-powered register file 2600 that may be used in AC-powered nano-processor 182, in accordance with at least one example. Register file 2600 may comprise four registers 2608, each capable of storing 4 bits of data, along with input and output selection multiplexers namely MUX 2606 and MUX 2612, in at least one example. Operations supported by AC-powered register file 2600 may include writing new data, left and right shifting data. To perform a specific operation, input MUX 2606 may select appropriate data based on an address of a target register. AC Register file 2600 may have an internal control circuit, including an AC-powered register file controller 2616, which may generate selection signals OP_Sel 2618 for input MUX 2606. AC register file controller 2616 may receive a control signal Cntrl_Signal 2614 from a control circuit of a data path and may use it to produce a select signal OP_Sel 2618. Input MUX 2606 may use OP_Sel 2618 to choose a correct input data DIN 2602 for a designated register in AC register file 2608. Data stored in a designated register of AC register file 2608 may be accessed through output MUX 2612, which may select data based on a Read Register Address (RRA) 2610 signal. Output signal DOUT 2622 from AC register file 2608 may be used to carry out operations on a data path of AC-powered nano-processor 182. This architecture may enhance functionality of AC-powered nano-processor 182 by allowing it to efficiently manipulate data in high speed AC registers of AC register file 2608.

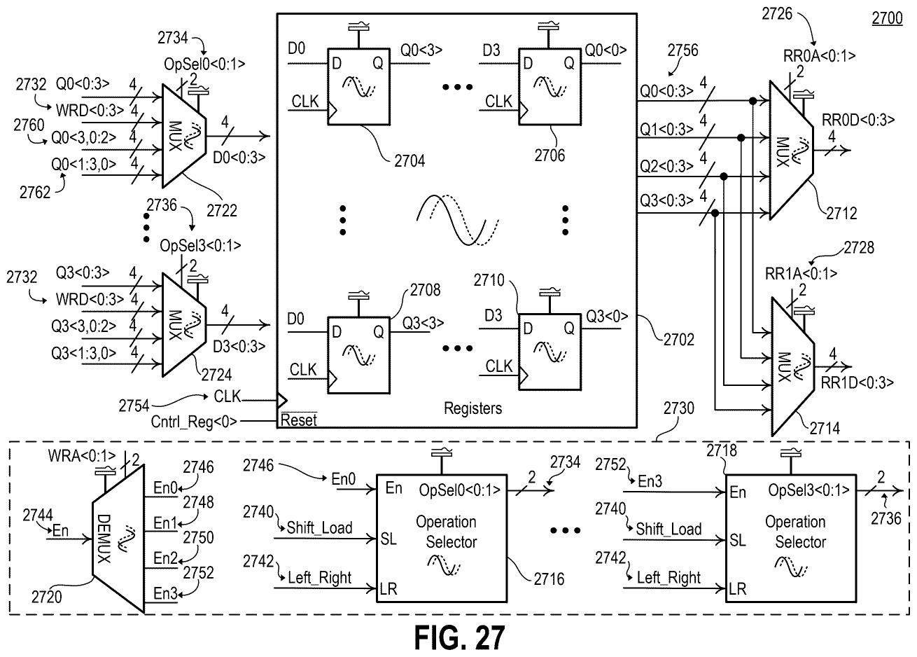

FIG. 27 is a circuit 2700 of an AC-powered register file 2600 from FIG. 26 which may be used in an AC-powered nano-processor 182, in accordance with at least one example. AC register file 2600 may comprise an AC register file 2702 including four AC registers, and an individual AC register may comprise four AC flip-flops; consequently, AC register file 2600 may include 16 AC flip-flops. All AC registers are clocked by a CLK 2754 signal. For a better comprehension, four flip-flops 2704, 2706, 2708, and 2710 are shown in FIG. 27, but it is easy to complete a complete circuit by adding the remaining 12 flip-flops. AC register file 2600 may also include two output AC multiplexers namely MUX 2712 and MUX 2714, which may select outputs from four AC registers based on read register address signals RR0A<0:1>α2726 and RR1A<0:1> 2728, respectively. Input selection may be selected by an AC demultiplexer (DEMUX) 2720, which may be followed by AC operation selectors 2716 and 2718, along with two additional selectors not shown in FIG. 27, and AC MUXes 2722 and 2724, along with two more MUXes that are not shown to avoid clutter. To execute data loading and shifting operations, AC MUX 2722 to AC MUX 2724 may select appropriate input bits. When AC register file 2600 is disabled and no operation may be needed, AC MUX 2722 may utilize a signal Q0<0:3> 2756, which may reflect a repeated output of register zero, ensuring that a stored value may remain unchanged after a next clock edge. When new data may need to be written, AC MUX 2722 may use a write register data signal WRD<0:3> 2732. For left or right shifting operations, MUX 2722 may use a left-shifted version of an AC register's stored data Q0<3,0:2> 2760 and its right-shifted version Q0<1:3,0> 2762, respectively. Other MUXes may operate similarly for their corresponding AC registers. Control signals for these input MUXes, OpSel0<0:1> 2734 to OpSel3<0:1> 2736, may be generated by an AC register file controller 2730, which may be an example of controller 2616 from FIG. 26. AC Register file controller 2730 may include AC DEMUX 2720 and AC operation selectors 2716 to 2718, which may generate different operation selection signals for four MUXes based on a selected address of an AC register and a desired operation. An enable signal En 2744 and AC DEMUX 2720 may produce four more enable signals: En0 2746, En1 2748, En2 2750, and En3 2752, corresponding to an individual AC register. These enable signals, combined with control signals Shift_Load 2740 and Left_Right 2742, may generate control signals OpSel0<0:1> 2734 to OpSel3<0:1> 2736 using operation selectors 2716 to 2718. This architecture may allow efficient data manipulation and control within AC-powered register file 2600, allowing to execute a set of heterogeneous instructions on an AC-powered nano-processor 182.

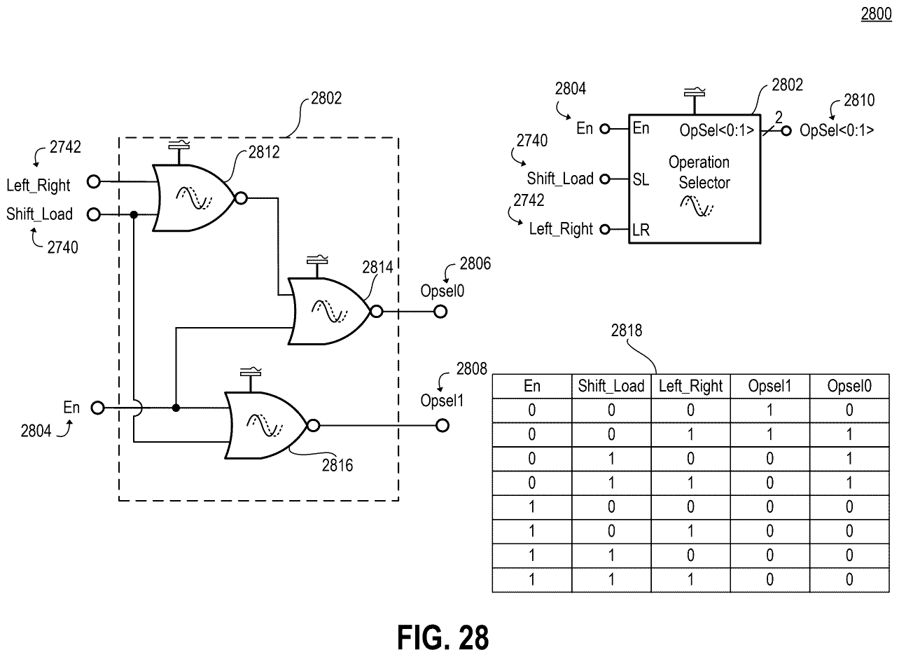

FIG. 28 is a circuit 2800 of an AC-powered operation selector 2802, in accordance with at least one example. AC-powered operation selector 2802 may comprise three AC NOR gates 2812, 2814, and 2816, which may generate an operation selection signal OpSel<0:1> 2810. OpSel<0:1> 2810 may include two sub-signals, Opsel0 2806 and Opsel1 2808, which may be used to select among four input cases for AC MUXes 2722 to 2724 illustrated in FIG. 27. Signal Opsel1 2808 may be generated by taking a NOR of an enable signal En 2804 and a Shift_Load signal 2740. In contrast, Opsel0 2806 is generated by first taking a first NOR of a Shift_Load signal 2740 with a Left_Right signal 2742, followed by taking a second NOR of a result of first NOR and an enable signal En 2804. Truth table 2818 illustrates different logic operations of AC operation selector 2802, with an enable signal En 2804 configured as an active low. Although AC register file's enable signal En 2744 may operate in an active high mode, enable signals that may be produced after DEMUX 2720 (En0 2746 to En3 2752) may be active low and may function as En 2804 here.

When En 2804 is high (1), both operation selection signals Opsel0 2806 and Opsel1 2808 are low (0), selecting a first input of an associated AC MUX, which corresponds to an AC register output without any change, as shown in FIG. 27. Conversely, when En 2804 is low (0), and Shift_Load 2740 is low (0) while Left_Right 2742 is high (1), both Opsel0 2806 and Opsel1 2808 may become high (1), indicating a selection of fourth input for an associated AC MUX, which may use a right-shifted version of input data. Other logic cases are also illustrated in truth table 2818, providing a detailed overview of operation selector's functionality within AC-powered register file 2600.

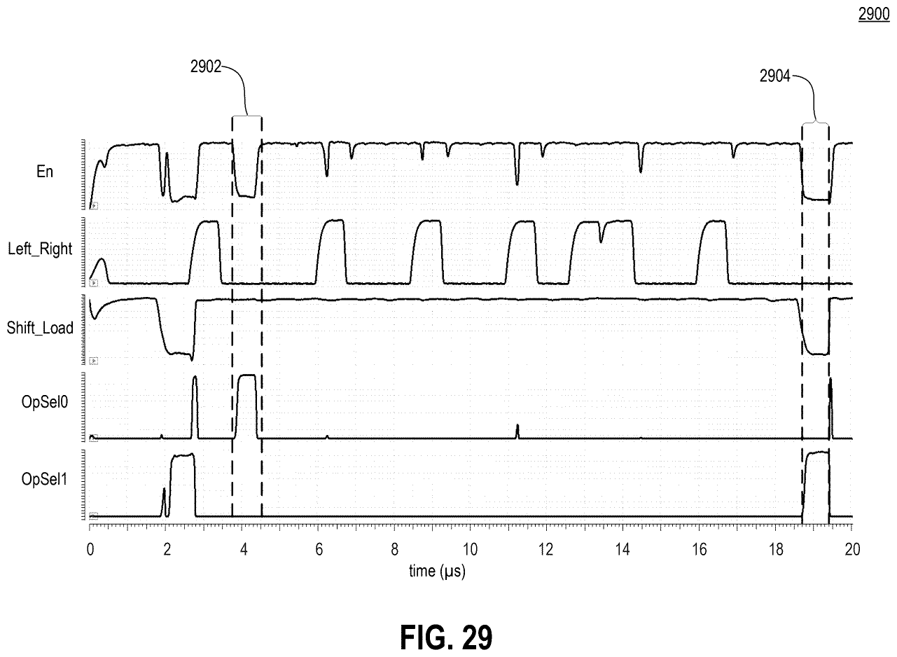

FIG. 29 is a plot 2900 of an output from the AC-powered operation selector 2802 depicted in FIG. 28, based on applied input signals En 2804, Left_Right 2742, and Shift_Load 2740, in accordance with at least one example. Operation selector circuit 2802 may produce a two-bit output signal that may be composed of Opsel0 2806 and Opsel1 2808. During time interval 2902, input signal En 2804 is low (0), indicating that AC register file 2600 may be set to execute an instruction. A Shift_Load signal 2740 is high (1), indicating that new data needs be loaded into a designated AC register of an AC register file 2600; while a Left_Right signal 2742 is low (0), rendering it as a don't-care condition. Consequently, AC register file of FIG. 27 may become ready to load new data, represented as WRD<0:3> 2732, at a specified register address. Output signals Opsel0 2806 and Opsel1 2808 are 1 and 0, respectively, signifying that input selection MUX of an associated operation selector may utilize its second input. In FIG. 27, a second input for input selection MUXes, 2722 and 2724 may correspond to a new data WRD<0:3> 2732, which demonstrates that a desired instruction is executed correctly.

In time interval 2904, an input signal En 2804 remains low (0), indicating an operation will be performed, while Shift_Load 2740 is low (0), signaling a shift operation needs to be performed. A Left_Right signal 2742 is also low (0), which may encode a left shift operation. As a result, output signals Opsel0 2806 and Opsel1 2808 are 0 and 1, respectively, which may indicate that an associated MUX may select its third input. In FIG. 27, a third input for an input selection MUX 2722 may represent a left circular shifted signal Q0<3,0:2> 2760. This notation may indicate that a least significant bit (LSB) may become bit 3 (previously a most significant bit), while remaining bits 0, 1, and 2 may shift to next positions 1, 2, and 3, respectively.

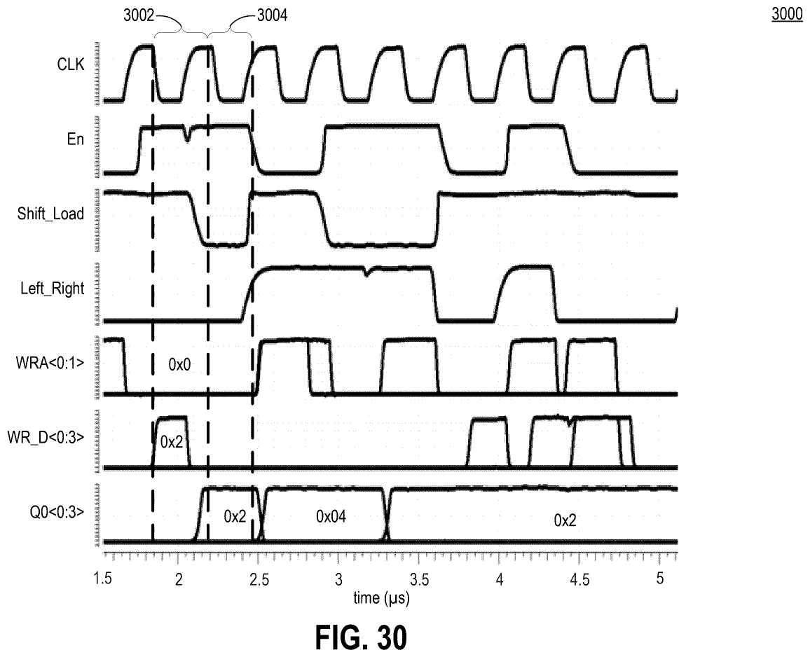

FIG. 30 is a plot 3000 illustrating a writing operation performed in e AC-powered register file 2600 of FIG. 27, in accordance with at least one example. Plot 3000 may include a clock signal CLK 2754 and an enable signal En 2744 that may be used as an input for DEMUX 2720 in an active high configuration, as shown in FIG. 27. Moreover, a Shift_Load 2740 and a Left_Right 2742 signals may be used to determine a desired operation, while a WRA<0:1> 2738 signal may be used to select a register's address for a desired operation. WRD<0:3> 2732 may represent data that needs to be loaded into an AC register file 2600, and Q0<0:3> 2756 may be its first register. During a time interval 3002, a signal En 2744 is high (1), indicating that AC register file 2600 may be set to perform an operation, while a Shift_Load 2740 signal is also high (1), indicating a load operation. Consequently, a Left_Right 2742 signal may become a don't-care and is low (0). WRA<0:1> 2738 signal may be set to 0x0, which may mean new data WRD<0:3> 2732 may be loaded into an AC register at an address 0x0, specifically in Q0<0:3> 2756. A WRD<0:3> 2732 may hold a value of 0x2, which may be stored in register Q0<0:3> 2756 at a subsequent clock edge. In a following time interval 3004, En 2744 signal may remain high (1), while Shift_Load 2740 signal may be low (0) and Left_Right 2742 signal may be also low (0). This configuration may determine that the data bits need to shift left. WRA<0:1> 2738 signal may remain at 0x0, meaning the same register Q0<0:3> 2756 may be used to perform a left shift operation, and WRD<0:3> 2732 signal may be treated as a don't-care and have a value of 0x0. As shown in plot 3000, a value stored in Q0<0:3> 2756 may shift left, changing from 0x2 to 0x4 at the next clock edge.

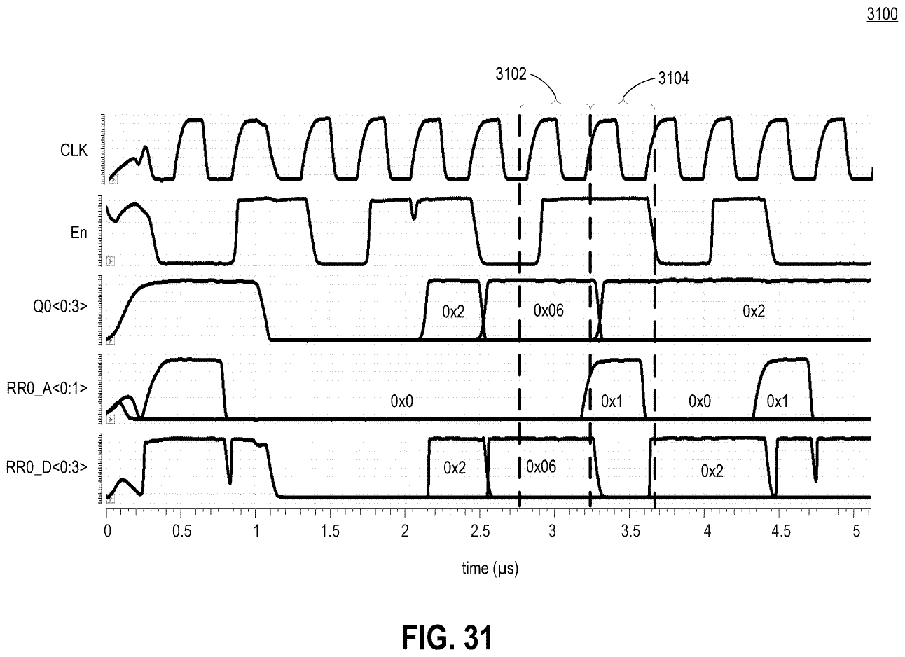

FIG. 31 is a plot 3100 depicting a read operation that may be executed in an AC-powered register file 2700 of FIG. 27, in accordance with at least one example. Plot 3100 may include a clock signal CLK 2754 and an enable signal En 2744, which may be used in an active low configuration. Data read as output may be represented by a signal RR0_D<0:3> 2758, while a 2-bit signal RR0A<0:1> 2726 may select an address of an AC register from which data needs to be read. During a time interval 3102, signal En 2744 may be high (1), indicating that the register file will perform an operation. At first, selected AC register may hold a value of 0x06, as indicated by a signal Q0<0:3> 2756. Signal RR0A<0:1> 2726 may be set to 0x0, indicating that data needs to be read from a first AC register of AC register file 2700. Its output may be represented by signal RR0_D<0:3> 2758, which may indicate a value of 0x06. In a subsequent time interval 3104, En signal 2744 may remain high (1), while signal Q0<0:3> 2756 may now indicate a value of 0x02. Notably, during this time interval, signal RR0A<0:1> 2726 may be set to 0x1, indicating that its output may not be read from register Q0<0:3> 2756. Consequently, an output signal RR0_D<0:3> 2758 may be 0, showing that it may not be possible to retrieve data is retrieved from a selected AC register of AC register file 2700.

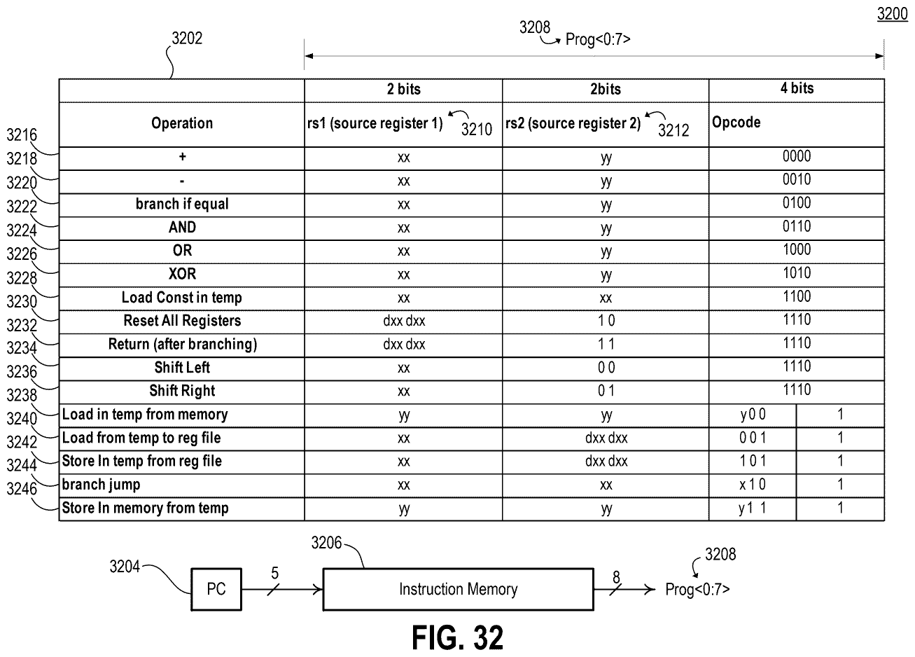

FIG. 32 shows a table 3200 of at least one example instruction set architecture (ISA) 3202 of at least one example of a 4-bit AC-powered nano-processor 182. ISA 3202 may also include 8-bit instructions that may encode various operations, including arithmetic, logical, memory, and control operations. Some basic arithmetic instructions may include addition 3216, subtraction 3218, a comparison for branch if equal 3220, some basic logical instructions may include AND 3222, OR 3224, and XOR 3226. Moreover, some basic memory instructions may include load a constant into a temporary register 3228 (‘load const in temp’), reset all registers 3230, return to a previously stored address 3228 (return after branching) 3232, and two data shifts operations: shift left 3234 and shift right 3236. These instructions may be stored in an 8-bit instruction memory 3206 like Prog<0:7> 3208, which may be accessed using a program counter PC 3204, as illustrated in FIG. 11. For arithmetic and logical operations, 2-bit addresses of operand registers may be represented by ‘xx’ for a source register 3210 and ‘yy’ for a source register 3212, whereas ‘dxx’ may be indicated as don't care cases. In cases where one register address may be needed, bits for a first operand register 3210 and a second operand register 3212 may be utilized for encoding other relevant information. An instruction for loading a constant in a temporary register 3228 may utilize all 4 bits of both operands register fields for representing a constant data.

In at least one example, instructions for reset 3230, return 3232, shift left 3234, and shift right 3236 may utilize bits from an operand register 3212 (e.g., Prog<4:5>) as control signals. When data is transferred from an AC register file to an AC memory, an 8-bit instruction may use 4 bits for selecting an operation (or instruction) and 2 bits for an address of an AC register file, leaving 2 bits encoding a memory address. A source operand register address may be bypassed by using a temporary operand register as an intermediate temporary location, eliminating a need for addressing, since one temporary register may be present. Consequently, data transfer from an AC register file to an AC memory may be done in two steps: first, an instruction ‘Store in temp from reg file’ 3242 can move data from an AC register file to a temporary AC register, and then a second instruction ‘Store in memory from temp’ 3246 may transfer it from a temporary AC register to AC memory. For this operation, first instruction may use a source address from an AC register file that may be available in Prog<6:7>, while a second instruction may use a target memory address that may be available in Prog<3:7>. This may allow for a 32-register AC memory using 5 bits for memory addressing. Similarly, data transfer from an AC memory to an AC register file may also follow a two-step process: first execute instruction ‘load in temp from memory’ 3238 followed by executing a second instruction ‘load from temp to reg file’ 3240. Program branching may also be conducted in two steps: first execute ‘branch if equal’ instruction 3220 by comparing operands in a source register 3210 with that of source register 3212, and subsequently setting a flag bit (beq) based on an outcome of a comparison. A subsequent instruction ‘branch jump’ 3244 then may transfer control to a specified target address. A return address from the branch if equal instruction may be stored in a special AC register, which may allow a return instruction 3232 to redirect control back to an instruction just after a branch instruction.

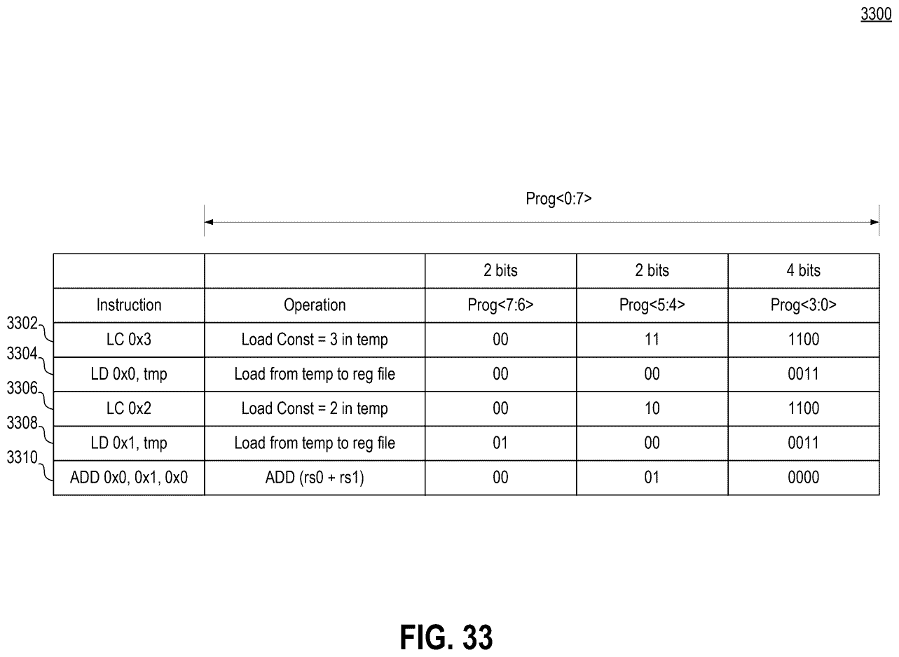

FIG. 33 is a table 3300 of sample instructions that may load data into registers and then execute arithmetic operations using an instruction set architecture from FIG. 32, in accordance with at least one example. A first instruction 3302 may load a constant value of 0x3 into a temporary AC register. A second instruction 3304 may transfer this value from a temporary AC register into an AC register, located at address 0x0, in an AC register file. A third instruction 3306 may load another constant value of 0x2 into a temporary AC register, followed by a fourth instruction 3308, which may move this value into an AC register, located at address 0x1, in an AC register file. A fifth instruction 3310 may perform an addition of two values stored in two AC registers and then may store result back into an AC register in an AC register file located at address 0x0. Instructions outlined in FIG. 33 may illustrate the functionality of an ISA in executing meaningful instructions (or operations). In at least one example, AC-powered nano-processor 182 may run any sequence of instructions to implement a useful application.

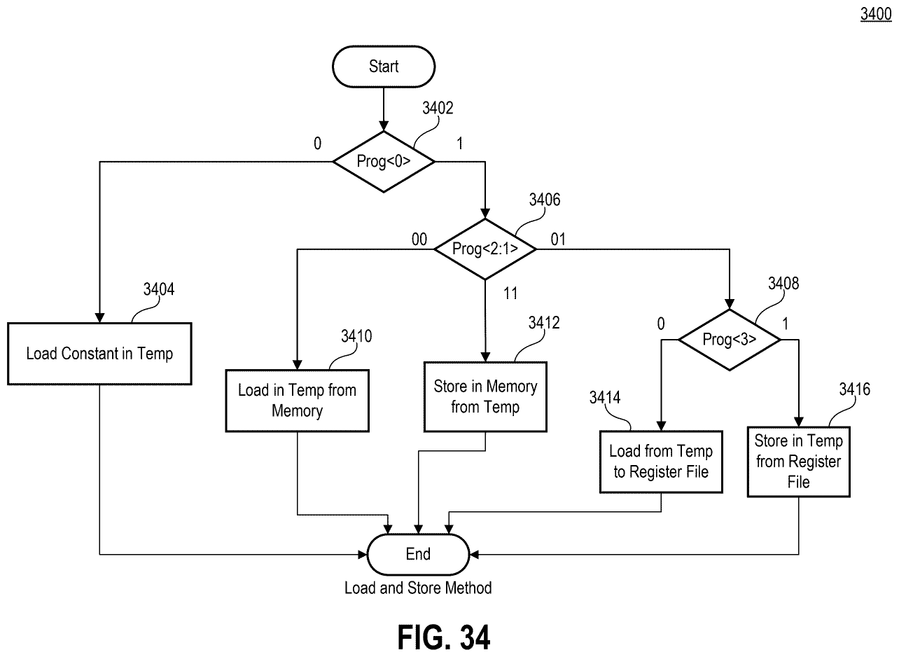

FIG. 34 is a flowchart 3400 illustrating a method of loading and storing data in an AC-powered nano-processor 182 using encoding as defined in instruction set architecture (ISA) 3202 shown in FIG. 32, in accordance with at least one example. Prog<0:3> bits may select between various memory operations. If Prog<0> is 0, an operation to load a constant into a temporary register may be selected at box 3404, as indicated by a decision box 3402. If Prog<0> is 1, decision box 3402 may proceed to further evaluate two bits of Prog<2:1> in a decision box 3406. If Prog<2:1> is 00, data may be loaded into a temporary AC register at box 3410. If Prog<2:1> is 11, data may be stored in a data memory from a temporary AC register at box 3412. If Prog<2:1> is 01, a decision box 3408 may check a bit Prog<3>. If Prog<3> is 0, data may be loaded from a temporary AC register into an AC register file at box 3414. Conversely, if Prog<3> is 1, data may be stored into a temporary AC register from an AC register file at box 3416.

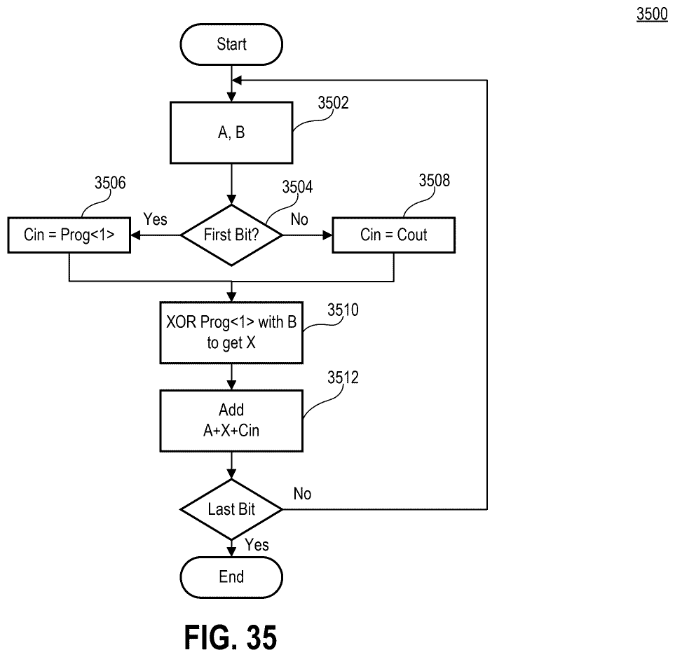

FIG. 35 is a flowchart 3500 illustrating a method for executing addition and subtraction instructions (or operations) in an AC-powered nano-processor 182, in accordance with at least one example. Inputs A and B are fetched at box 3502, followed by selecting a carry-in (Cin) bit based on position of bits being processed in a decision box 3504. If a bit being processed is the first bit (e.g., a least significant bit LSB), then at box 3506, Cin may be set to Prog<1>. If it is not a first bit, then at decision box 3508, Cin may be taken as carry-out (Cout) from a previous stage. At box 3510, Prog<1> bit may be XORed with a second input B to obtain a signal X. If Prog<1> is 0 (indicating addition), B may be passed through unchanged. If Prog<1> is 1 (indicating subtraction), B may be inverted using one's complement method. At box 3512, input A and signal X are added along with Cin, which for a first bit depends on Prog<1> to pad additional 1's in two's complement during a subtraction operation. Until a last bit is received, this process may be repeated by taking Cout from a predecessor stage as Cin for a current stage. Once last bit is received, addition or subtraction process may end.

In at least one example, in case of an addition operation, an instruction 3310 shown in FIG. 33 may add two numbers, 0x2, and 0x3. Here, a first input A is 0x2 (4′b0010), and a second input B is 0x3 (4′b0011). For a first bit case, Cin (Prog<1>) is selected as 0 according to a binary coded instruction 3310. When instruction 3310 is XORed with a second input B (4′b0011) at box 3510, a resulting signal X with a value of 4′b0011 is generated. This signal may then be added to Cin and A at box 3512, yielding a final result of 4′b0101.

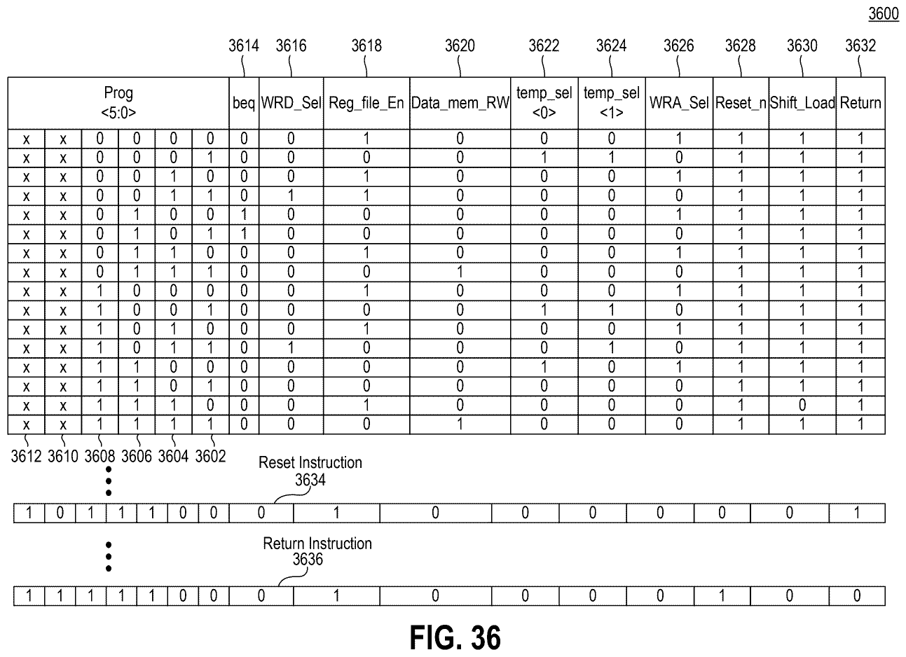

FIG. 36 is a table 3600 of a control circuit that may generate signals corresponding to specific tasks, in accordance with at least one example. An AC control circuit may utilize bits Prog<0> 3602, Prog<1> 3604, Prog<2> 3606, Prog<3> 3608, Prog<4> 3610, and Prog<5> 3612 from an instruction Prog<0:7> 3208 to produce control signals. It generates a Reset_n signal 3628 to reset all AC registers, a beq signal 3614 for branch instructions, and a Return signal 3632. For operations on a register file, control circuit may produce a Reg_file_En signal 3618 to enable or disable various operations, a WRD_Sel signal 3616 for selecting data that needs to be written into an AC register file, and a WRA_Sel signal 3626 for choosing an address of an AC register in an AC register file where data needs to be written. Additionally, a Shift_Load signal 3630 may control shifting or loading within an AC register file. Type of a shift operation, either left or right may be determined by the Prog<4> bit 3610, which may feed directly into an AC register file.

In at least one example, control circuit may also generate a Data_mem_RW signal 3620 to control the read/write operations of an AC data memory and produces AC control signals for a temporary AC register, allowing it to select from four different combinations of two inputs: temp_sel<0> 3622 and temp_sel<1> 3624. A temporary register may receive an input from an AC register file, instructions at Prog<4:7>, an AC data memory, or maintain its previous state based on various signal values. FIG. 36 illustrates selected cases focusing on first sixteen cases that may utilize signals Prog<0> 3602, Prog<1> 3604, Prog<2> 3606, and Prog<3> 3608. Moreover, two use cases—3634 for a reset instruction and 3636 for a return instruction—may use extra bits Prog<4> 3610 and Prog<5> 3612.

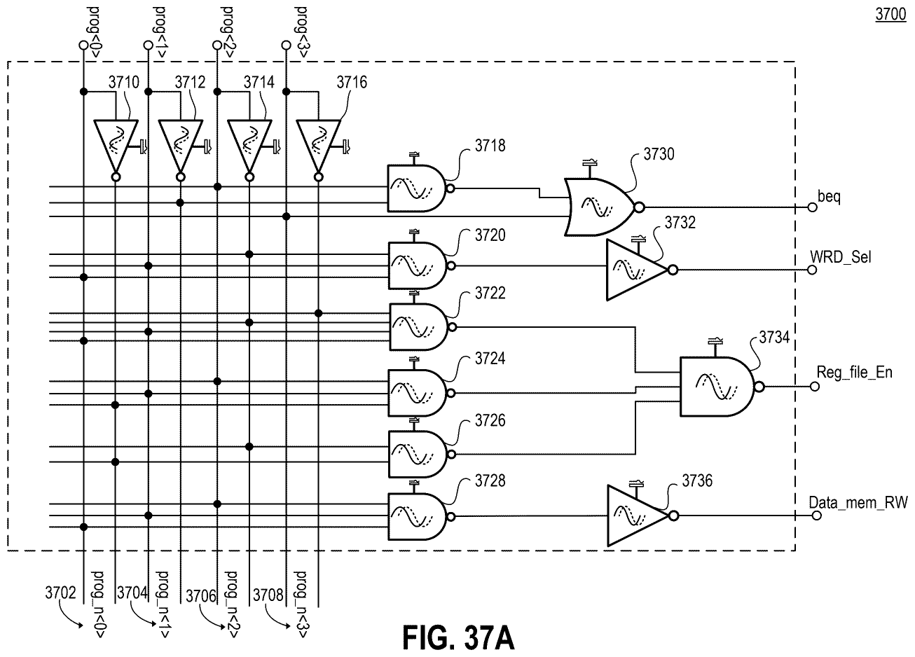

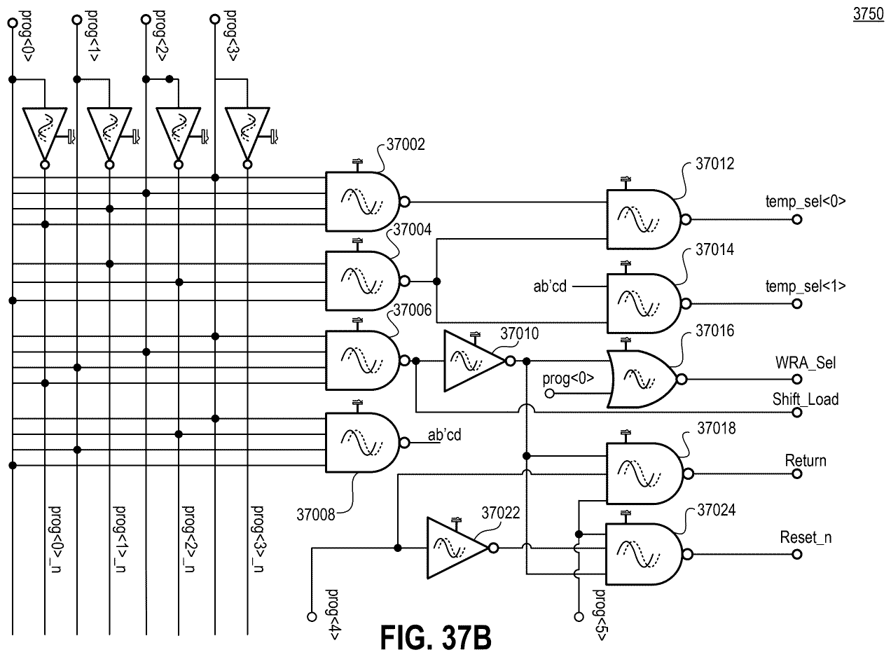

FIG. 37A is a circuit 3700 of a first half of an AC control circuit for an AC-powered nano-processor 182, in accordance with at least one example. AC control circuit may function in a similar manner as that of a typical decoder circuit, utilizing AC control signals prog<0> 3602, prog<1> 3604, prog<2> 3606, prog<3> 3608, and their inverted counterparts prog_n<0> 3702, prog_n<1> 3704, prog_n<2> 3706, prog_n<3> 3708 to generate control signals WRD_Sel 3616, Reg_file_En 3618, and Data_mem_RW 3620. Input signals prog<0> 3602, prog<1> 3604, prog<2> 3606, and prog<3> 3608 may be sourced from an AC program memory and are inverted by AC inverters 3710, 3712, 3714, and 3716, respectively, to produce AC signals prog_n<0> 3702, prog_n<1> 3704, prog_n<2> 3706, and prog_n<3> 3708. AC control signals are then generated by processing these input signals using AC logic gates, specifically NAND gates 3718, 3720, 3722, 3724, 3726, 3728, and 3734, an AC NOR gate 3730, and additional AC inverters 3732 and 3736, according to a truth table provided in FIG. 36.

FIG. 37B is a circuit 3750 of a second half of an AC control circuit for an AC-powered nano-processor 182, in accordance with at least one example. AC Control signals prog<0> 3602, prog<1> 3604, prog<2> 3606, prog<3> 3608, prog<4> 3610, and prog<5> 3612, along with their inverted counterparts prog_n<0> 3702, prog_n<1> 3704, prog_n<2> 3706, and prog_n<3> 3708, may be utilized to generate control signals temp_sel<0> 3622, temp_sel<1> 3624, WRA_Sel 3626, and Reset_n 3628. These control signals may be produced using AC NAND gates 37002, 37004, 37006, 37008, 37012, 37014, 37018, and 37024, and as AC inverters 37010 and 37022 and an AC NOR gate 37016. Logical configurations presented in FIG. 37A and FIG. 37B may be simplified into a NAND form of a sum of products based on logical circuits that are derived from a truth table shown in FIG. 36.

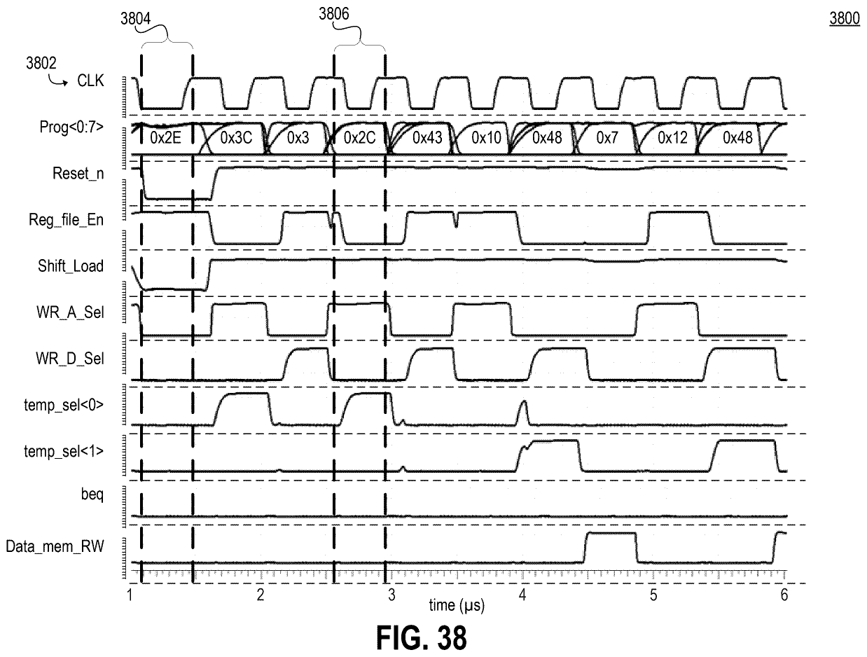

FIG. 38 is a plot 3800 of an output of AC control circuits of FIG. 37A and FIG. 37B, in accordance with at least one example. Signal 3802 CLK represents a clock signal that may be utilized by an AC program counter of an AC instruction, while signal Prog<0:7> 3208 may be an output from an AC instruction memory that may serve as an input to an AC control circuit. AC control circuit may generate various signals, including Reset_n 3628, Reg_file_En 3618, Shift_Load 3630, WR_A_Sel 3626, WR_D_Sel 3616, temp_sel<0> 3622, temp_sel<1> 3624, beq 3614, and Data_mem_RW 3620, which may be used by various components of a data path to perform different operations. In at least one example, Reset_n 3628 may be an active low signal that may reset all AC registers in an AC register file, and Reg_file_En 3618 may enable or disable it. Shift_Load 3630 may select between shifting and loading operations, while WR_A_Sel 3626 and WR_D_Sel 3616 may designate an address of an AC register in an AC register file for storing operations and source operand(s), respectively. Temp_sel<0> 3622 and temp_sel<1> 3624 may be used to select among between cases for a given temporary register: maintaining its value, loading a constant directly from an instruction, loading from an AC register file, or loading from an AC data memory. Signal beq 3614 may initiate branching instructions, and Data_mem_RW 3620 may indicate whether data needs to be written to or read from an AC SRAM-based data memory. During a time interval 3804, an instruction stored in Prog<0:7> 3208 is 0x2E (8′b00101110), with an opcode of Prog<0:3> 3214 is 1110 and Prog<5> 3610 is 1, thus initiating a reset operation as per ISA 3202 of FIG. 32. Consequently, control signal Reset_n 3628 is 0 during interval 3804. In time interval 3806, an instruction code is 0x2C (8′b00101100), where opcode Prog<0:3> 3214 is 1100, indicating a load of a constant number in a temporary AC register, and its constant value 4′b0010 (0x2) may be stored in Prog<4:7>. During this time interval 3806, Reset_n 3628 is 1 (no reset), Reg_file_En 3618 is 0 (as operation gets executed using a temporary register), Shift_Load 3630, WR_A_Sel 3626, and WR_D_Sel 3616 signals are don't care conditions. Temp_sel<0> 3622 signal is 1 and temp_sel<1> 3624 is 0, indicating a temporary AC register may use its second case to load a value from an instruction. Both beq 3614 and Data_mem_RW 3620 signals are 0, which may put AC nano-processor 182 in a read mode.

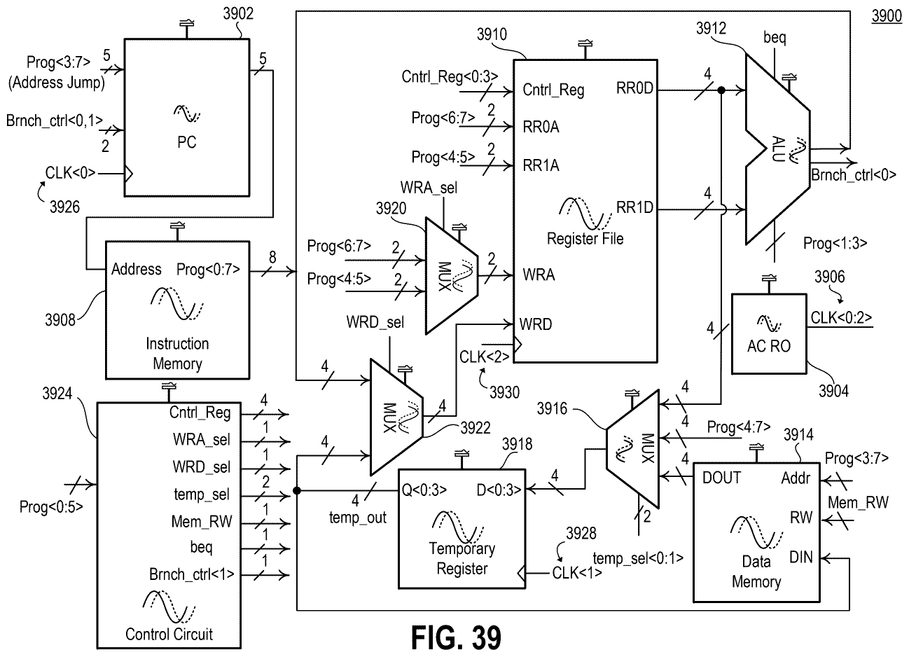

FIG. 39 is a block diagram 3900 of an AC-powered data path comprising AC-powered control blocks, memory blocks, and an arithmetic-logic unit (ALU), in accordance with at least one example. Data path may include an AC ring oscillator 3904, a 4×4 AC register file 3910, a 4-bit AC ALU 3912, a 4-bit AC temporary register 3918, a 4×32 AC SRAM-based data memory 3914, an 8×32 AC instruction memory 3908, a 5-bit AC program counter (PC) 3902, a 2-bit AC multiplexer (MUX) 3920 for selecting an address of an AC write register, two 4-bit AC MUXes 3922 for selecting data bits to be written in a write register, and an AC MUX 3916 for selecting an input to AC temporary register 3918, along with an AC control circuit 3924. Data path may comprise various AC-powered components that are represented by their symbols as defined in FIG. 3A and FIG. 3B. In another example, AC program counter 3902 may correspond to an AC program counter 1128 of an example illustrated in FIG. 11, an instruction memory 3908 may be an example of an AC ROM 2042 illustrated in FIG. 20A, and AC control circuit 3924 may be examples of AC control circuits illustrated in FIG. 37A and FIG. 37B. An AC register file 3910 may be an example of an AC register file 2702 illustrated in FIG. 27, while an AC data memory 3914 may be an example of an AC memory circuit illustrated in FIG. 23. An ALU 3912 and an AC ring oscillator 3904 may be examples of AC ALU 1800 illustrated in FIG. 18 and AC-powered ring oscillator 908 illustrated in FIG. 9 respectively. Finally, AC MUXes 3920, 3922, and 3916 may be examples of AC MUX 502 illustrated in FIG. 5.

In at least one example, AC ring oscillator 3904 may generate three clock phases, CLK<0:2> 3906, using an example circuit illustrated FIG. 9. A first clock phase, CLK<0> 3926, may be used by an AC program counter 3902; a second phase, CLK<1> 3928 may be used by an AC temporary register 3918; and a third clock phase CLK<2> 3930 may be used by an AC register file 3910. These distinct clock phases may help in removing timing violations within a data path of an AC-powered nano-processor 182. Once an instruction starts executing, first phase CLK<0> 3926 has a positive edge, AC program counter 3902 may generate a desired address in AC instruction memory 3908, fetching a corresponding instruction. AC Control circuit 3924 may subsequently generate the control signals for various AC components of a data path of an AC-powered nano-processor 182. Data is then loaded from an AC register file 3910 using AC MUXes, and an ALU 3912 may perform an operation that is encoded in an instruction. When a positive edge of a second phase CLK<1> 3928 arrives, AC temporary register 3918 may receive its clock edge and subsequently may execute a desired operation. Finally, AC register file 3910 may also receive a positive edge of its clock from a third phase CLK<2> 3930 and then may perform its desired operation.

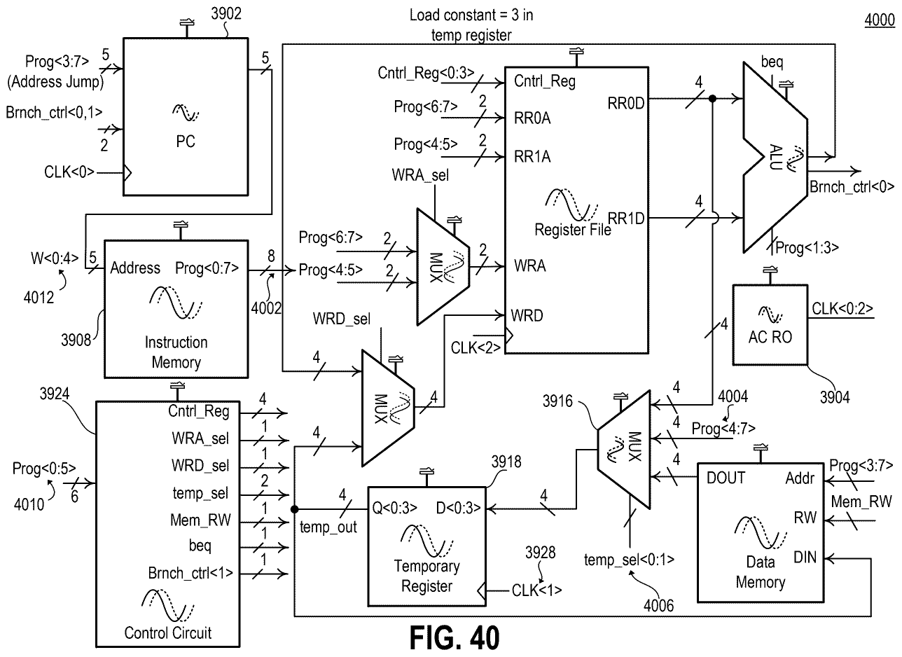

FIG. 40 is a circuit 4000 of an AC-powered data path for a first instruction 3302 of FIG. 33, in accordance with at least one example. AC data path components that may be active during this time interval may include: an AC ring oscillator 3904, an AC program counter (PC) 3902, an AC instruction memory 3908, an AC control circuit 3924, an AC temporary register 3918, and an AC multiplexer (MUX) 3916. AC ring oscillator 3904 may generate clock signals that may trigger various components of an AC data path. Program counter PC 3902 may contain an address of an instruction in AC instruction memory 3908. Using PC 3902 a 5-bit address W<0:4> 4012 may be generated of a load constant instruction and then form this address an 8-bit code prog<0:7> 4002 may be fetched. Program code prog<0:7> 4002 may include a 4-bit constant number prog<4:7> 4004 (both 4 and 7 bits are included). AC Control circuit 3924 may use signal prog<0:5> 4010 to generate a temp_sel<0:1> 4006 signal, which may be used for selecting an input data for a temporary AC register 3918. Temp_sel<0:1> 4006 signal may select a temporary AC register 3918 for storing input constant data prog<4:7> 4004 using MUX 3916, which may then be stored in temporary AC register 3918 on a next positive edge of clock CLK<1> 3928.

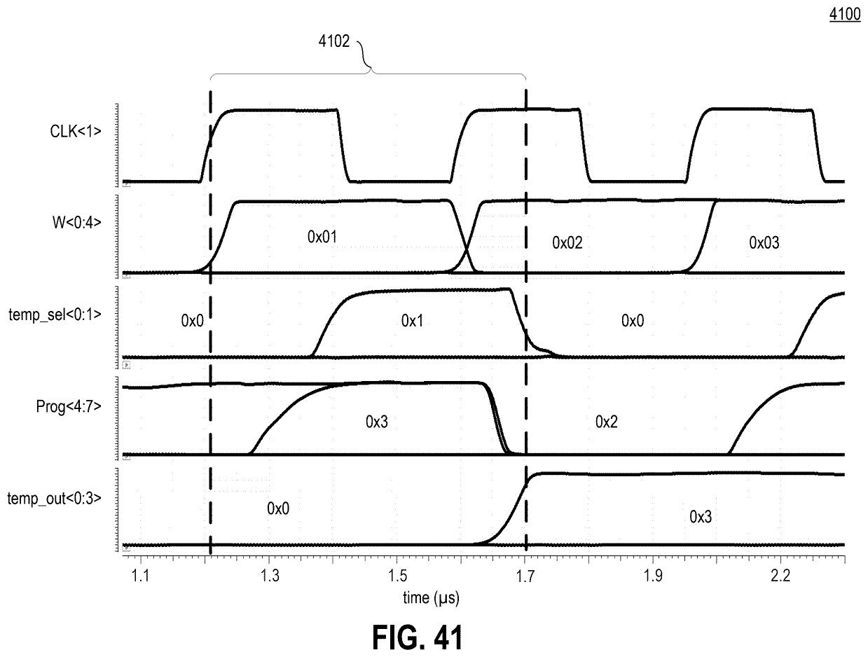

FIG. 41 is a plot 4100 of an output of an AC-powered data path illustrated in FIG. 40, in accordance with at least one example. A dotted section 4102 in a timing diagram may illustrate execution stage of a load instruction. Initially, a positive edge of a clock signal CLK<1> 3928 may increment an instruction address W<0:4> 4012, which may result in a change in an instruction value Prog<0:7> 4002. A constant value of 0x3 may be loaded in Prog<4:7> 4004, and a control signal for a temporary AC register 3918, temp_sel<0:1> 4006, may also change to 0x1. Ultimately, when a clock edge for a next instruction arrives, a constant value may be loaded into a temporary AC register 3918, as indicated by a signal temp_out<0:3>.

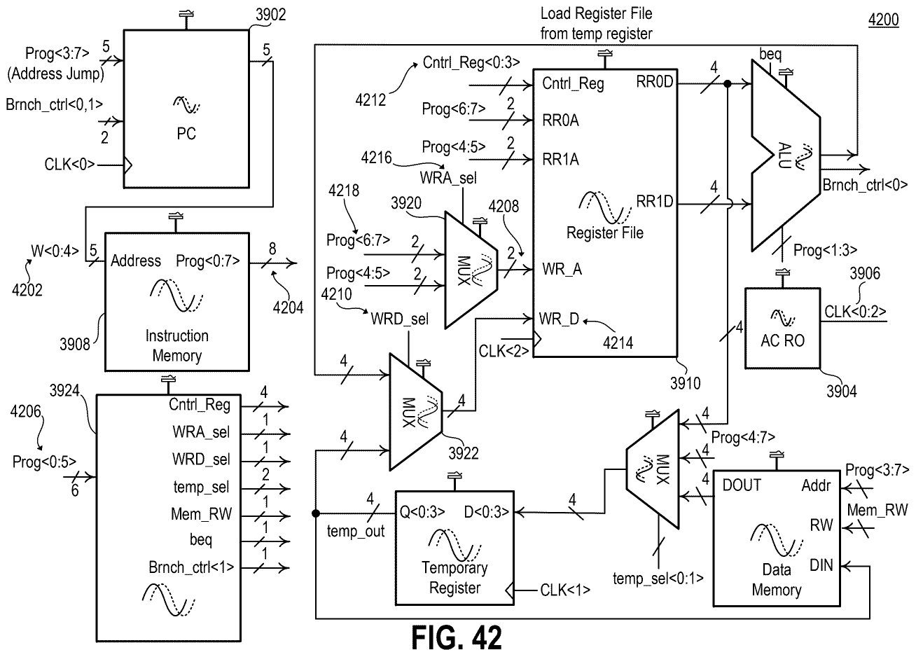

FIG. 42 is a circuit 4200 of an AC-powered data path for a second instruction of FIG. 33, in accordance with at least one example. Similar to the previous instruction, AC ring oscillator 3904 may generate a clock signal, and address W<0:4> 4202 bits of program counter 3902 may determine an address in instruction memory 3908 for reading data bits. 8-bit program code Prog<0:7> 4204 may be retrieved from instruction memory 3908 may include control signals Prog<0:5> 4206 for control circuit 3924 and a target address location for register file 3910 in Prog<6:7> 4218. 6-bit signal Prog<0:5> 4206 may be transferred to control circuit 3924, which may generate WRD_sel 4210 and WRA_sel 4216 select signals for MUX 3922 and MUX 3920, respectively. A source of data WR_D 4214 may be selected using WRD_sel 4210 signal, while a destination address may be selected using WRA_sel 4216 signal. Moreover, 4-bit register control signals Cntrl_Reg<0:3> 4212 may determine status of register file 3910 and then perform operations such as load/store, left shift, or right shift on the data.

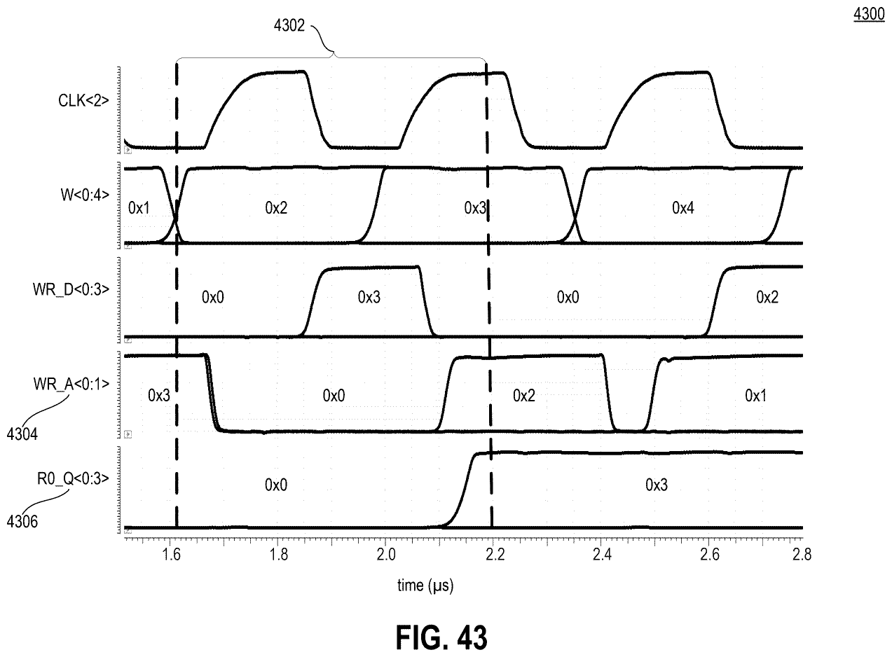

FIG. 43 is a plot 4300 of an output of an AC-powered data path of FIG. 42, in accordance with at least one example. A timing diagram may illustrate a sequence of signals once a second instruction is executed. Initially, during a time interval 4302, a WR_A 4304 signal may transition to 0x0, indicating that data may be stored in a first register (R0). This signal may direct a data flow within register file 3910, ensuring that a correct register is chosen for storing data. Subsequently, a register input data signal WR_D 4214 may change to 0x3, which may represent a value that needs be stored in a designated register. This transition shows that an AC-powered data path has completed its data selection and is now ready to latch its new value into an appropriate register. A new value may be latched to a first register, denoted as R0_Q 4306, on a next positive edge of CLK<2> 3930 clock signal once time interval 4302 ends. The timings of these signals' changes may determine an accurate operation of an AC-powered data path. Synchronization provided by clock signals may ensure that data may be stored at a precise time instant when needed, minimizing timing violations, and maximizing operational efficiency. A clear demarcation of various time intervals may also illustrate how an AC-powered architecture may remain responsive and manage execution of instructions. Output plot 4300 may show dynamic interactions between control signals and flow of data. In at least one example, an AC control circuit may be made responsible for managing signals of different data path components once instructions are executed.

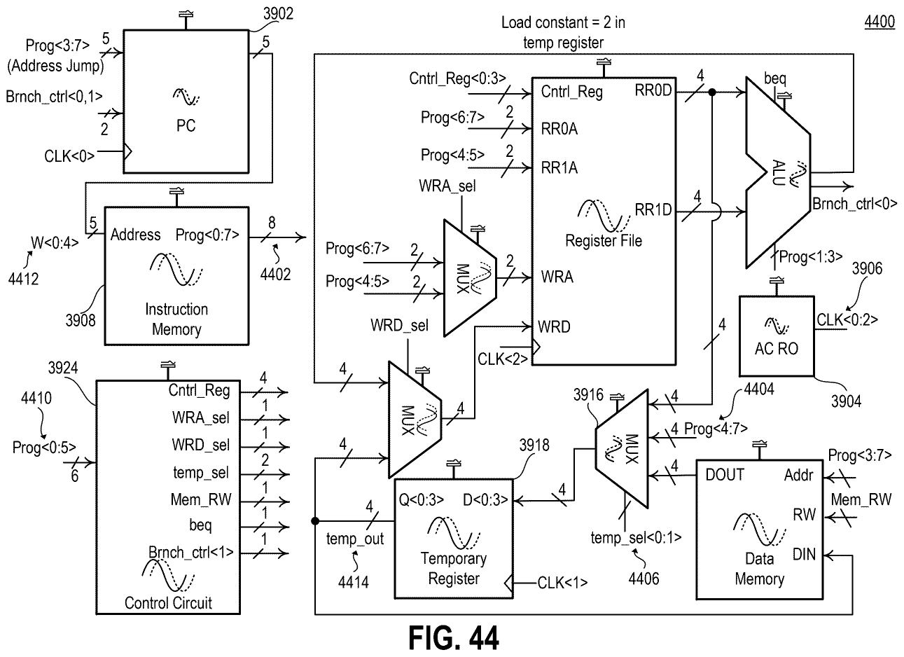

FIG. 44 is a circuit 4400 of an AC-powered data path for a third instruction of FIG. 33, in accordance with at least one example. As with previous instructions, active components during this operation may include AC ring oscillator 3904, AC program counter PC 3902, AC instruction memory 3908, AC control circuit 3924, AC temporary register 3918, and AC MUX 3916. AC ring oscillator 3904 may generate a clock signal to synchronize operations of various data path components. Using program counter PC 3902, instruction memory 3908 may be accessed at an address to retrieve an 8-bit code prog<0:7> 4402 associated with a load constant instruction, using a 5-bit address W<0:4> 4412 generated by program counter 3902. Program code prog<0:7> 4402 may contain a 4-bit constant number prog<4:7> 4404 for executing load constant instructions. Control circuit 3924 may process signal prog<0:5> 4410 to generate e temp_sel<0:1> 4406 signal, which is responsible for selecting an input data for temporary AC register 3918. In this instance, temp_sel<0:1> 4406 may select an input data prog<4:7> 4404, and select data bits using MUX 3916. Selected data may then be stored in a temporary register 3918 on a next positive edge of a clock signal CLK<1> 3928. Data can be retrieved as temp_out<0:3> 4414. This flow of operations may be needed to efficiently execute a load constant instruction. By ensuring that a correct constant is selected and loaded into a temporary AC register 3918, AC-powered data path can maintain its integrity and accuracy of executing instructions.

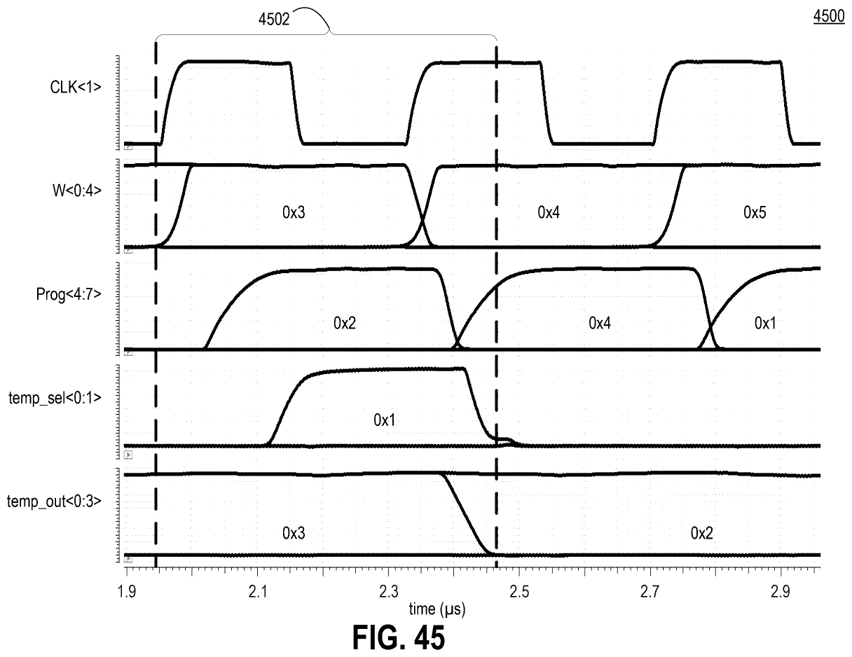

FIG. 45 is a plot 4500 of an output of an AC-powered data path of FIG. 44, in accordance with at least one example. In time interval 4502, a load instruction needs to be loaded. A control signal for this instruction may be accessed by setting value of W<0:4> 4412 bits to 0x3. time interval 4502, a 4-bit constant input data Prog<4:7> 4404, holding a value of 0x2, may be selected by MUX 3916, as select signal temp_sel<0:1> 4406 may transition to 0x1, allowing an input data to be moved to temporary AC register 3918. At a next positive edge of CLK<1> 3928, 4-bit constant data 0x2 can be latched into temporary AC register 3918. Consequently, data stored in temp_out<0:3> 4414 of temporary AC register 3918 may be replaced by a new data 0x2, demonstrating a successful execution of a load instruction.

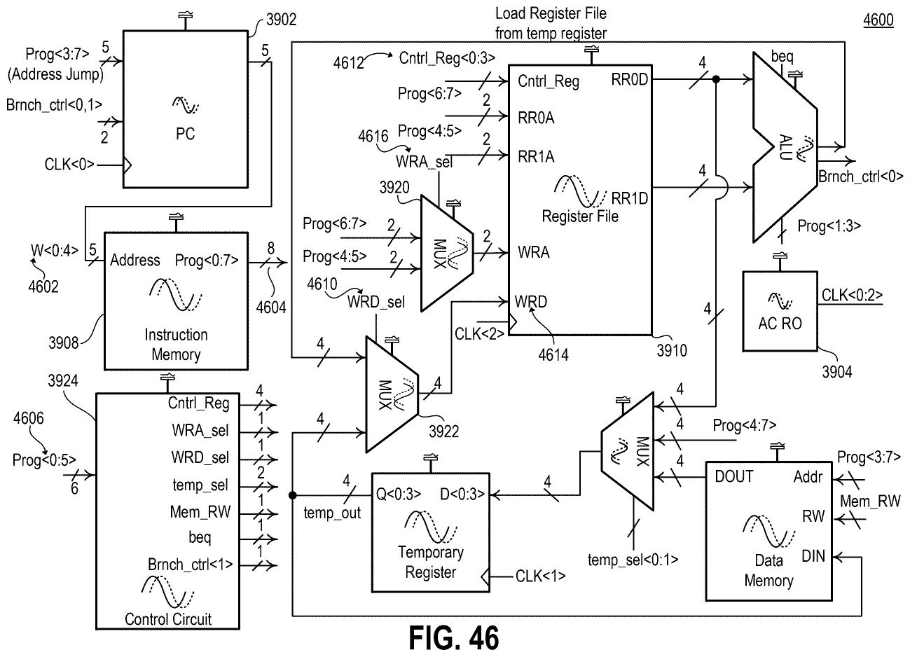

FIG. 46 is a circuit 4600 of an AC-powered data path for a fourth instruction of FIG. 33, in accordance with at least one example. AC ring oscillator 3904 may generate a clock signal, and address bits W<0:4> 4602 from program counter 3902 may determine an address of fourth instruction in instruction memory 3908. Similar to instruction 4204, as illustrated in FIG. 42, a 8-bit program code Prog<0:7> 4604 may be fetched from instruction memory 3908 that may also include control signals Prog<0:5> 4606 for control circuit 3924, as well as a target address location for register file 3910 in bits Prog<6:7> 4618. 6-bit signal Prog<0:5> 4606 may be transferred to control circuit 3924, which may generate a WRD_sel 4610 and a WRA_sel 4616 select signals for MUX 3922 and MUX 3920, respectively. A source of data may be selected using WRD_sel 4610 signal, determining from which register in AC register file 3910 to read data bits WR_D 4614. In parallel, a destination address for an associated operation may be selected by a WRA_sel 4616 signal, indicating an address of a register in AC register file 3901 for storing a result of associated operation. Additionally, a 4-bit register having a state of control signals Cntrl_Reg<0:3> 4612 may manage an operation of AC register file 3910 and may perform tasks such as load/store operations or left/right shifts on the data.

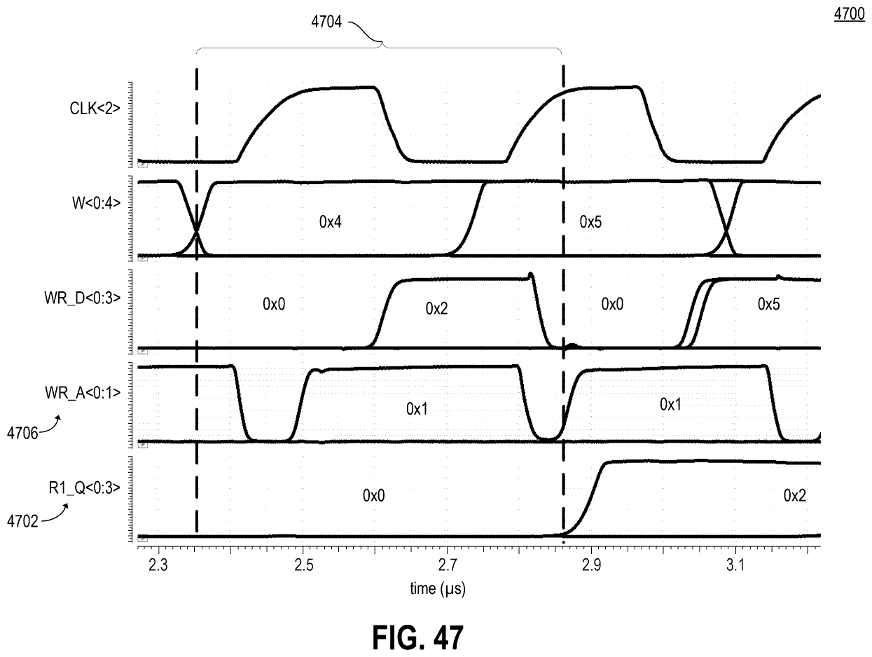

FIG. 47 is a plot 4700 of an output of an AC-powered data path of FIG. 46, in accordance with at least one example. During time interval 4704, WR_A<0:1> 4706 signal may transition to 0x1, indicating that data needs to be stored in a second register (R1). Following this, a value of register input data WR_D 4614 may change to 0x2. This value is then latched into AC register R1_Q 4702 of register file 3910 on a subsequent positive edge of a clock signal CLK<2> 3930. The timing diagram illustrates synchronization between control signals and clock cycles, ensuring correct reading of data may at an appropriate moment in an instruction cycle.

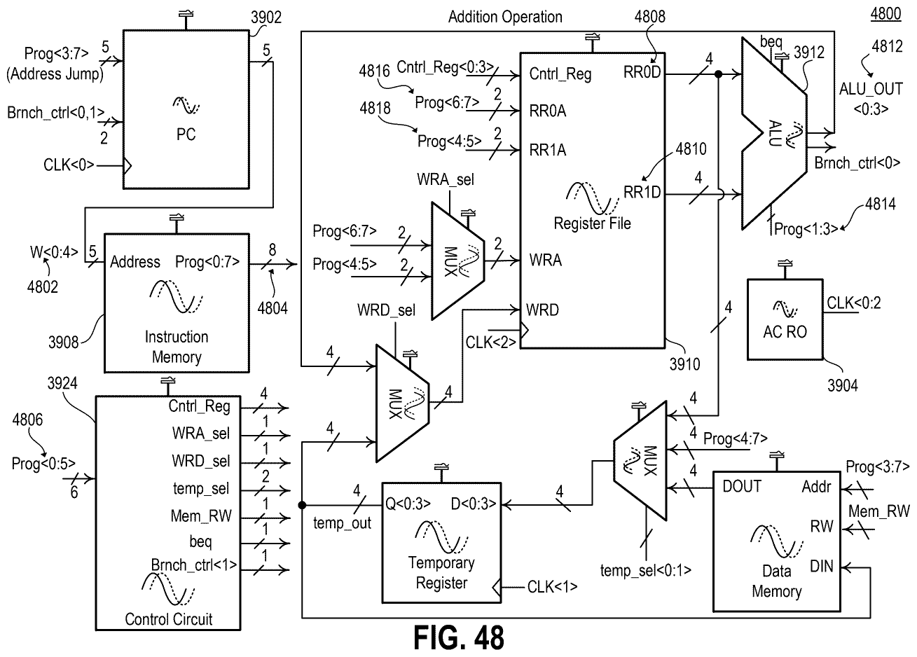

FIG. 48 is a schematic of a circuit 4800 of an AC-powered data path for a fifth instruction of FIG. 33, in accordance with at least one example. AC ring oscillator 3904 may generate as a clock signal, producing clock signal 3906 that may drive program counter PC 3902. Program counter 3902 may utilize address signal bits W<0:4> 4802 to access instruction 3310 from instruction memory 3908. First five bits of an instruction Prog<0:7> 4804, specifically Prog<0:5> 4806, may be transmitted to control circuit 3924, which may generate control signals for correctly executing 5^{th} instruction. During this execution, register file 3910 reads outputs RR0D 4808 and RR1D 4810 using a register read addresses Prog<6:7> 4816 and a Prog<4:5> 4818 respectively. ALU control signal Prog<1:3> 4814 may select an addition operation, directing ALU 3912 to perform a computation. A result of addition output, ALU_OUT<0:3> 4812, may subsequently be stored back into AC register file 3910 for a future use. Circuit 4800 illustrates an efficient flow of data and control signals within an AC-powered data path, ensuring a proper execution of arithmetic operations while adhering to the timing constraints of a clock signal.

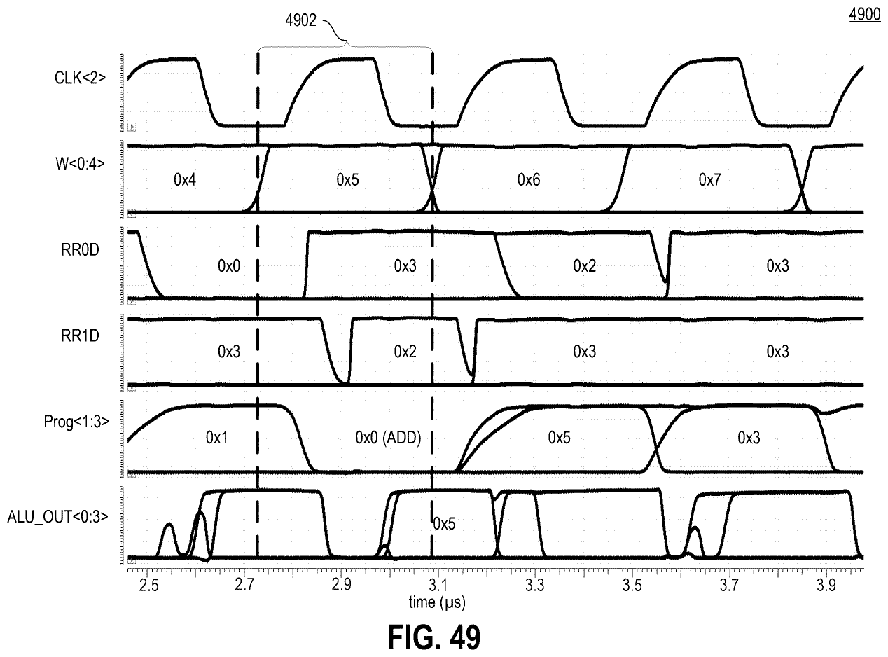

FIG. 49 is a plot 4900 of an output of an AC-powered data path of FIG. 48, in accordance with at least one example. The dotted section 4902 highlights a timing diagram segment during which an addition operation may be executed. Program counter 3902 may read a program code from instruction memory 3908 when address W<0:4> 4802 may be set to a value of 0x5. Now, value in register R0, represented as RR0D 4808, is 0x3; while register R1, denoted as RR1D 4810 may hold a value of 0x2. An addition operation may be triggered when an ALU control signal Prog<1:3> 4814 may transition to 0x0, indicating that ALU 3912 may perform a specified operation. Output ALU_OUT<0:3> 4812 may reflect a sum of two 4-bit inputs, yielding a result of 0x5. This output can confirm a successful execution of an addition operation within AC-powered data path, demonstrating capability to do arithmetic calculations as intended.

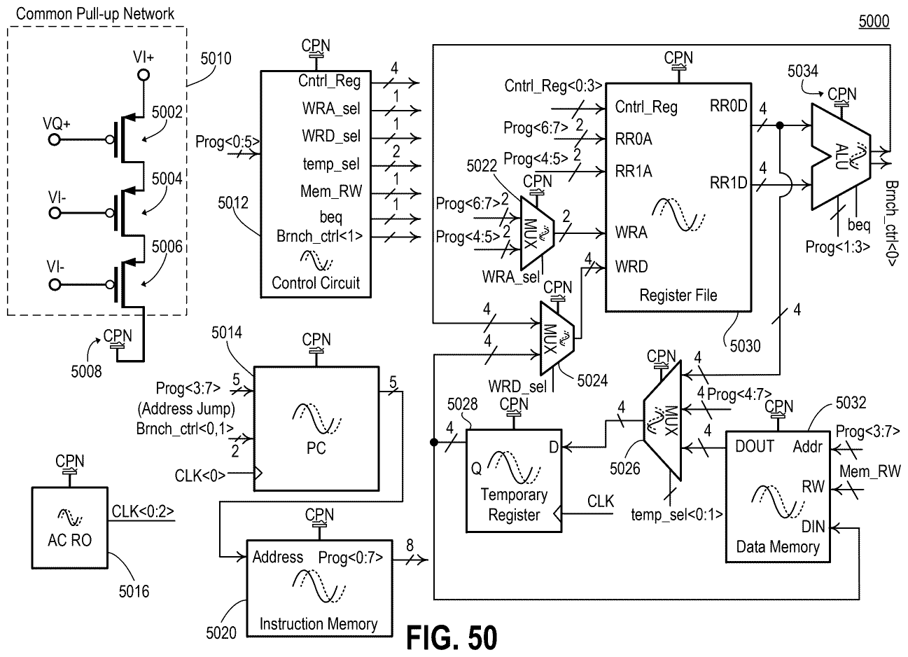

FIG. 50 is a circuit 5000 that illustrates an example structure of AC-powered nano-processor 182, wherein a pull-up network and/or an IQ power port may be used, with larger transistors, to power a data path of FIG. 39, in accordance with at least one example. In previous examples of an AC-powered data path of an AC nano-processor 182 is illustrated in FIG. 39, wherein an individual component may utilize an IQ power port 166 to efficiently and effectively utilize different AC phases. While this configuration may provide a strong signal integrity, it may significantly increase both a number of transistors and a power consumption for each component. In the example of FIG. 50, a common pull-up network (CPN) 5010 may be used, which may be designed to reduce a total number of transistors and power consumption across nano-processor 182. A CPN may comprise transistors 5002, 5004, and 5006, receiving input signals VI+ 134, VQ+ 146, and VI− 136. This network may generate a common pull-up node CPN 5008, which may supply power to all AC circuits of nano-processor 182. An individual circuit component may be connected to a node and CPN may draw power from this common pull-up network. An operational function of remaining components—such as AC control circuit 5012, AC program counter 5014, AC clock generation circuit 5016, AC instruction memory 5020, AC multiplexers (MUXes) 5022, 5024, and 5026, an AC temporary register 5028, an AC register file 5030, an AC data memory 5032, and an AC arithmetic-logic unit (ALU) 5034. This circuit schematic may remain consistent with an example of FIG. 39. This new layout design may enhance its efficiency, while still maintaining the desired operational characteristic of AC-powered nano-processor 182.

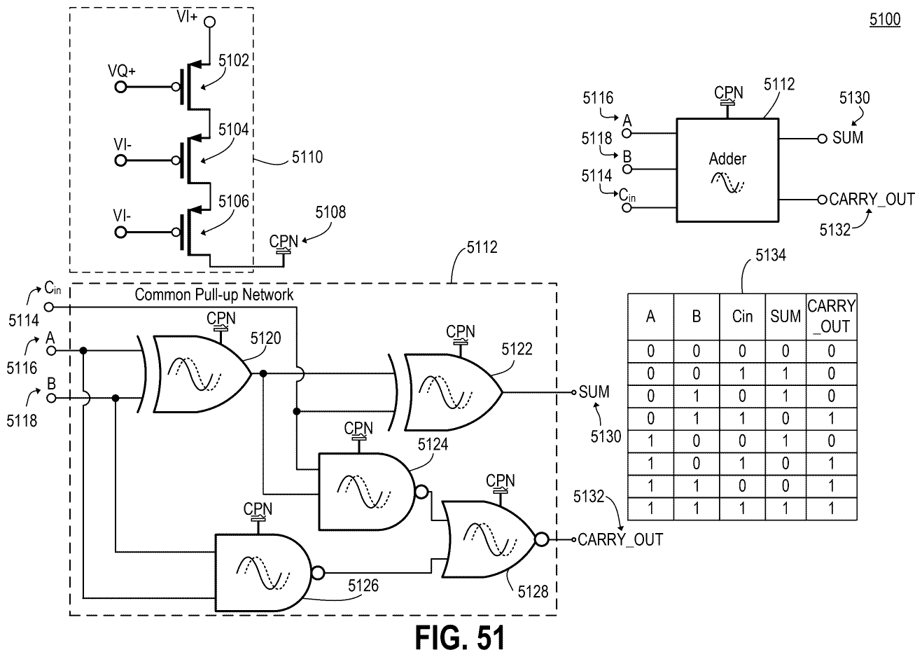

FIG. 51 is a circuit schematic 5100 of an AC-powered full adder 5112, wherein all AC logic gates of AC-powered full adder of FIG. 13 may share a single IQ power port, in accordance with at least one example. A common pull-up network 5110 may reduce a total number of transistors that may be needed by individual logic gates 5120, 5122, 5124, 5126, and 5128; thereby improving area and power efficiency. Common pull-up network 5110 may utilize three PMOS transistors 5102, 5104, and 5106, which may be activated by AC signals VI+ 134, VQ+ 146, and VI− 136 to generate a stable power signal at common pull-up node CPN 5108 for an AC full adder circuit 5112. AC adder circuit 5112 may receive three inputs: A 5116, B 5118, and Cin 5114, and may generate a sum output 5130 and a carry-out signal 5132. Additionally, a truth table 5134 may be provided, illustrating an input and output response of an AC full adder circuit 5112. A truth table may confirm that AC-powered full adder 5112 may provide a functionality of a conventional full adder circuit, demonstrating its effectiveness in performing arithmetic operations when utilizing a shared pull-up configuration to enhance power efficiency and reducing count of circuit components.

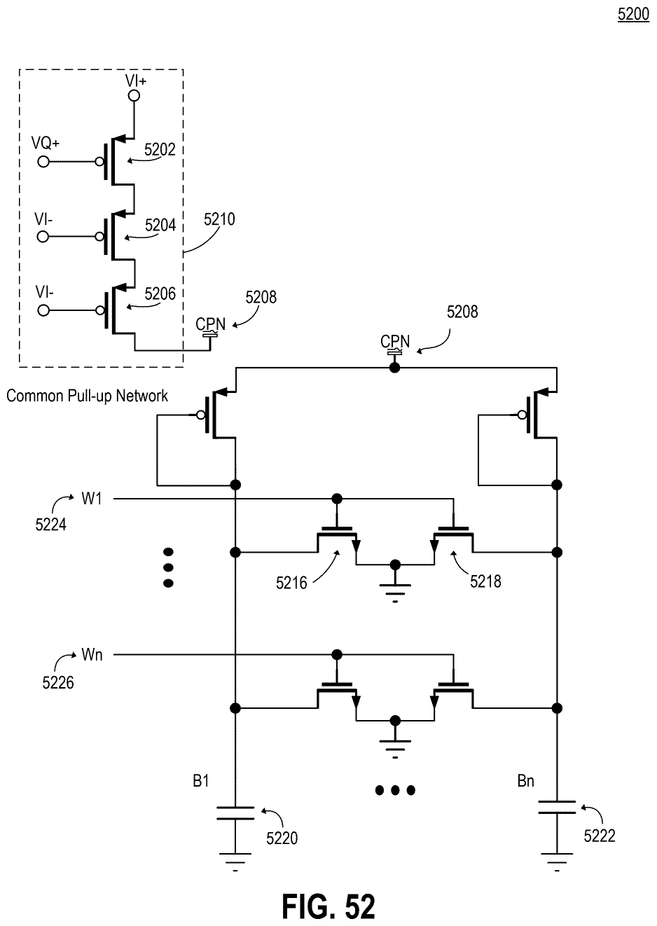

FIG. 52 is a schematic of an AC instruction memory circuit 5200, wherein each bit line of an instruction memory of FIG. 20A may share a single IQ power port, in accordance with at least one example. Bit lines, ranging from B1 5220 to Bn 5222, may be charged through a common pull-up network 5210, rather than using individual pull-up networks as shown in FIG. 20A. A pull-up network may comprise three PMOS transistors 5202, 5204, and 5206, which may be activated by three AC signals—VI+ 134, VQ+ 146, and VI− 136—to generate a stable power signal at a common pull-up node CPN 5208 for a circuit of AC instruction memory 5200. Selection of memory addresses may be done using memory word lines from W1 5224 to Wn 5226. Instruction memory can be programmed by either removing or retaining transistors 5218 and 5216. If a transistor is removed, a transistor stores a ‘1’, while if it is kept, it stores a ‘0’ in a memory. Once a specific word line is selected, such as W1 5224, a corresponding memory location may be accessed.

FIG. 50, FIG. 51, and FIG. 52 illustrate examples of different circuits that may use a common pull-up network (CPN). However, CPN configuration may also be used by all components of an example illustrated in FIG. 39, highlighting its efficiency in enhancing an overall circuit performance; while reducing a count of transistors in various components of circuits.

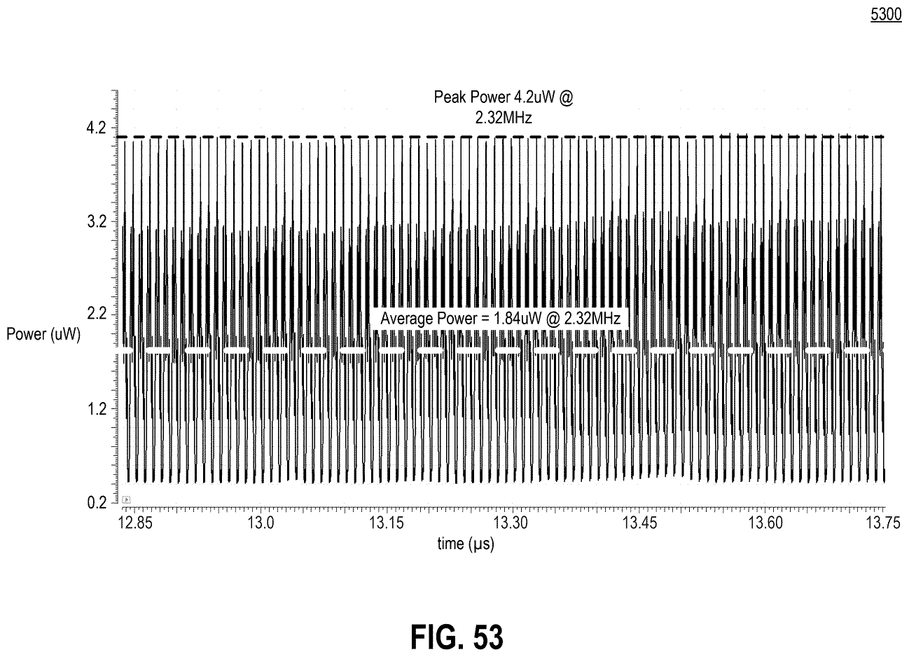

FIG. 53 is a plot 5300 of a power consumption profile of an AC-powered nano-processor 182 of FIG. 39 while executing instructions from instruction set of FIG. 32, in accordance with at least one example. A plot may illustrate metrics, including a peak power consumption of 4.2 μW and an average power consumption of 1.84 μW, once AC-powered nano-processor 182 is operating at a clock frequency of 2.32 MHz. A comparatively high-power consumption may be attributed to each AC logic gate that may be powered by its dedicated separate pull-up network, which may increase overall compute efficiency of nano-processor components but may also result in consuming more power illustrating a trade-off between a nano-processor's performance and its power efficiency.

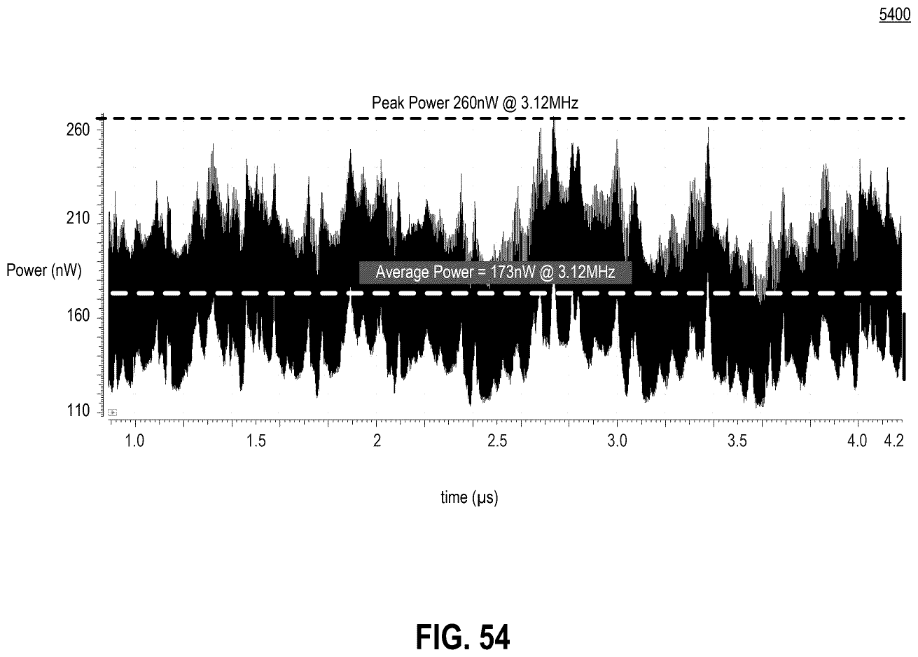

FIG. 54 is a plot 5400 of a power consumption profile of an AC nano-processor of FIG. 50 while executing instructions form instruction set of FIG. 32, in accordance with at least one example. A nano-processor 182 may consume a peak power of approximately 260 nW, with an average power consumption of 173 nW, when AC-powered nano-processor is operating at a clock frequency of 3.12 MHz. A reason for a significantly low power consumption in this example nano-processor compared with that of FIG. 39 is a cluster of AC logic gates can use a common pull-up network (CPN) to share AC power, reducing an overall transistor count and also power consumption.

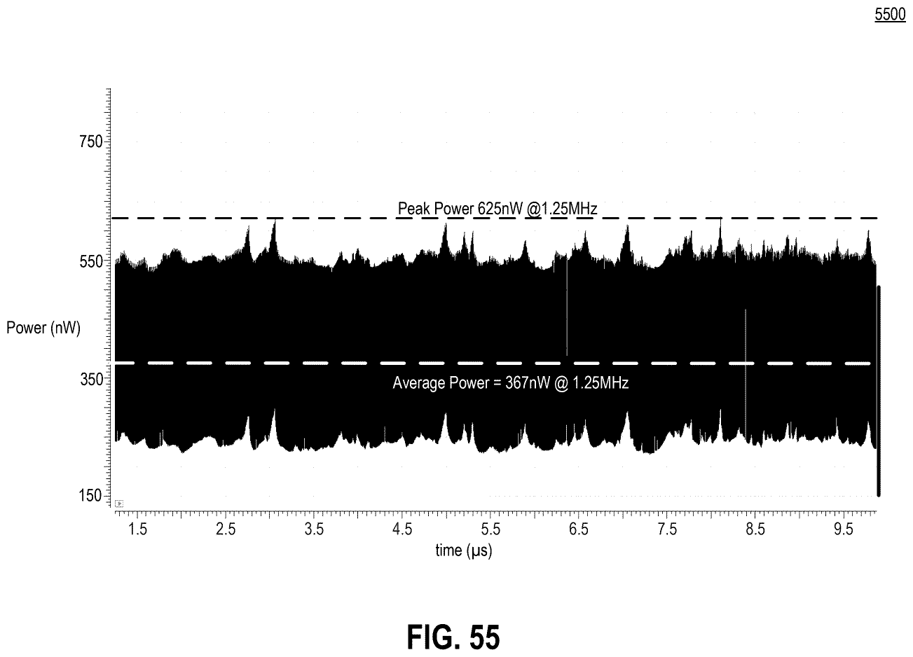

FIG. 55 is a plot 5500 of a power profile of an 8-bit AC nano-processor while executing instructions from an instruction set of FIG. 32, in accordance with at least one example. This 8-bit nano-processor operates at 1.25 MHz and may consume a peak power of approximately 625 nW, and an average power consumption of approximately 367 nW. An average power consumption per MHz may have increased significantly from 55 nW/MHz in a 4-bit nano-processor to 460 nW/MHz in an 8-bit nano-processor, illustrating an exponential increase in power consumption as bit-width of register increases. This power consumption behavior may further emphasize power efficiency while designing larger bit-width nano-processors.

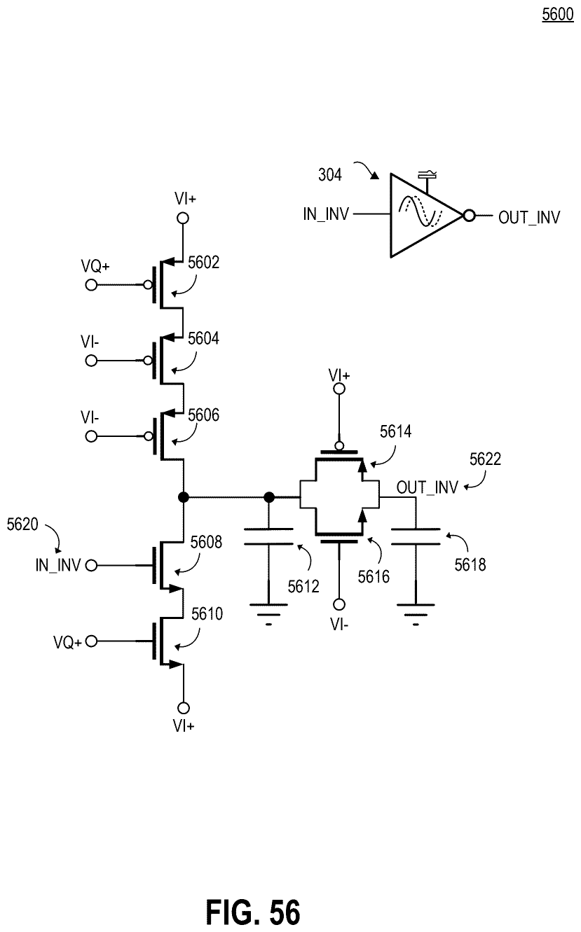

FIG. 56 is a circuit of an inverter circuit 5600, in accordance with at least one example. Inverter circuit 5600 may be powered using three signals VI+ 134, VI− 136, and VQ+ 146 that may be generated by IQ power supply 112 of FIG. 1A. Inverter circuit 5600 illustrates an example circuit for an inverter gate illustrated by symbol 304. Circuit 5600 may be divided into two primary branches: a PMOS charging branch and an NMOS discharging branch. Gate-source signals of transistors from IQ power source to a gate circuit can be arranged in such a manner to ensure that one branch may be activated during an individual operating phase. Transistors 5604 and 5606 in this example may always be ON due to 180° phase difference between VI+ 134 and VI− 136 signals. These transistors may be used for isolation to improve a circuit's operation. During a pre-charge phase 172, when VI+ 134 can be higher than VQ+ 146, transistor 5602 may conduct whereas transistor 5610 may remain cutoff. Consequently, a PMOS charging branch may conduct irrespective of a value of an input signal IN_INV 5620 during this phase time interval and may store a positive charge on capacitor 5612. Capacitor 5612 may be included, as it may act as a load capacitance for subsequent circuits driven by an inverter gate. In both of hold phases 174 and 178, neither of two transistors 5602, 5610 may get enough Vsg or Vgs in case of an NMOS technology; consequently, neither of two branches may conduct. During evaluate phase 176, when VQ+ 146 may be greater than VI+ 134, transistor 5602 may be cutoff which may disable a PMOS charging branch, whereas, transistor 5610 may be turned ON which may enable an NMOS discharging branch. During this phase, input transistor 5608 may behave like an inverter gate. If input signal IN_INV 5620 is high, transistor 5608 may conduct, and which may discharge capacitor 5612 and a 0 (low) is at output of inverter. On the flip side, if input signal 5620 is low, transistor 5608 may stay in a cutoff state, which may leave capacitor 5612 with a positive voltage that may have been established previously during pre-charge phase 172. However, in this example, an output signal at capacitor 5612 may keep oscillating between high and low states if input signal 5620 is high. To resolve this issue, a sample and hold circuit may include transistors 5614 and 5616 that may be used to sample output signal from 5612 in evaluate phase 176 to avoid undesired output jumps. Transistors 5614 and 5616, with gate signals VI+ 134 and VI− 136, may serve this purpose to generate final output OUT_INV 5622 at capacitor 5618.

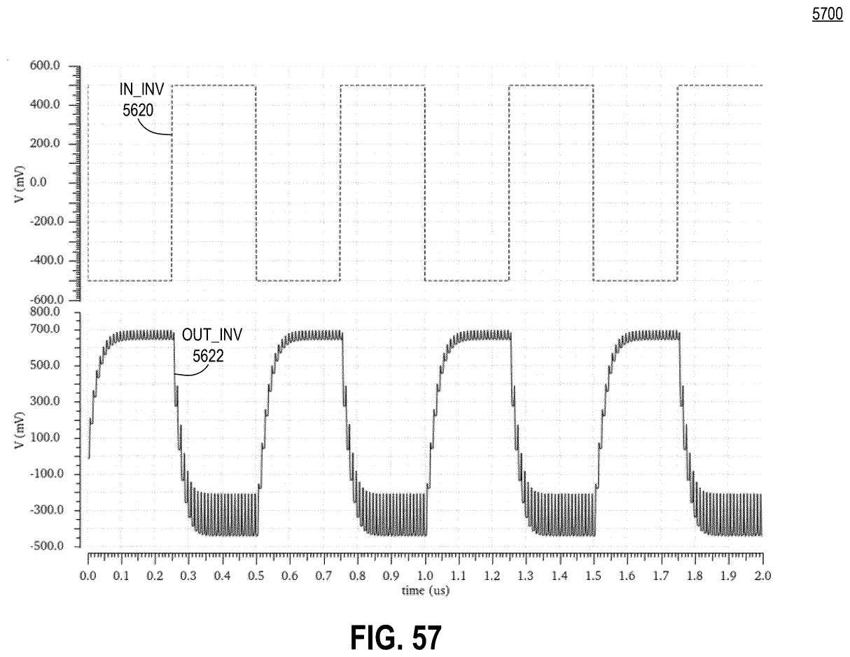

FIG. 57 is a plot 5700 that shows output OUT_INV 5622 of inverter circuit 5600 when input signal IN_INV 5620 is applied, in accordance with at least one example.

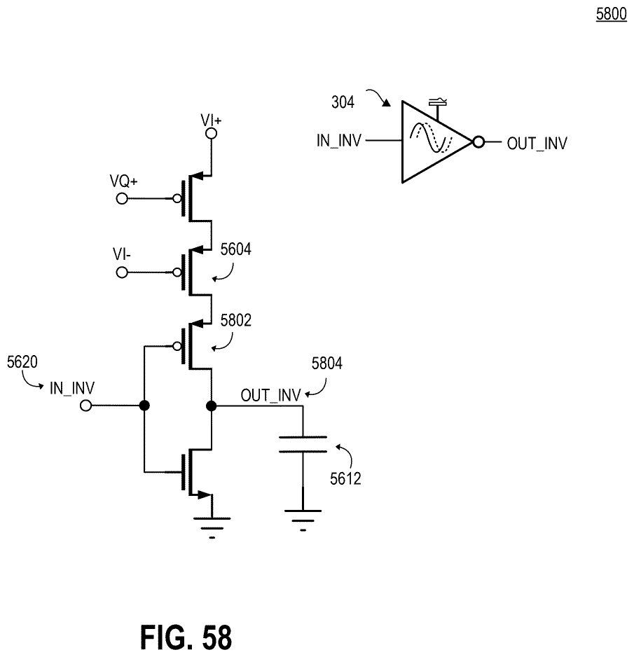

FIG. 58 is a circuit of an example structure of a quadrature phase RF inverter 5800, in accordance with at least one example. Inverter circuit 5800 illustrates an example circuit for an inverter gate illustrated by symbol 304. It may be powered using three signals VI+ 134, VI− 136, and VQ+ 146 generated by an example circuit of FIG. 1A, in accordance with at least one example. In this example, a PMOS transistor 5802 may be included in a PMOS charging branch, and transistors 5606 and 5610 can be eliminated. Transistor 5802 may allow a PMOS charging branch to conduct, and hence it may store a positive charge on output capacitor 5612 if input signal 5620 is low. This may prevent output 5804 from oscillating between high and low states when an input signal is high and may also allow eliminating sample and hold transistors 5614 and 5616 and capacitor 5618 of FIG. 56. Furthermore, it may also allow an inverter circuit to operate with one isolation transistor 5604. However, if lower power at higher voltages may be needed, transistor 5606 may also be included to increase a branch's overall resistance at a cost of voltage margin.

FIG. 59 is a plot 5900 that illustrates an output OUT_INV 5804 of a quadrature phase RF inverter circuit 5800 when input signal IN_INV 5620 is applied.

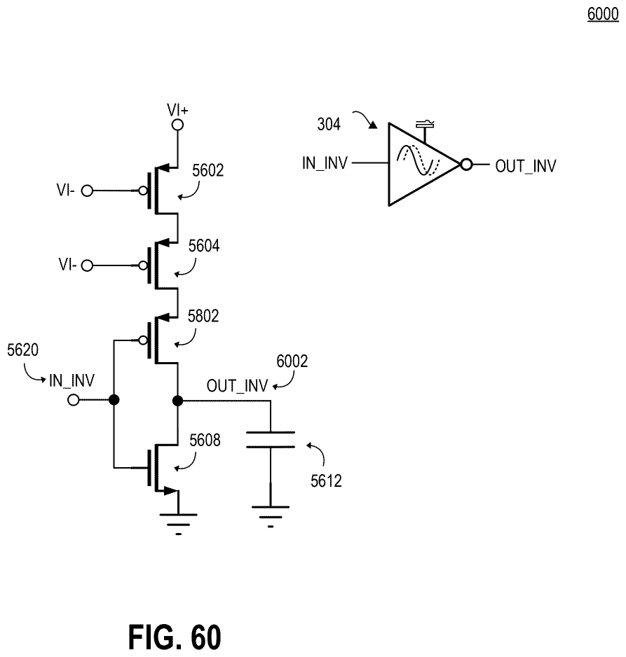

FIG. 60 is a schematic illustrating a quadrature RF inverter circuit 6000, in accordance with at least one example. Inverter circuit 6000 illustrates an example circuit for an inverter gate represented by symbol 304. It may be powered using two signals VI+ 134 and VI− 136 that may be generated by a circuit of the embodiment of FIG. 1A. Its operations are similar to that of inverter circuit 5800, except that this circuit may use two 180° out of phase signals namely VI+ 134 and VI− 136. Consequently transistor 5602's gate signal VQ+ 146 may be replaced with VI− 136 signal. This may enable inverter 6000 to evaluate logic in two phases (phase 296 and phase 298). During a pre-charge phase 296, transistors 5602 and 5604 may be switched ON. In this interval, depending on input 5620, capacitor 5612 may or may not be charging. If there is a low (0) at input 5620, transistor 5802 may be switched ON, and capacitor 5612 may charge to give a high (1) at output OUT_INV 6002, whereas at input high (1) a charging branch may remain OFF as transistor 5802 stays cutoff. In evaluate phase 298 a charging branch may remain OFF and its logic is evaluated depending on input 5620. If there is high (1) at input 5620, transistor 5608 may provide a path to discharge capacitor 5612 to ground and it may remain in a cutoff region if there is a low at input 5620. In at least one example, VQ+ 146 and VQ− 148 may be used instead of VI+ 134 and VI− 136, as VQ+ 146 and VQ− 148 are also 180° out of phase signals.

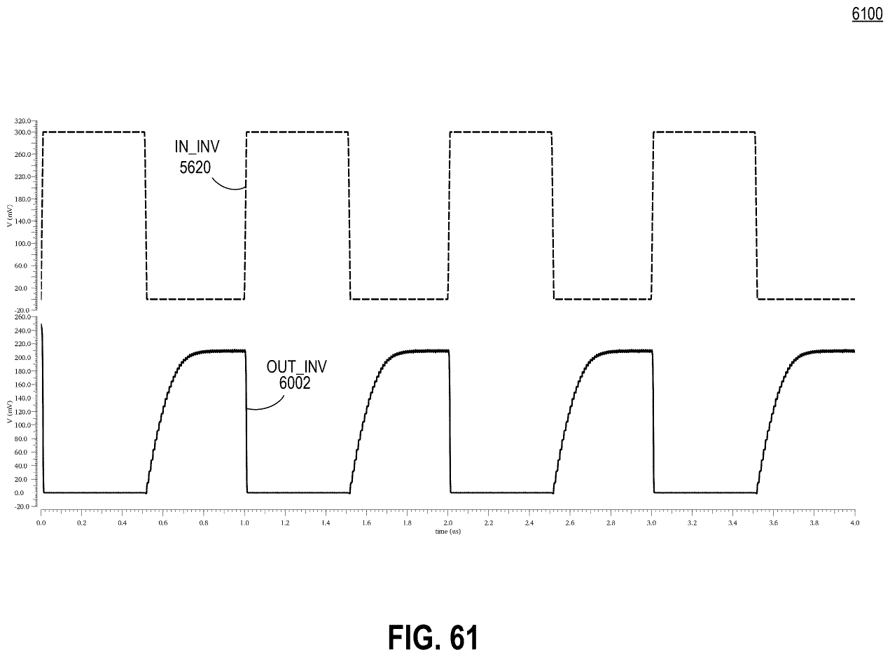

FIG. 61 is a plot 6100 that illustrates an output OUT_INV 6002 of inverter circuit 6000 when input signal IN_INV 5620 is applied, in accordance with at least one example.

In other examples of disclosure, a ground in a discharging branch in invertor circuits 5800 and 6000 may be replaced by input signal VI+ 134 like the one shown in at least one example of FIG. 56 to exploit an adiabatic nature of this logic. As a result, power consumption may be reduced.

In other examples of disclosure, an inverter explained in at least one example of FIG. 56, FIG. 58, and FIG. 60, may be used as a buffer by using two inverters in a series combination.

In other examples of disclosure, inverter circuits may also be used to make a ring oscillator by using an odd number of inverter stages.

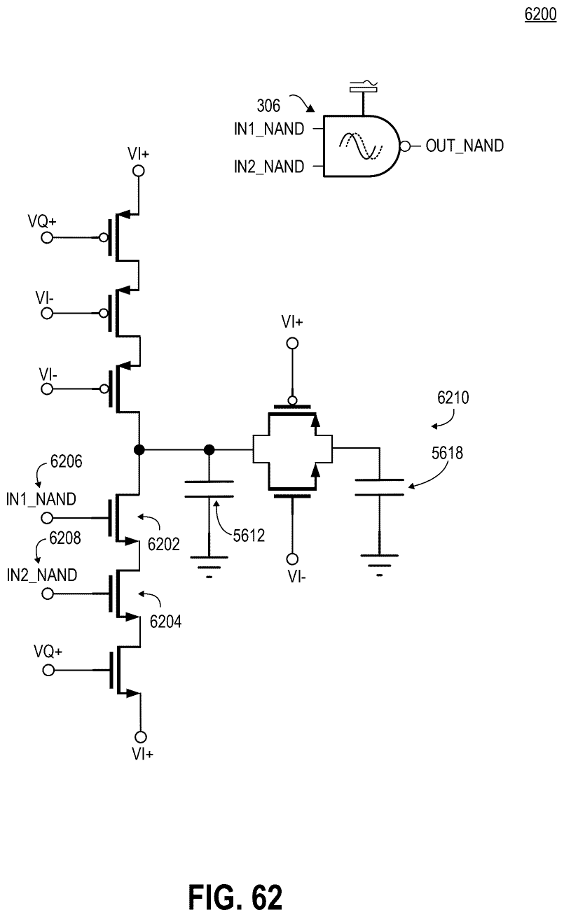

FIG. 62 is a circuit of a quadrature RF NAND gate 6200, in accordance with at least one example. NAND gate 6200 illustrates an example circuit for a NAND gate 1 306. RF NAND gate 6200 may be powered by three signals VI+ 134, VI− 136, and VQ+ 146 that are generated by at least one example circuit of FIG. 1A. Operating principle of NAND gate 6200 is similar to that of an example inverter circuit of FIG. 56, except that an inverter transistor 5608 may be replaced by a pair of transistors 6202 and 6204 that may be placed in series. Moreover, NAND gate 6200 takes two input signals IN1_NAND 6206 and IN2_NAND 6208. A NAND gate's operation during hold and pre-charge phases may remain unchanged. During evaluation phase 176, two transistors 6202 and 6204 may behave as a NAND gate and discharge output capacitor 5612 through an NMOS branch when both inputs are high (1), thereby implementing a NAND logic. A final output after sample and hold may be shown at capacitor 5618 as OUT_NAND 6210.

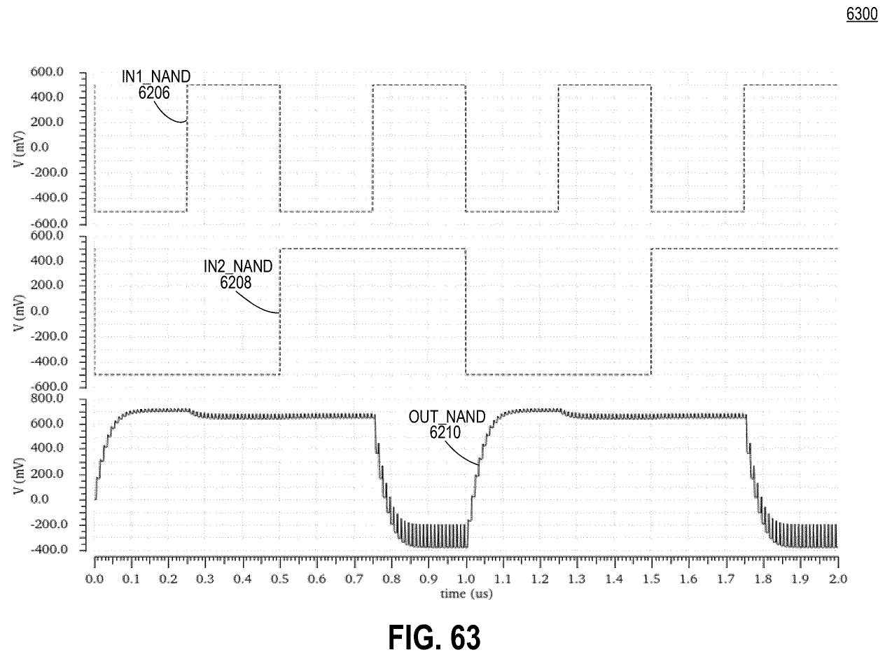

FIG. 63 is a plot 6300 of output OUT_NAND 6210 of a quadrature RF NAND gate 6200 of FIG. 62, when signals IN1_NAND 6206 and IN2_NAND 6208 are applied at inputs, in accordance with at least one example.

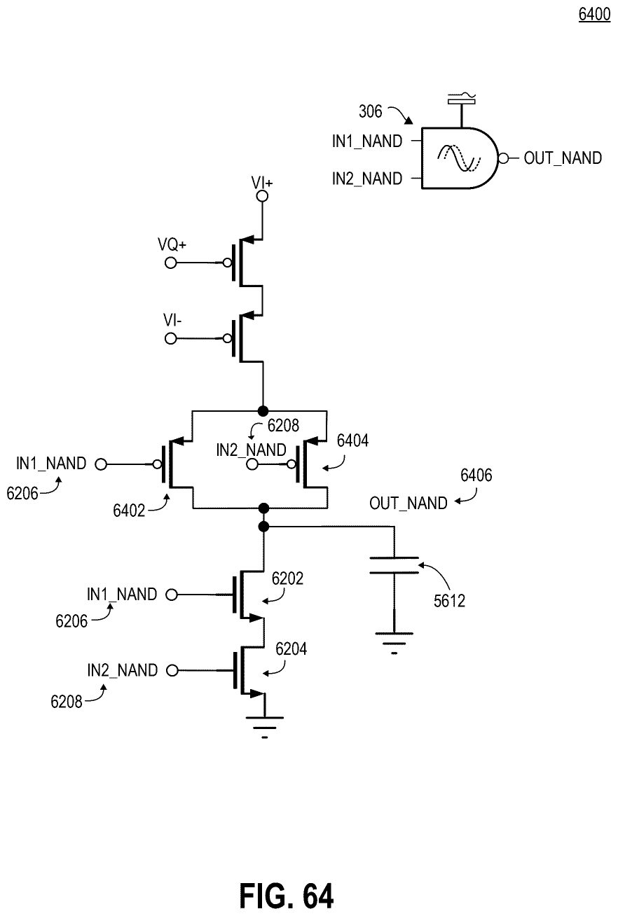

FIG. 64 is a circuit of an example structure of a quadrature RF NAND gate 6400, in accordance with at least one example. NAND gate 6400 illustrates an example circuit for a NAND gate 306. Parallel transistors 6402 and 6404 may be combined with series transistors 6202 and 6204 that may perform a NAND operation instead of a NOT operation in an inverter circuit 5800. In a pre-charge phase 172, either of transistors 6402 and 6404 may conduct if any of inputs 6206 or 6208 is low (0), and this would charge capacitor 5612, thereby storing a positive voltage (high) at output OUT_NAND 6406. However, if neither of inputs 6206 or 6208 is low, two transistors 6402 and 6404 may cut off a PMOS charging branch and may prevent an output capacitor 5612 provide a high voltage. In evaluation phase 176, series NMOS transistors 6202 and 6204 conduct if both of inputs 6206, 6208 are high. This circuit 6400 implements logic of a NAND gate.

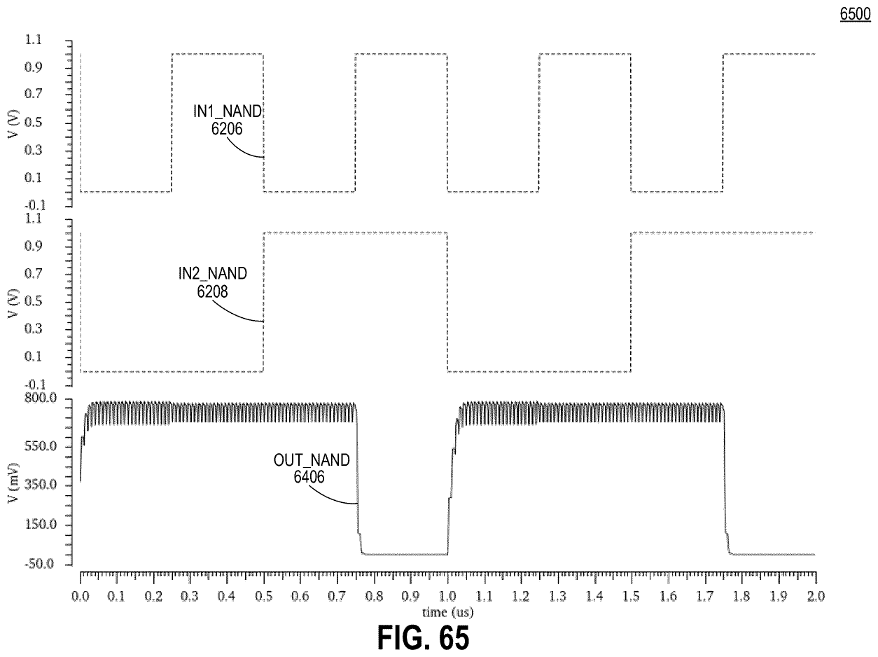

FIG. 65 is a plot 6500 of an output OUT_NAND 6406 of NAND circuit 6400 when two input signals IN1_NAND 6206 and IN2_NAND 6208 are applied at its inputs, in accordance with at least one example.

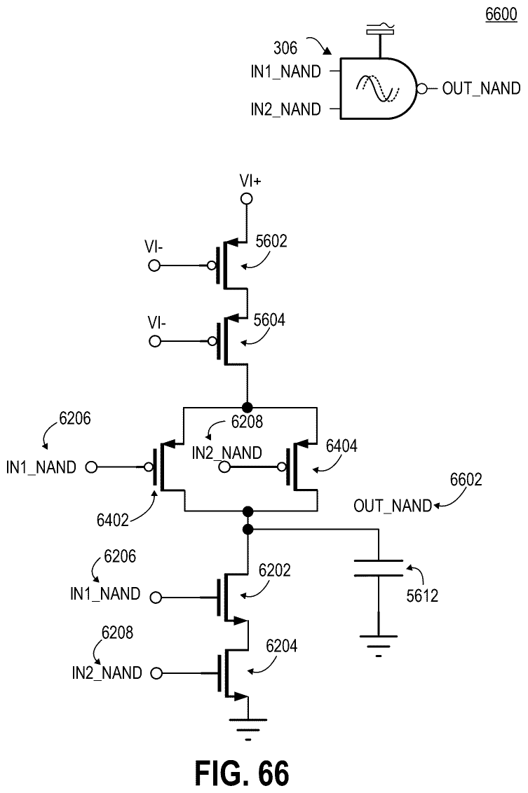

FIG. 66 is a circuit of a 180° AC-powered RF NAND gate 6600, in accordance with at least one example. NAND gate 6600 illustrates an example circuit for a NAND gate 306. Its operating principle is like a NAND gate circuit 6400, except that this circuit may use two 1800 signals VI+ 134 and VI− 136. Hence transistor 5602's gate signal VQ+ 146 may be replaced with VI− 136. This may enable this circuit to evaluate logic in two phases 296 and 298. During a pre-charge phase 296, transistors 5602 and 5604 may be switched ON. In this phase, depending on input signals IN_NAND1 6206 and IN_NAND2 6208, a capacitor 5612 may or may not be charged. Either of transistors 6402 and 6404 may conduct if any of two inputs 6206, 6208 is low, which may charge capacitor 5612 and store a positive voltage (high) at its output 6602. However, if neither of two inputs 6206, 6208 is low, two transistors 6402 and 6404 may cut off a PMOS charging branch and may prevent an output capacitor 5612 from providing a high voltage. In evaluation phase 298, series NMOS transistors 6202 and 6204 may be conducted if both of inputs 6206 and 6208 are high. Hence circuit 6600 can implement logic of a NAND gate.

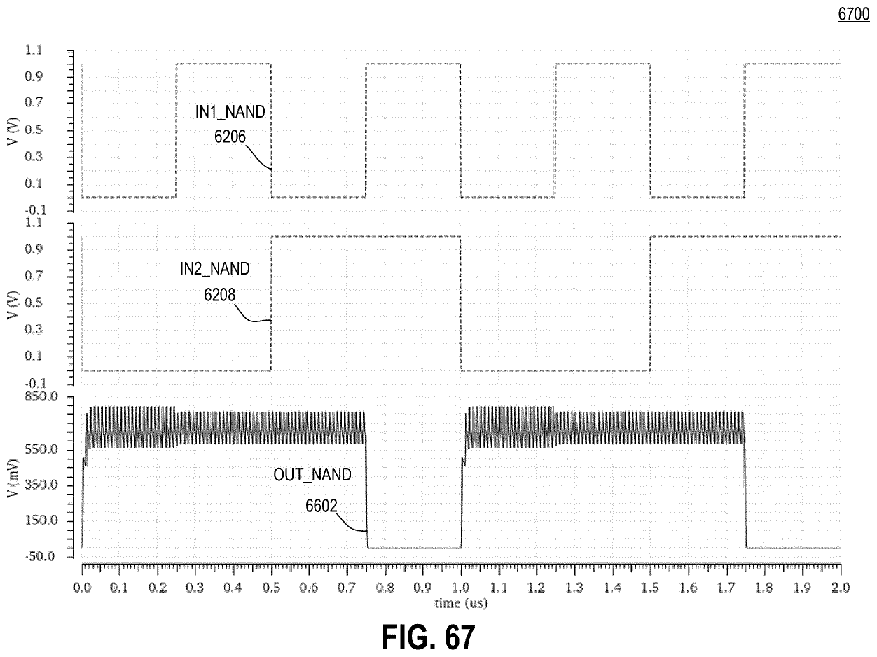

FIG. 67 is a plot 6700 of an output OUT_NAND 6602 when input signals IN1_NAND 6206 and IN2_NAND 6208 are applied to inputs of RF NAND gate 6600 of FIG. 66, in accordance with at least one example.

In other examples of disclosure, a ground in a discharging branch in circuits 6400 and 6600 may be replaced by an input signal VI+ 134 similar to the one shown in at least one example of FIG. 62 to exploit an adiabatic nature of this logic. As a result, power consumption may be reduced.

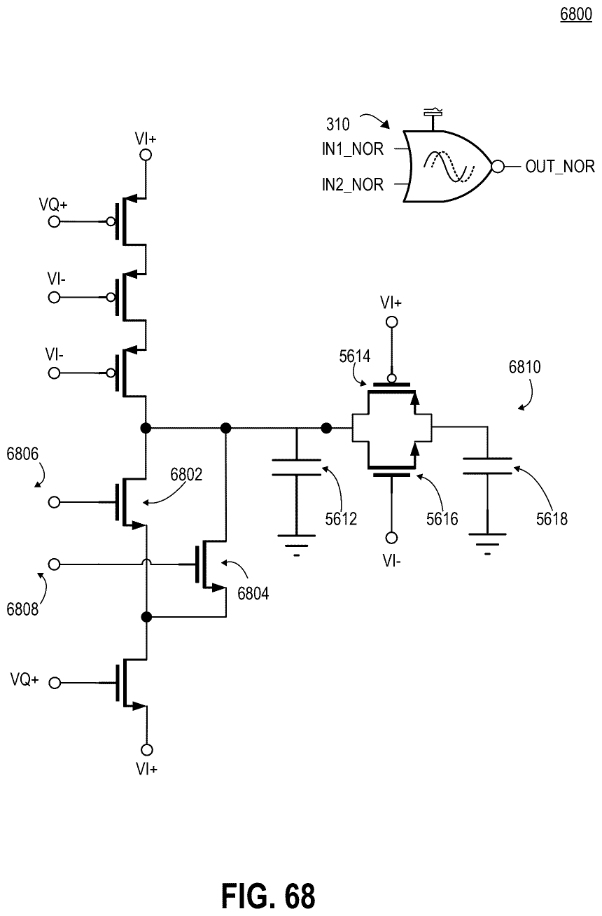

FIG. 68 is a circuit of a quadrature RF NOR gate 6800, in accordance with at least one example. NOR gate 6800 illustrates an example circuit for NOR gate 310. Like inverter circuit 5600 and NAND gate circuit 6200 of the embodiments of FIG. 56 and FIG. 62, circuit 6800 also may operate in four phases of quadrature signals and may be powered using three signals VI+ 134, VQ+ 146, and VI− 136. A PMOS charging branch may initially charge an output capacitor 5612 irrespective of inputs 6806 and 6808, whereas an NMOS discharging branch may conduct and discharge capacitor 5612 using transistors 6802 or 6804 in case when a desired output may be low (e.g., when either of inputs IN1_NOR 6806 or IN2_NOR 6808 may be high). When desired output is high (e.g., when both of inputs 6806 and 6808 signals are low), an output OUT_NOR 6810 may oscillate between high and low states like previous circuits, and this problem may be resolved using a sample and hold circuit that may include transistors 5614 and 5616 and another output capacitor 5618.

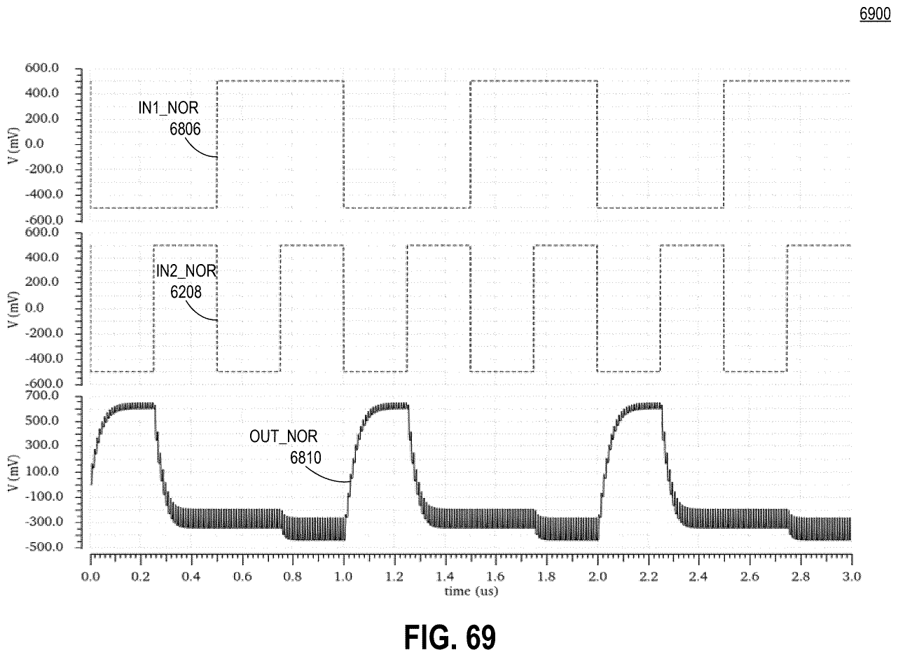

FIG. 69 is a plot 6900 of output OUT_NOR 6810 when input signals IN1_NOR 6806 and IN2_NOR 6808 are applied at inputs of RF NOR gate 6800 of FIG. 68, in accordance with at least one example.

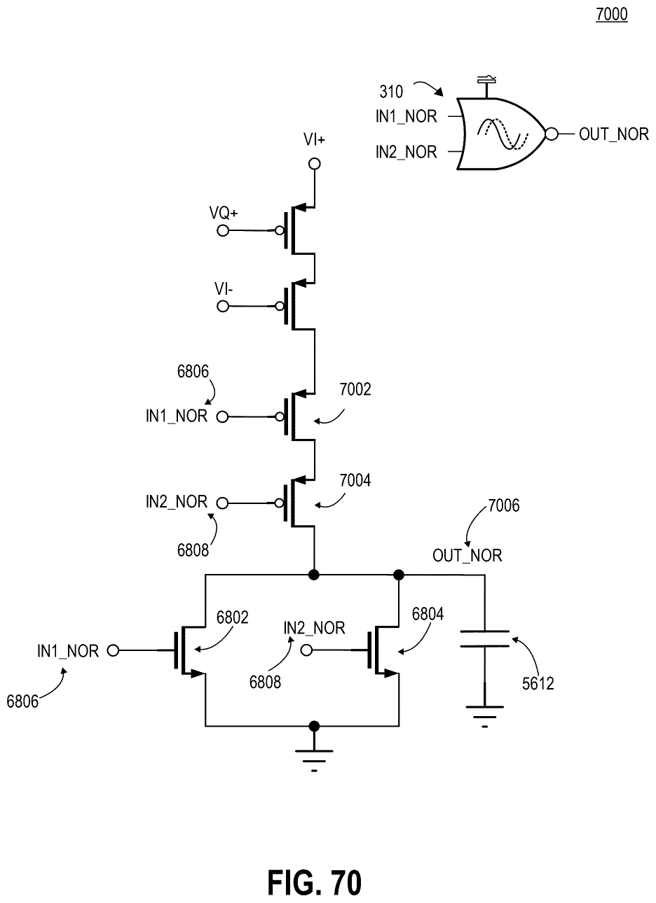

FIG. 70 is a circuit of an example structure of a quadrature RF NOR gate 7000, in accordance with at least one example. NOR gate 7000 illustrates an example circuit for NOR gate 1 310. This example has the same operating principle as that of two-input quadrature RF NAND gate of FIG. 64, except in circuit 7000 PMOS transistor 7002 and 7004 are placed in series. Like circuit 6400, a PMOS charging branch may initially charge an output capacitor 5612 when a desired output is high (e.g., when both of inputs IN1_NOR 6806 and IN2_NOR 6808 are low) due to logic arrangement of PMOS transistors 7002 and 7004. NMOS transistors 6802 and 6804 in a discharging branch may conduct and discharge an output OUT_NOR 7006 from capacitor 5612 when a desired output is low (e.g., when either of the inputs is high). Hence circuit 7000 can implement logic of a NOR gate.

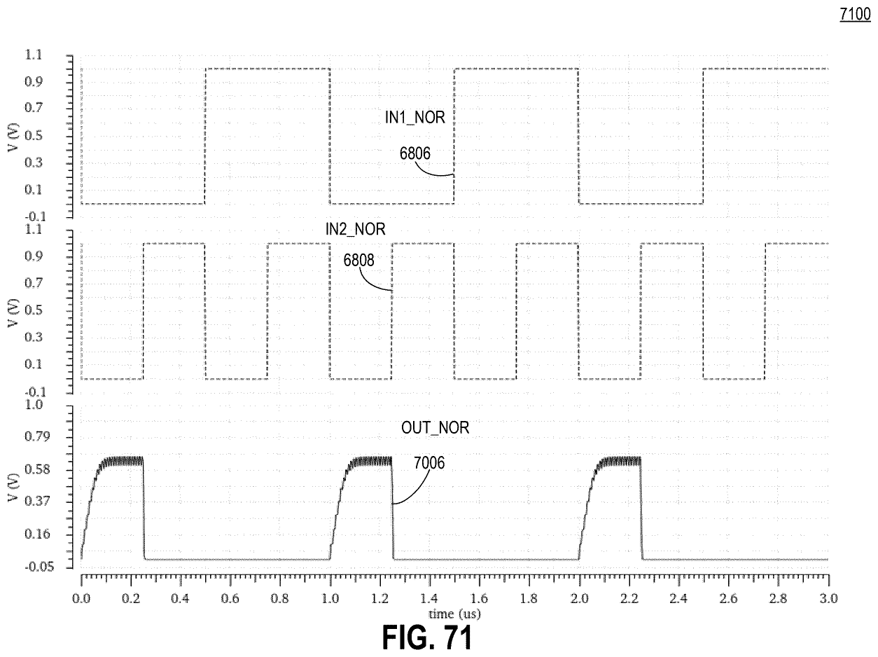

FIG. 71 is a plot 7100 of output OUT_NOR 7006 when two input signals IN1_NOR 6806 and IN2_NOR 6808 are applied at inputs of quadrature RF NOR gate 7000 of FIG. 70, in accordance with at least one example.

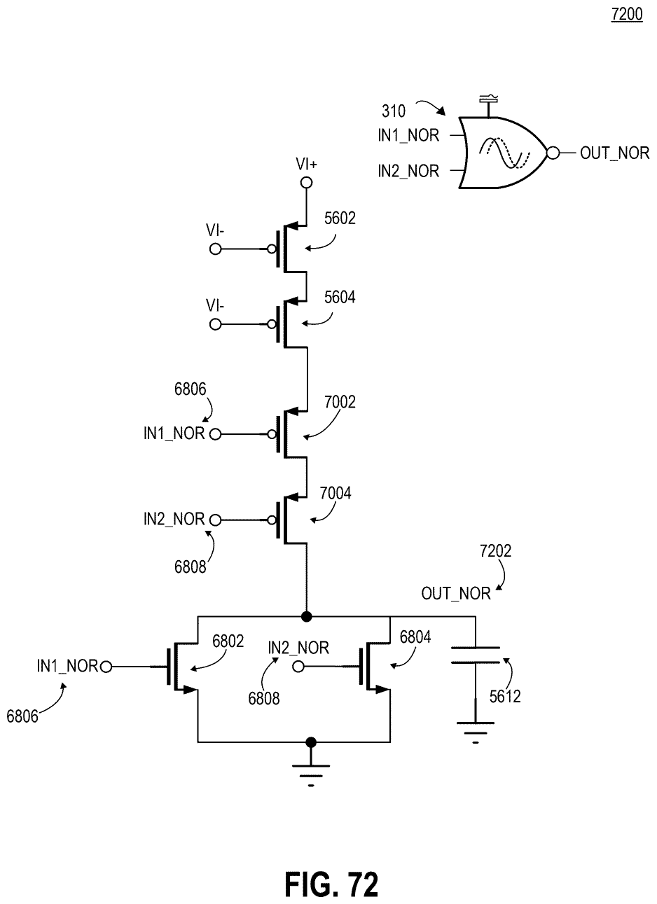

FIG. 72 is a circuit of a 180° AC-powered RF NOR gate 7200, in accordance with at least one example. NOR gate 7200 illustrates an example circuit for NOR gate 1 310. Its operating principle is similar to that of NAND gate circuit 6600: circuit 7200 uses two 180° signals VI+ 134 and VI− 136, which may enable this circuit to evaluate logic in two phases 296 and 298. During a pre-charge phase 296, transistors 5602 and 5604 may be switched ON. In this phase, depending on input signals IN1_NOR 6806 and IN2_NOR 6808, capacitor 5612 may or may not be charging. Transistors 7002 and 7004 may conduct if both inputs are low, which may result in charging capacitor 5612 and may set a high voltage at output 7202. However, if either of inputs 6806 or 6808 is high, a corresponding transistor may cut off a PMOS charging branch and may prevent output capacitor 5612 from providing a high voltage. In evaluation phase 298, parallel NMOS transistors 6802 and 6804 may be conducted if any of two inputs 6806 or 6808 is high. Hence circuit 7200 can implement logic of a NOR gate. In at least one example, VQ+ 146 and VQ− 148 may be used instead of VI+ 134 and VI− 136, VQ+ 146, and VQ− 148 are also 180° out of phase signals.

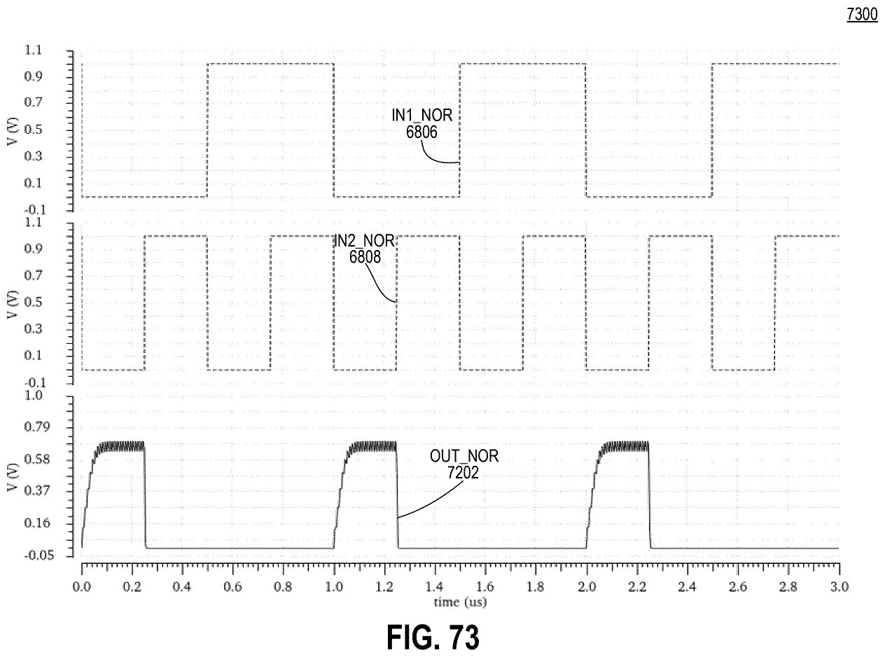

FIG. 73 is a plot 7300 of an output OUT_NOR 7202 when two input signals IN1_NOR 6806 and IN2_NOR 6808 are applied at inputs of RF NOR gate 7200 of FIG. 72, in accordance with at least one example.

In other examples of disclosure, a ground in a discharging branch in circuits 7000 and 7200 may be replaced by an input signal VI+ 134 similar to the one shown in an example of FIG. 68 to exploit an adiabatic nature of this logic. As a result, the power consumption may be reduced.

In other examples of disclosure, NAND and NOR gate circuits may also be included that might take more than two input signals.

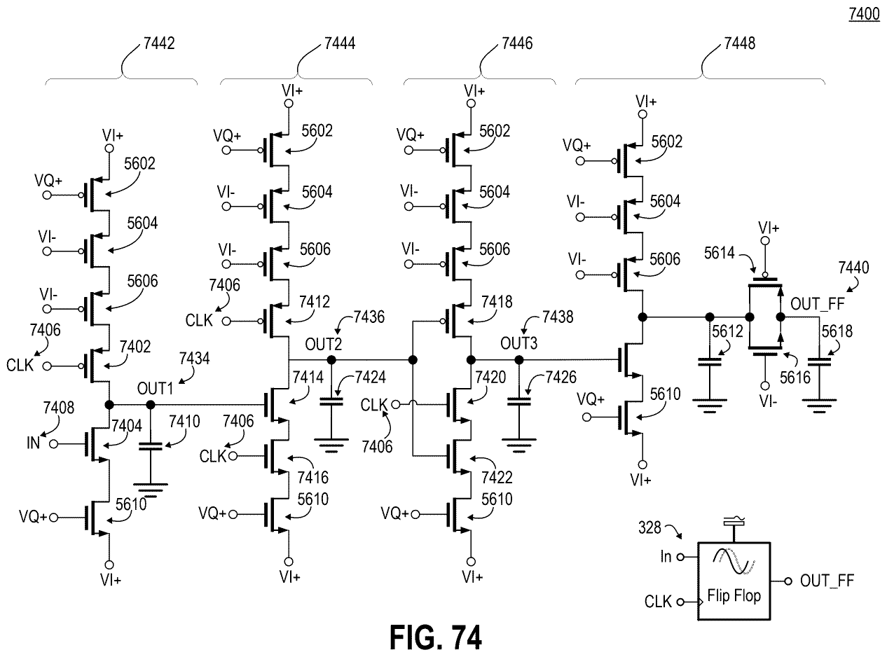

FIG. 74 is a circuit of a quadrature RF D flip flop 7400, in accordance with at least one example. D flip flop 7400 illustrates an example circuit for D flip flop 328. Circuit 7400 may operate using three signals VI+ 134, VI− 136, and VQ+ 146 that may be generated by at least one example circuit of FIG. 1A. Circuit 7400 may be divided into four stages 7442, 7444, 7446, and 7448, wherein every individual stage may have two primary branches: a PMOS charging branch and an NMOS discharging branch. Four stages 7442, 7444, 7446, and 7448 may need to support operations with an IQ power port; therefore, transistors 5602, 5604, and 5606 may be added and a gate to source signals of these transistors may be arranged to ensure that one branch may conduct during each operating phase. Like AC powered gates, transistors 5604 and 5606 may always be turned ON due to 180° out of phase VI+ 134 and VI− 136 that may be used for isolation to improve operations of circuit 7400. During a pre-charge phase 172, when VI+ 134 may be higher than VQ+ 146, transistors 5602 may conduct whereas transistor 5610 may remain cutoff. Consequently, an AC powered circuit may allow all four PMOS branches to conduct during a pre-charge phase 172 and NMOS branches to conduct during an evaluate phase 176. In order implement operation logic of a D Flip Flop, circuit 7400 may hold a previous value of output 7440 at both static states of a CLK signal 7406 when clock signal is maintaining a level e.g., CLK=0 (low) or CLK=1 (high) and it may change its output 7440 at a positive edge of CLK signal 7406. First examining a low static state (CLK=0), first stage 7442 may be enabled in this state. So, input signal IN 7408 may propagate to node OUT1 7434 at capacitor 7410, e.g., if IN 7408 is low then output OUT1 7434 may be pre-charged to high, and if IN 7408 is high then output OUT1 7434 may be discharged to low. However, a second stage 7444 may prevent it from going to next stages 7446 and 7448, as a transistor 7416 may be switched off which may also disable a transistor 7414. A transistor 7412 may be ON which may pull a node OUT2 7436 at a capacitor 7424 up. So, a second stage OUT3 7438, irrespective of OUT1 7434, may go into a pre-charge state, and may pull node OUT2 7436 up. This may cause a third stage 7446 to go into a high impedance mode, since CLK=0 signal may turn off transistor 7420 and signal OUT2 (7436)=1 may turn off transistor 7418. Consequently, capacitor 7426 at node OUT3 7438 may hold its previous state. Now consider CLK=1 case. In this state, a first inverter's transistor 7402 may be disabled, so transistor 7404 is turned on. In a second inverter's transistor 7416 may be turned on and a transistor 7412 may be turned off so a transistor 7414 may be turned on. In this state, either of two inverters may prevent an input signal from propagating depending on a value of input signal IN 7408. If IN=0, transistor 7404 turns off and stops the input. If IN=1, then transistor 7404 may pull up transistor 7434 to 0 and transistor 7414 may be turned off and may prevent it from propagating any further. Consequently, in either case, a node OUT2 7436 may remain unchanged. Thus, circuit 7400 may cut off inputs in static states. Now see a negative edge of a clock signal CLK 7406, e.g., when CLK goes from high to low. A first stage 7442 may be initially turned off and then it may be turned on. Consequently, signal IN 7408 may be allowed to propagate to a node 7434 after an edge is seen. However, node 7436 may be connected to node 7434 in a pre-charge state so it prevents an input signal from going to its output because of transistors 7412 and 7416. In a pre-charge state, node OUT2 7436 may get charged irrespective of an input signal 7408. To isolate this signal from output signal, a third stage 7446 may be used. This stage may act as a clock-controlled invertor, when CLK signal 7406 goes from high to low node, OUT2 7436 goes high that may turn transistor 7422 ON and transistor 7418 OFF. As CLK signal 7406 is low, transistor 7420 stays OFF, hence blocking voltage of OUT2 7436 node. In a case of a positive edge, e.g., CLK going from low to high. A PMOS branch of first stage 7442 may go from on to off. When it is on, this may allow an initial state of signal IN 7408 may be loaded on node OUT1 7434 but then it gets disconnected. So, node OUT1 7434 may store a value of input 7408. Second stage 7444 may go from a pre-charge state to a discharge state. In this state, node OUT2 7436 may stay high if stage OUT1 7434 is low and goes low (discharges) if stage OUT1 7434 is high. Thus, node OUT2 7436 may store a value of IN 7408 while node voltage at OUT3 7438 may be inverted as CLK signal 7406 goes from low to high. Finally, last stage 7448 may again invert a signal at node OUT3 7438 to store a value of IN 7408 at final output OUT_FF 7440 on a capacitor 5618. Hence circuit 7400 may implement logic of a D Flip Flop.

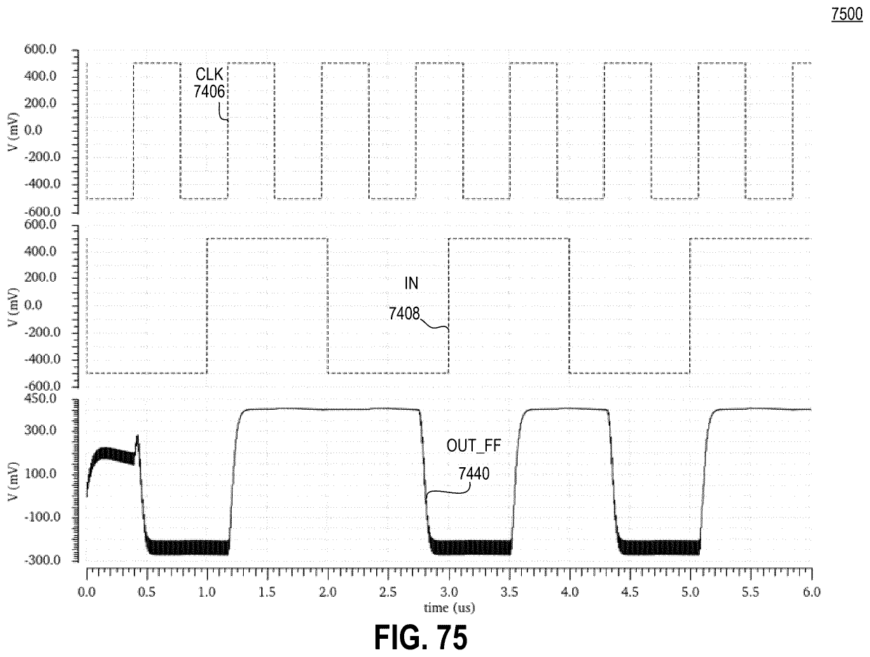

FIG. 75 is a plot 7500 of an output OUT_FF 7440 when clock signal CLK 7406 and an input signal IN 7408 are applied to a quadrature RF D Flip Flop 7400 of FIG. 74, in accordance with at least one example.

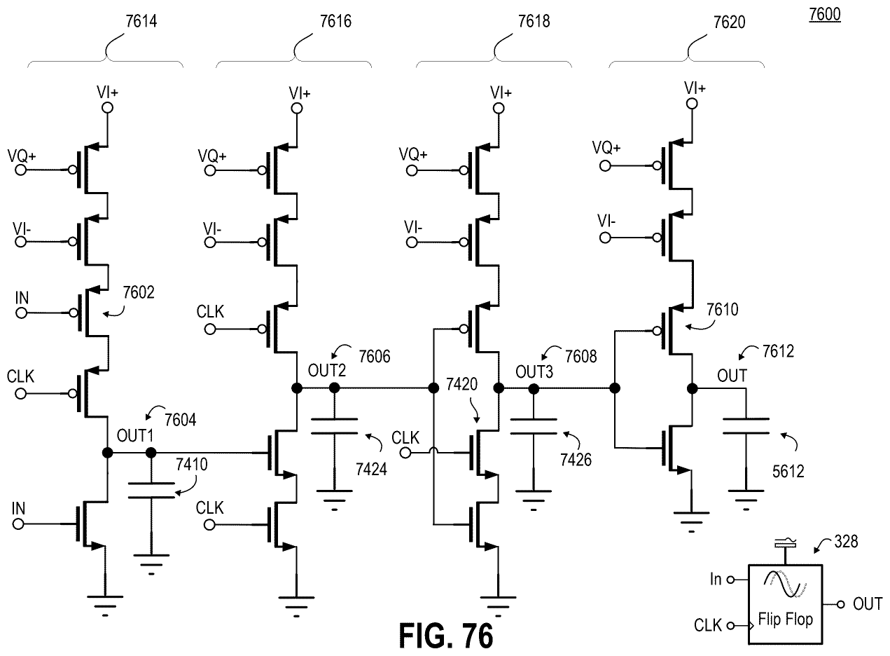

FIG. 76 is a circuit of an example structure of a quadrature RF D flip flop 7600, in accordance with at least one example. D flip flop 7600 illustrates an example circuit for flip flop 328. Like previous amendments that are made in examples of FIG. 58, FIG. 64, and FIG. 70, a PMOS transistor 7602 may be included in a charging branch of a first stage to allow charging of branch 7604 when supported by input signal 7408. This amendment removes one of isolation transistors 5606 in all of charging branches. All NMOS transistors 5610 in discharging branches may also be removed. PMOS transistor 7610 may also be included in a final inverting stage 7620. Output signals of branches 7614, 7616, 7618, and 7620 may be held as OUT1 7604, OUT2 7606, OUT3 7608, and OUT_FF 7612, respectively, on capacitors 7410, 7424, 7426, and 5612. Sample and hold transistors 5614, 5616 and their corresponding capacitor 5618 can also be removed.

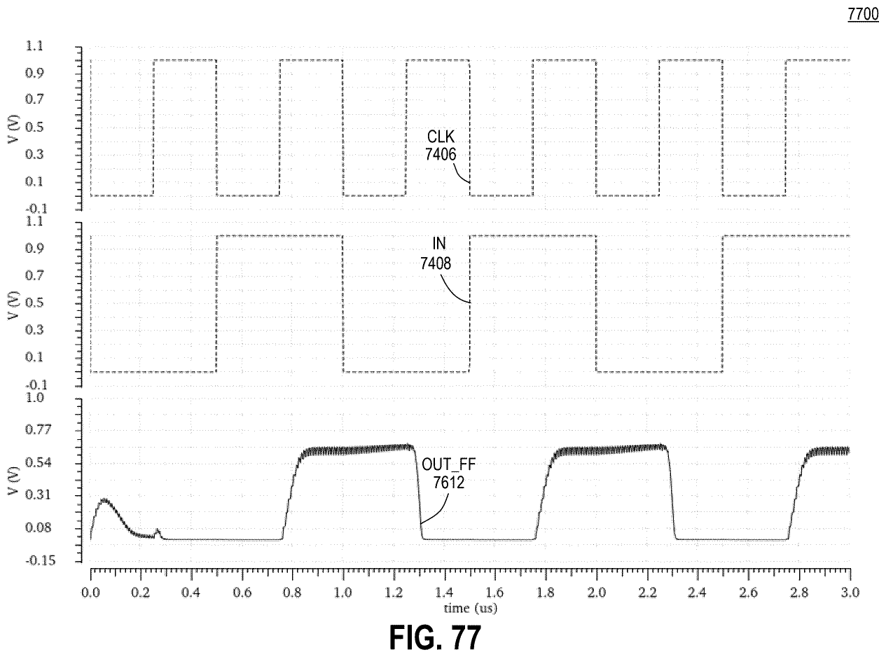

FIG. 77 is a plot 7700 of an output OUT_FF 7612 when an input signal IN 7408 and a clock signal CLK 7406 are applied at inputs of RF D Flip Flop 7600 of FIG. 76, in accordance with at least one example.

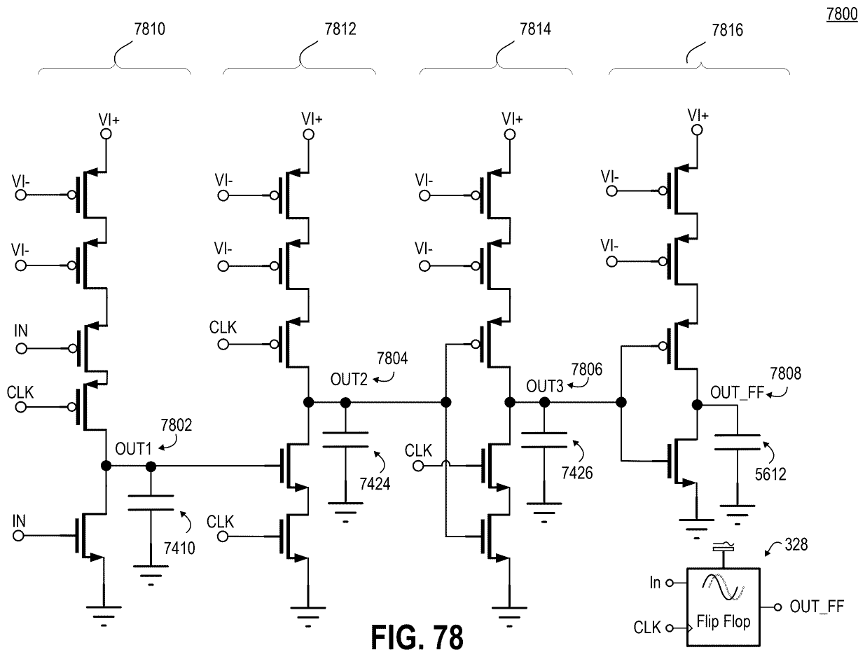

FIG. 78 is a circuit of a 180° AC-powered RF D Flip Flop 7800, in accordance with at least one example. D flip flop 7800 illustrates an example circuit for flip flop 328. D Flip Flop circuit 7800 may be powered by two 180° out of phase signals VI+ 134 and VI− 136. Like previous examples of FIG. 60, FIG. 66, and FIG. 72, circuit 7800 may operate in two phases: pre-charge phase 296 and evaluate phase 298. Rest of operating principle is same as described for circuit 7600 of FIG. 76. Outputs of stages 7810, 7812, 7814, and 7816 are shown as OUT1 7802, OUT2 7804, OUT3 7806, and OUT_FF 7808, respectively, at capacitors 7410, 7424, 7426, and 5612. In at least one example, VQ+ 146 and VQ− 148 may be used instead of VI+ 134 and VI− 136, since VQ+ 146 and VQ− 148 are also 180° out of phase signals.

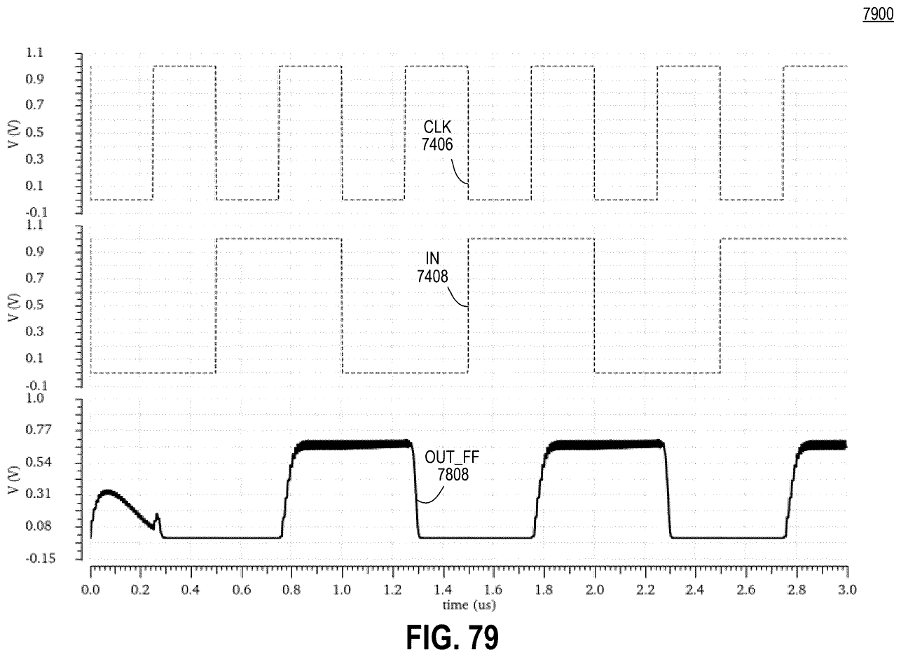

FIG. 79 is a plot 7900 of output OUT_FF 7808 with an input signal IN 7408 and a clock signal CLK 7406 applied at inputs of an AC-powered RF D Flip Flop 7800 of FIG. 78, in accordance with at least one example.

In other examples of disclosure, a ground in a discharging branch in circuits 7600 and 7800 may be replaced by an input signal VI+ like the one shown in at least one example of FIG. 74 to exploit an adiabatic nature of this logic.

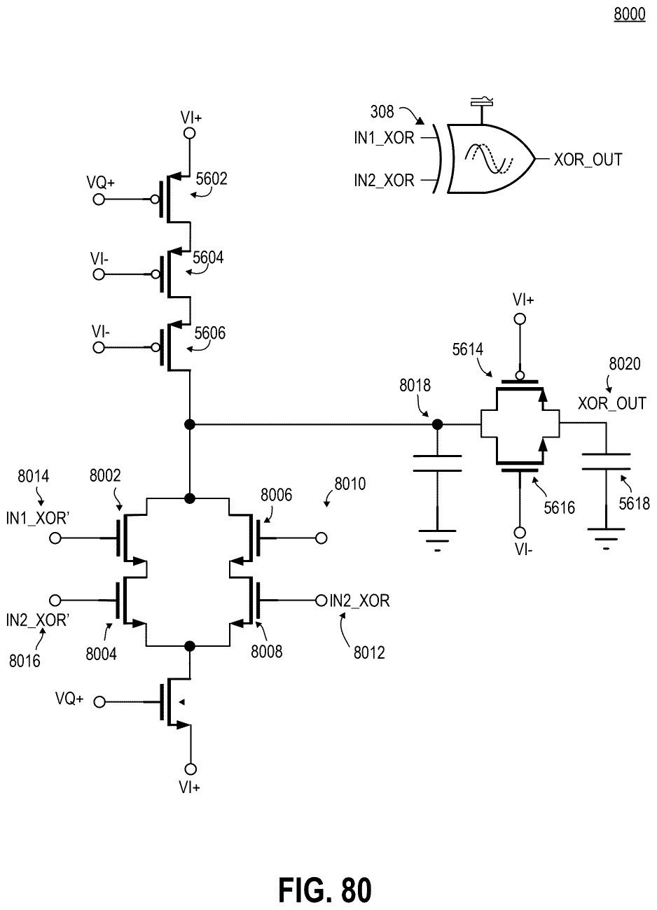

FIG. 80 is a circuit of a quadrature RF XOR gate 8000, in accordance with at least one example. XOR gate 8000 illustrates an example circuit for XOR gate 308. XOR gate 8000 may be powered using three quadrature signals VI+ 134, VQ+ 146, and VI− 136. Like previous examples, a PMOS charging branch charges a node 8018 using transistors 5602, 5604, and 5606 during a pre-charge phase 172 irrespective of values of input signals. In an evaluate phase 176, NMOS discharging branch may perform a XOR operation using transistors 8002, 8004, 8006, and 8008. Circuit 8000 may use two input signals IN1_XOR 8010 and IN2_XOR 8012 and their inverted versions IN1_XOR′ 8014 and IN2 XOR′ 8016. Transistors 8002 and 8004 may be placed in series, hence implementing a logic IN1_XOR NAND IN2_XOR, whereas transistors 8006 and 8008 may be placed in series which might make logic IN1_XOR′ NAND IN2_XOR′. A complete NMOS branch may be put in parallel to two NAND gates, which can implement XOR gate logic. An NMOS branch may pull output node 8018 down when both inputs are negation of one another. Output 8018, like previous examples, may also be oscillating between high and low states when an expected output is high, and this may happen when both inputs are same in a XOR gate. This problem may be resolved using a sample and hold circuit that may include transistors 5614 and 5616, and a final output may be shown at a capacitor 5618 as XOR_OUT 8020.

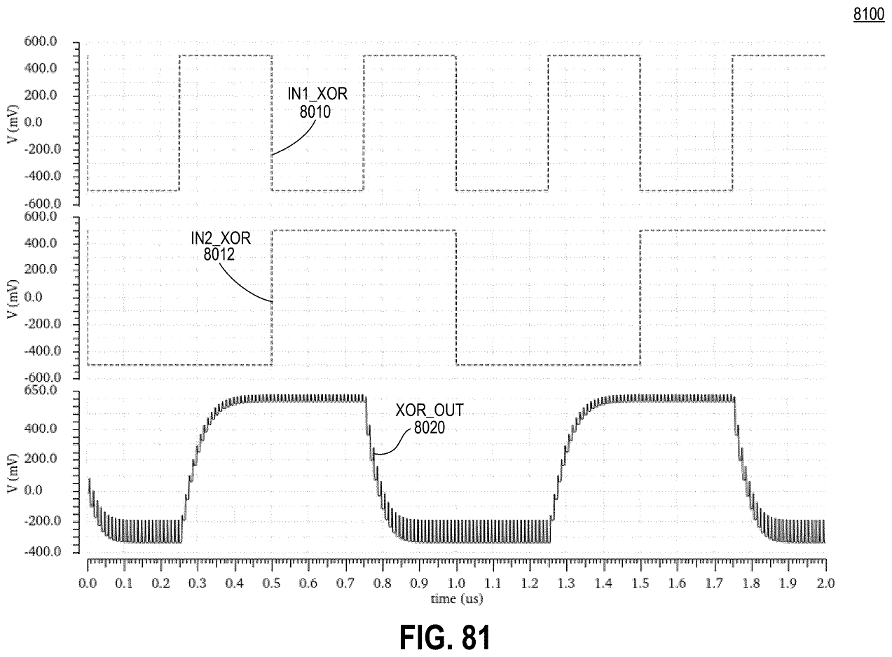

FIG. 81 is a plot 8100 of an output XOR_OUT 8020 of XOR circuit 8000 when input signals IN1_XOR 8010 and IN2_XOR 8012 are applied to inputs of quadrature RF XOR gate 8000 of FIG. 80, in accordance with at least one example.

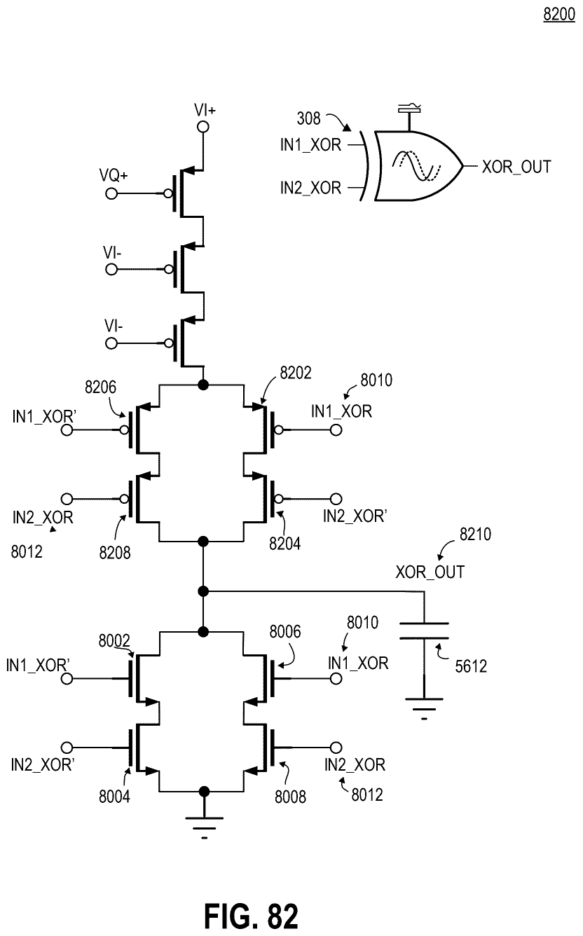

FIG. 82 is a circuit of an example structure of a quadrature RF XOR gate 8200, wherein XOR logic is evaluated using signals IN1_XOR, IN2_XOR, and their inverted counterparts IN1_XOR′ and IN2_XOR′, in accordance with at least one example. XOR gate 8200 illustrates an example circuit for XOR gate 308. Circuit 8200 may also work on a same working principle as that of two-input quadrature RF NAND gate example 6400 of FIG. 64. Like circuit 6400, a PMOS charging branch initially may charge output capacitor 5612 in a case when desired output 8210 is high e.g., when both of inputs IN1_XOR 8010 and IN2_XOR 8012 are negation of one another because of PMOS transistors 8202, 8204, 8206, and 8208 in a charging branch. These transistors might form a complimentary logic equivalent of NMOS transistors 8002, 8004, 8006, and 8008 in a discharging branch.

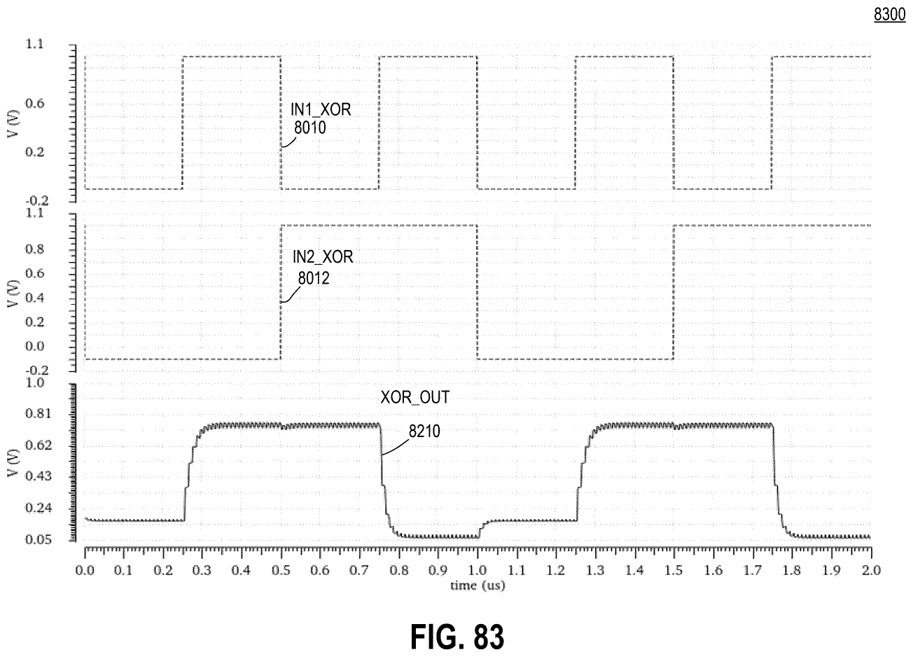

FIG. 83 is a plot 8300 of an output XOR_OUT 8210 when two input signals IN1_XOR 8010 and IN2_XOR 8012 are given at input of a quadrature RF XOR gate 8200 of FIG. 82, in accordance with at least one example.

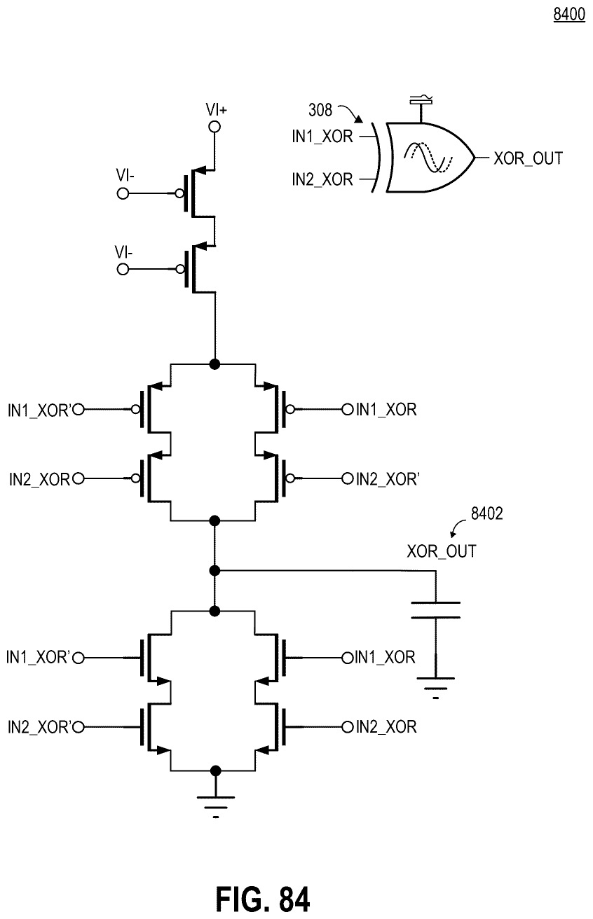

FIG. 84 is a circuit of a 180° out of phase AC-powered RF XOR gate 8400, in accordance with at least one example. XOR gate 8400 illustrates an example circuit for XOR gate 308. XOR gate 8400 may be powered using two 180° out of phase signals VI+ 134 and VI− 136. Like previous examples of FIG. 60, FIG. 66, FIG. 72, and FIG. 78, circuit 8400 may operate in two phases, a pre-charge phase 296 and an evaluate phase 298, to get a desired output at XOR_OUT 8402. Rest of operating principle is the same as described for circuit 8200 of example of FIG. 82. In at least one example, VQ+ 146 and VQ− 148 may be used instead of VI+ 134 and VI− 136, since VQ+ 146 and VQ− 148 are also 180° out of phase signals.

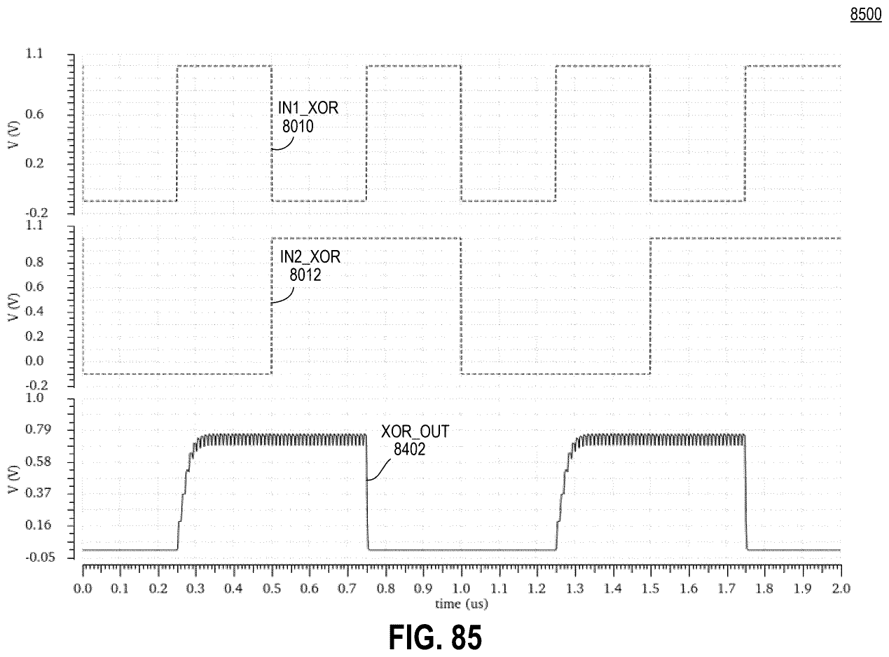

FIG. 85 is a plot 8500 of an output XOR_OUT 8402 of XOR circuit 8400 when two input signals IN1_XOR 8010 and IN2_XOR 8012 are applied at 180° AC-powered RF XOR gate 8400 of FIG. 84, in accordance with at least one example.

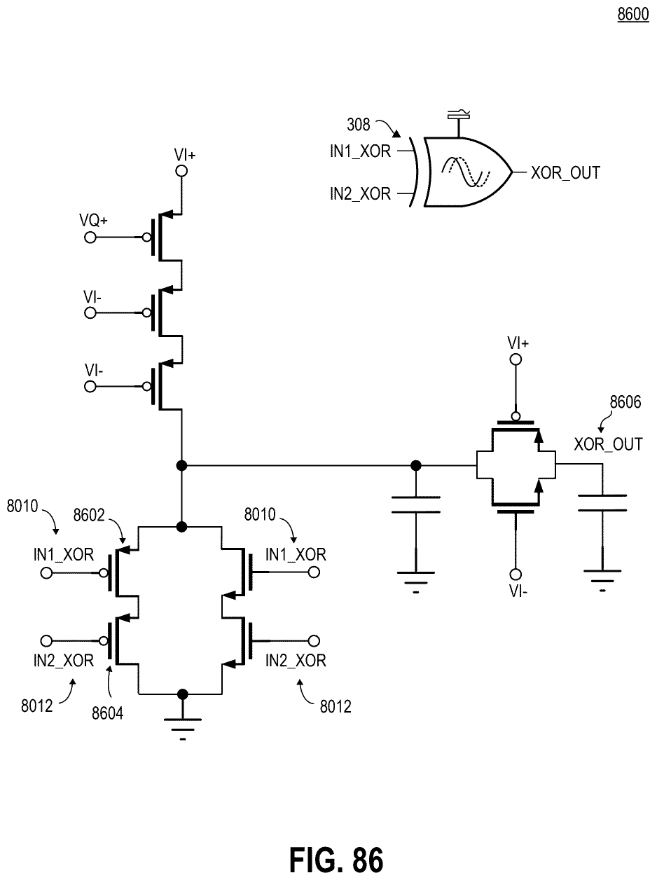

FIG. 86 is a circuit of an example circuit 8600 of a quadrature RF XOR gate 8600, wherein XOR logic may be implemented using signals IN1_XOR and IN2_XOR, in accordance with at least one example. XOR gate 8600 illustrates an example circuit for XOR gate 308. Circuit 8600 may take two input signals IN1_XOR 8010 and IN2_XOR 8012 as well as their complementary signals IN1_XOR′ 8014 and IN2_XOR′ 8016 for its correct operation. Two inverters are not shown in this example to avoid clutter. This approach may be desirable and may be used in a standard DC powered XOR circuit due to its low static losses because both NMOS and PMOS transistors may provide minimum resistance in their respective branches. However, in the case of AC-powered powered XOR circuit, especially when it needs to be operated in a sub-threshold region, this feature might not be useful as none of transistors are expected to be providing a minimum resistance. This phenomenon may be leveraged to replace NMOS transistors 8002 and 8004 with inverted signals IN1 XOR′ 8014 and IN2_XOR′ 8016 in a NMOS discharging branch with their PMOS counterparts 8602 and 8604, thus using input signals IN1_XOR 8010 and IN2_XOR 8012. This might save two inverters that may otherwise are needed in the previous example 8000 of FIG. 80.

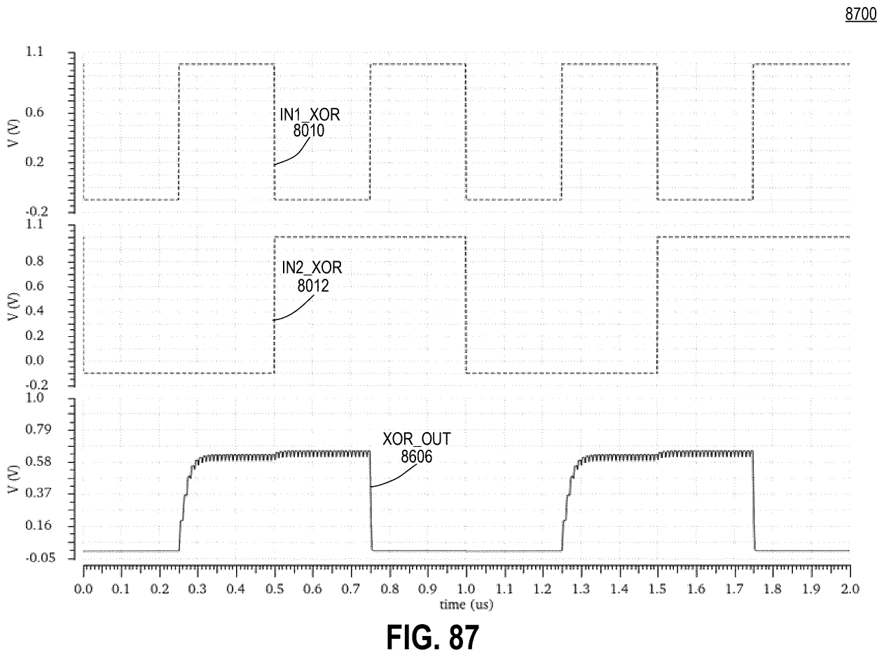

FIG. 87 is a plot 8700 of an output XOR_OUT 8606 when two input signals IN1_XOR 8010 and IN2_XOR 8012 are applied as inputs to quadrature RF XOR gate 8600 of FIG. 86, in accordance with at least one example.

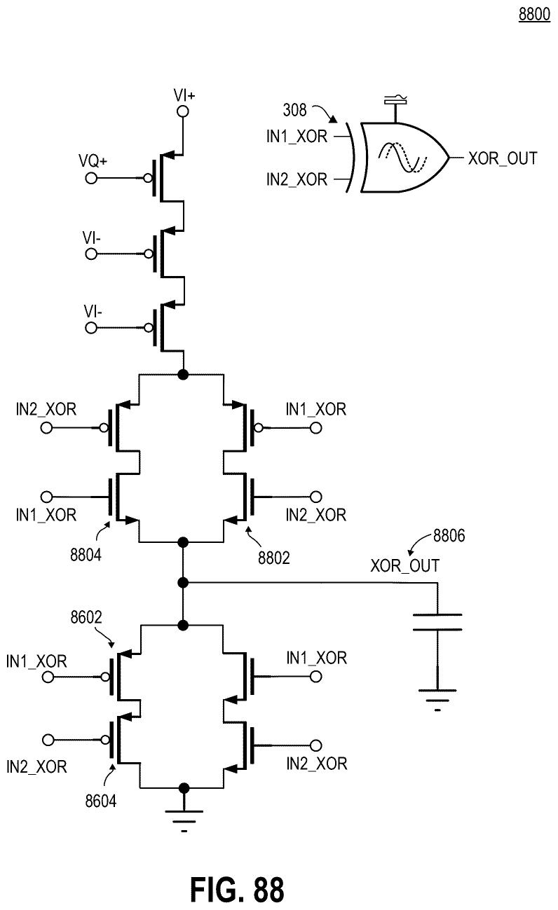

FIG. 88 is a circuit of an example circuit of a quadrature RF XOR gate 8800, wherein XOR logic may be implemented using signals IN1_XOR and IN2_XOR, in accordance with at least one example. AC XOR gate 8800 illustrates an example circuit 8800 for XOR gate 308. Here NMOS transistors 8002 and 8004 in a discharging branch are replaced with PMOS transistors 8602 and 8604; and PMOS transistors 8204 and 8206 in a charging branch are replaced with NMOS transistors 8802 and 8804; thereby, eliminating a need to invert input signals. The output of RF XOR gate 8800 is XOR_OUT 8806.

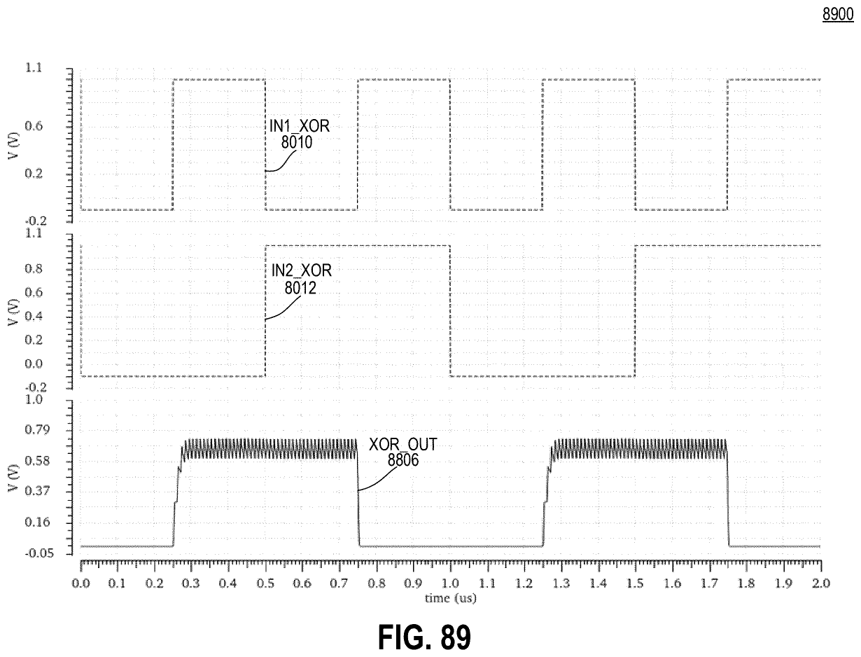

FIG. 89 is a plot 8900 of an output XOR_OUT 8806 when two input signals IN1_XOR 8010 and IN2_XOR 8012 are applied at inputs of quadrature RF XOR gate 8800 of FIG. 88, in accordance with at least one example.

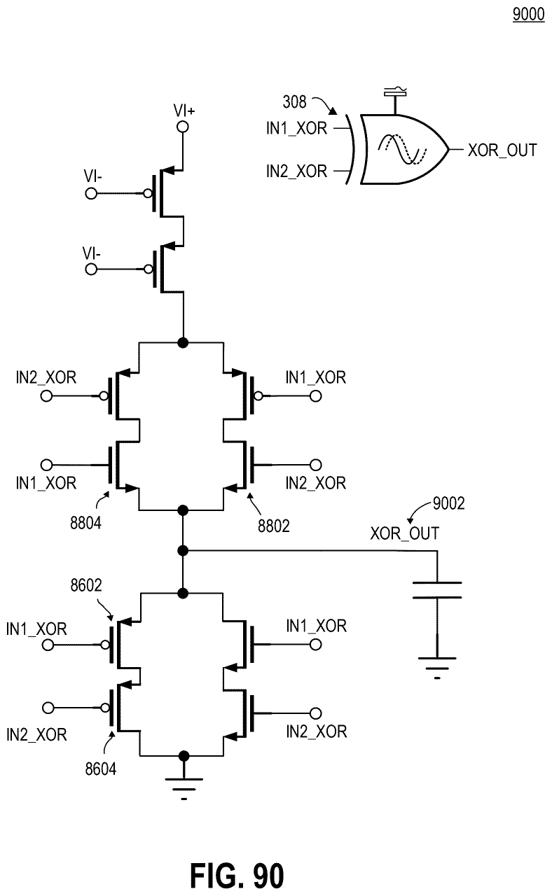

FIG. 90 is a circuit of an example structure of a 180° out of phase AC-powered RF XOR gate 9000, in accordance with at least one example. XOR gate 9000 illustrates an example circuit for XOR gate 308. In circuit 9000, NMOS transistors 8002 and 8004 in a discharging branch are replaced with PMOS transistors 8602 and 8604, and PMOS transistors 8204 and 8206 in a charging branch are replaced with NMOS transistors 8802 and 8804; thereby, eliminating a need for inverting input signals. Circuit 9000 operates in two phases, a pre-charge phase 296 and an evaluate phase 298, using two 180° out of phase signals VI+ 134 and VI− 136. In at least one example, VQ+ 146 and VQ− 148 may be used instead of VI+ 134 and VI− 136, since VQ+ 146 and VQ− 148 are also 180° out of phase of each other. The output of RF XOR gate 9000 is XOR_OUT 9002.

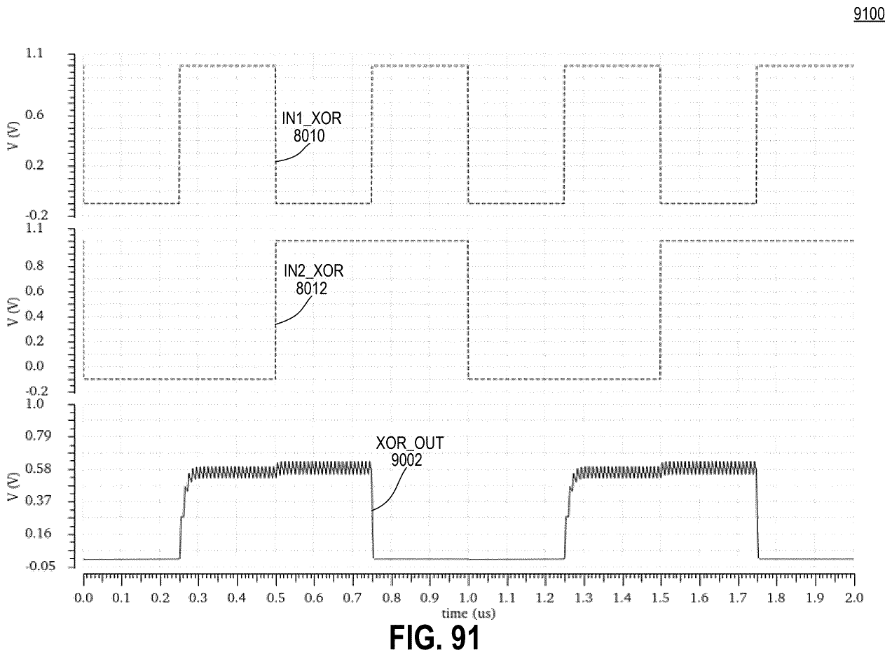

FIG. 91 is a plot 9100 of an output XOR_OUT 9002 when two input signals IN1_XOR 8010 and IN2_XOR 8012 are applied at inputs of 180° AC-powered RF XOR gate 9000 of FIG. 90, in accordance with at least one example.

In at least one example, AC-powered NAND 5900, AC-powered NOR 6000, and AC-powered XOR 6100 of FIG. 59, FIG. 60, and FIG. 61, respectively, may represent one example circuit of AC-powered logic gates that may be used in an AC-powered nano-processor. Other examples of AC-powered logic gates may also be used to design and manufacture an AC-powered nano-processor 182.

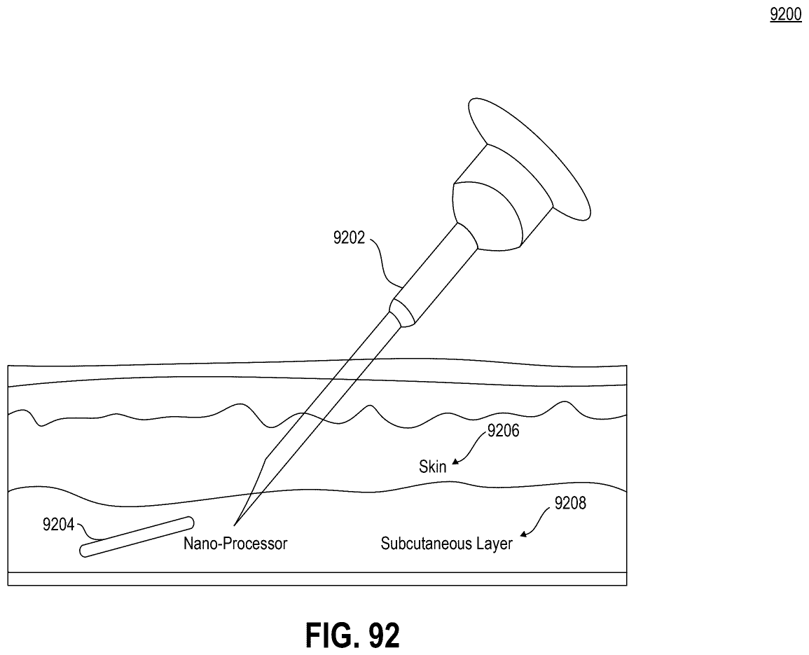

FIG. 92 illustrates an application 9200 of an AC-powered nano-processor 182 in biomedical applications, in accordance with at least one example. A notable application of a nano-processor is its use in smart dust applications due to its compact size and ultra-low power requirements. Smart dust refers to networks of nano-sized structures, or motes, capable of assembling, aligning, sensing, and reporting on their local environment. These motes are lightweight and can be deployed in narrow spaces and may be powered wirelessly. A programmable microchip may allow for a cost-effective and time-efficient reuse. In urban infrastructure, an ultra-low power nano-processor can monitor megaprojects, while in agriculture, it may assess soil and plant health. In healthcare, a nano-processor may enable real-time monitoring of vital signs such as oxygen levels, heart rate, and blood sugar. Furthermore, in transport and blockchain sectors, a nano-processor may facilitate real-time monitoring of goods, including vaccines. Since a nano-processor may operate on AC signals through a wireless power transfer (WPT) and backscattering link, it might eliminate a need for physical packaging and pins, significantly reducing space and design complexity of an AC nano-processor 182. Conventional microchips often use extensive packaging, which can introduce parasitic inductances and capacitances that may degrade signal integrity. By employing a combination of two transistors, a disclosed AC-powered nano-processor may avoid a need for high-power, inefficient rectifier circuits that are typically used for AC to DC conversion in wireless IoT or Smart dust nodes.

An AC-powered nano-processor 182 may also enable real-time in-vivo monitoring in the field of medicine. It may be integrated with various sensors for doing different tasks like blood glucose monitoring and heart rate measurement. When linked to a feedback control system, a nano-processor may autonomously perform actions without human intervention. For example, a blood sugar monitoring system may trigger an external system to administer insulin when glucose levels drop below a threshold. This capability may save lives by enabling timely medical interventions. As shown in FIG. 92, an AC-powered nano-processor 9204 may act as a processing element in small, low-power biomedical implants. Due to its small size, AC-powered nano-processor 9204 may be implanted in a human body under skin 9206 using an injector 9202 via a minimally invasive method. A small sized implant may ensure effective operation within a subcutaneous layer 9208 over extended periods without inducing a Foreign Body Reaction (FBR). Its low power consumption may maintain a Specific Absorption Rate (SAR) below specified limits, enabling it to monitor various human body physiological parameters using different sensors and transmit sense values to external monitoring systems.

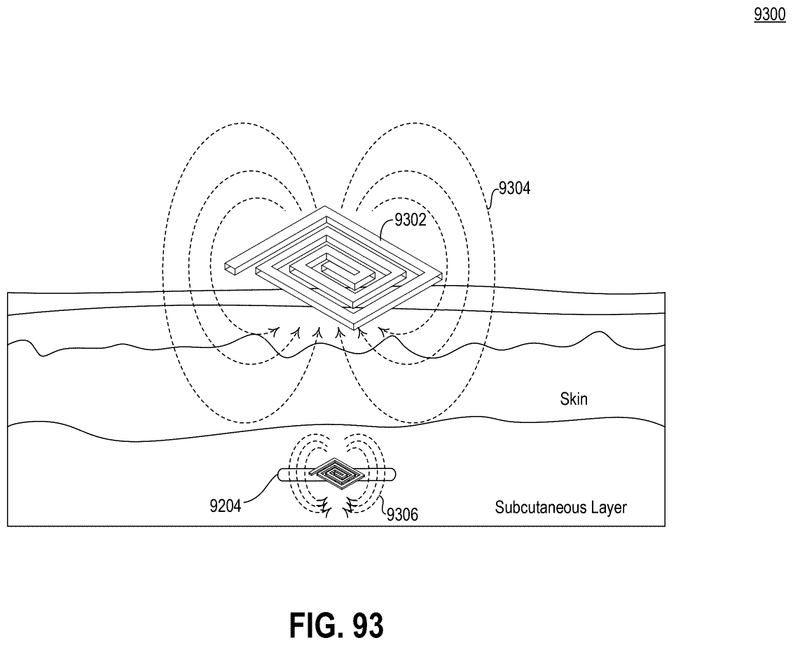

FIG. 93 is a schematic 9300 that illustrates a wireless power transfer link between a transmitter and a receiver for biomedical applications, in accordance with at least one example. Field lines 9304 from transmitter 9302 may interact with field lines 9306 of AC-powered nano-processor 9204, inducing voltage in a receiver, and activating a nano-processor along with an implant.

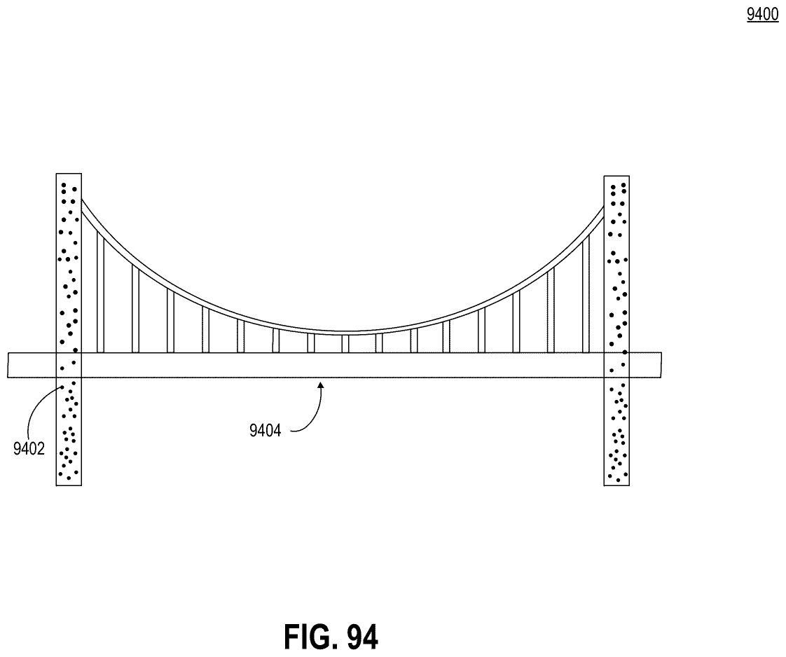

FIG. 94 is an application 9400 of the AC-powered nano-processor in a civil construction industry, in accordance with at least one example. Civil engineering projects such as bridges, skyscrapers, and dams have specific loading limits that must not be exceeded to maintain their structural integrity. Natural events like earthquakes and flooding, or excessive loading, can lead to cracks that, if not addressed, may cause permanent damage or a catastrophic failure. An AC nano-processor 182 combined with AC pressure sensors may be included in microchips 9402 within a bridge 9404. Various small and cost-effective microchips may be embedded within a concrete mixture of structures. A server may collect real-time loading data from multiple pressure sensors, allowing for preventive measures if loads exceed specified limits. These sensors may map near-continuous loading profiles, aiding in identifying fault lines in structures. Similarly, nano-processor-based AC sensor microchips may be integrated into aircraft wings and fuselage structures to monitor real-time pressure profiles during wind tunnel tests.

Throughout specification, and in claims, “connected” may generally refer to a direct connection, such as electrical, mechanical, or magnetic connection between things that are connected, without any intermediary devices.

Here, “coupled” may generally refer to a direct or indirect connection, such as a direct electrical, mechanical, or magnetic connection between things that are connected or an indirect connection, through one or more passive or active intermediary devices.

Here, “signal” may generally refer to at least one current signal, voltage signal, magnetic signal, or data/clock signal. Here, meaning of “a,” “an,” and “the” include plural references. Here, the meaning of “in” includes “in” and “on”.

Here, “resonance coupled” may generally refer to a condition or mechanism in which energy is transferred between two or more elements, structures, or systems through a resonant interaction, such as inductive, capacitive, or other resonance-based coupling methods. Resonance coupled may refer to a coupling of two systems through inductive-capacitive resonant circuits.

Here, “AC power” may generally refer to power that may alternate usually in a sinusoidal manner. In at least one example, AC power may refer to a power that may be transferred using AC signals from an IQ power supply.

Here, “multiphase” may generally refer to using multiple phases in alternating current (AC) power supply to distribute power effectively across a nano-processor. In at least one example, “multiphase” may refer to an approach that allows for better performance and stability, especially in high-frequency and low-power applications that use nano-processors.

Here, “IoT and smart dust systems” may generally refer to an integration of tiny, wireless sensors (smart dust) within the Internet of Things (IoT) network. In at least one example, IoT and smart dust systems may refer to various sensors that are very small and can detect ambient environmental factors like temperature, light, and chemicals, and transmit sensors' data to a low-power central system.

Here, “RF signals” may generally refer to Radio Frequency signals, which are electromagnetic waves operating in the frequency range of 3 kHz to 300 GHz and are essential for transmitting data wirelessly. In at least one example, RF signals may refer to signals that enable devices to send and receive information over long distances without the need for physical connections.

Here, “logic circuits” may generally refer to electrical circuits that perform logical operations on one or more binary inputs to produce a single binary output. In at least one example, the logic circuit comprises circuits that form a foundation of digital systems, utilizing basic logic gates like NAND, NOR, and XOR to build complex circuits.

Here, “DC power” may generally refer to direct current power, which is a flow of electric charge in a single direction. In at least one example, DC power includes a source that maintains a constant flow, making it ideal for devices like batteries, solar panels, and electronic circuits.

Here, “diode-based rectifiers” may generally refer to electronic components designed to convert alternating current (AC) to direct current (DC), utilizing diodes as the primary active elements. In at least one example, diode-based rectifiers may be used in energy harvesting systems to convert radio frequency (RF) signals into a usable DC power. In at least one example, diode-base rectifiers may be eliminated from a data path due to their inefficiency at low voltage levels, allowing sensors, processors, and associated circuitry to operate directly on AC/RF signals that are directly harvested from the ambient environment.

Here, “impedance” may generally refer to the total resistance offered by a circuit or electronic component to a flow of alternating current (AC), encompassing both resistance and reactance. In at least one example, impedance may refer to an opposition encountered when trying to convert low-voltage radio frequency (RF) signals.

Here, “quadrature phase signals” may generally refer to a pair of sinusoidal waveforms that are out of phase with one another by 90 degrees (π/2 radians). In at least one example, quadrature phase signals may refer to various AC waveforms captured by inductors and utilized to power and control critical components within a nano-processor architecture.

Here, “multiplexer” may generally refer to an electronic device or integrated circuit that selects one of several input signals and forwards a selected input to a single output line. In at least one example, a multiplexer may refer to a component within an AC-powered nano-processor architecture that facilitates signal selection and routing using AC logic powered by quadrature phase signals.

Here, “demultiplexer” may generally refer to an electronic circuit that takes a single input signal and distributes it to multiple output lines. In at least one example, a demultiplexer may refer to a component that works alongside multiplexers to ensure efficient routing of signals to their destination components in an AC-powered nano-processor.

Here, “ring oscillator” may generally refer to a type of digital circuit comprising an odd number of NOT gates connected in a loop generating a periodic square wave signal by repeatedly inverting the input signal through a chain of gates. In at least one example, a ring oscillator may include a timing generation component that utilizes AC logic and quadrature phase signals to create stable clock frequencies for an AC-powered nano-processor.

Here, “routing” may generally refer to the process of directing or guiding something along a certain path. In at least one example, routing may refer to a mechanism by which signals are directed to components in a nano-processor by using multiplexers and demultiplexers that operate on AC logic.

Here, “clock generation” may generally refer to a process of producing a regular series of pulses or cycles to synchronize operations in digital systems. In at least one example, clock generation may refer to the creation of stable clock frequencies using ring oscillators that operate on AC logic and quadrature phase signals.

Here, “synchronized” may generally refer to a state of being coordinated or timed to occur simultaneously. In at least one example, synchronized may refer to an operation of various components of a nano-processor, such as multiplexers, demultiplexers, and ring oscillators, working in at the rising or falling edge of a clock signal.

Here, “AC-powered memory system” may generally refer to a memory system that uses alternating current (AC) for its operation. In at least one example, an AC-powered memory system may include a memory subsystem designed to operate using AC logic, which minimizes energy consumption.

Here, “data memory” may generally refer to a portion of processor memory to store data temporarily during program execution. In at least one example, data memory may include a component of an AC-powered memory system that stores temporary data for executing arithmetic and logic operations.

Here, “static random-access memory (SRAM) cells” may generally refer to a type of semiconductor memory cell that retains its data if power is supplied to it, and more particularly refer to a basic building block of an AC memory system, designed to efficiently store and retrieve data using AC logic gates.

Here, “memory circuits” may generally refer to electronic components designed to store and retrieve information in digital systems. In at least one example, memory circuits include a specific implementation of SRAM cells within an AC-powered memory system.

Here, “branching” may generally refer to a process of changing the flow of control in a program, typically based on certain conditions being met. In at least one example, branching refers to a mechanism implemented by the control unit to manage conditional jumps in an instruction set.

Here, “data loading” may generally refer to a process of transferring data into a memory or storage device. In at least one example, data loading may refer to a mechanism implemented by memory circuits to transfer data into SRAM cells.

Here, “computational reliability” may generally refer to a consistency and accuracy of computational results produced by a processor. In at least one example, computational reliability refers to the ability of an AC-powered nano-processor to consistently produce accurate results while operating with a low power.

Here, “miniaturization” or “scaling” may generally refer to a process of making something smaller in size or scale. In at least one example, miniaturization may refer to a reduction in physical dimensions of a nano-processor and its constituent components, building ultra-small devices that are suitable for implantation in living organisms or integration into compact sensing systems.

Here, “biomedical implants” may generally refer to medical devices implanted inside a biological body to diagnose, monitor, or treat medical conditions. In at least one example, biomedical implants may include tiny electronic devices designed for insertion into a human body to perform specific functions.

Here, “resonant wireless power transfer (RWPT) receiver” may generally refer to a device capable of receiving electrical energy wirelessly through resonant coupling between transmitter and receiver coils. In at least one example, RWPT receiver may include a component that captures quadrature RF signals transmitted via wireless power transfer and backscattering links.

Here, “clock generator circuit” may generally refer to an electronic circuit designed to produce a stable clock signal used for timing operations in digital systems. In at least one example, a clock generator circuit includes a component responsible for generating timing signals essential for synchronized operation across AC-powered nano-processor and other elements of the edge node.

Here, “wake-up circuit” may generally refer to an electronic circuit designed to activate a device from a low-power or sleep state when a specific condition is met. In at least one example, a wake-up circuit comprises a power-efficient mechanism that triggers an activation of a nano-processor and associated components when certain conditions are met.

Here, “edge node” may generally refer to a device located at an edge of a network, typically used for sensing, processing, and transmitting data in real-time applications. In at least one example, an edge node includes a tiny, autonomous sensor device that collects environmental data and communicates wirelessly as part of a distributed network.

Here, “AC logic” may generally refer to a method of performing logical operations using alternating current (AC) signals. In at least one example, the AC logic includes a digital circuit where computations are performed directly on AC signals without a need to convert them to DC.

Here, “AC-powered nano-processor” may generally refer to a processor that operates directly on alternating current signals without a need to convert to direct current. In at least one example, an AC-powered nano-processor may include a central processing unit (CPU) of an edge node that processes sensor data and manages communications using AC logic.

Here, “sensor hub” may generally refer to a centralized component that integrates and manages data from multiple sensors in a system. In at least one example, the sensor hub includes a module comprising one or more sensors that gather environmental or physical data.

Here, “backscattering links” may generally refer to communication channels that utilize reflected radio frequency signals to transmit data. In at least one example, backscattering links comprise a mechanism used for transmitting processed sensor data from the edge node to external systems.

Here, “wireless power transfer” may generally refer to a technology that transmits electrical energy from a power source to a device without using wires or cables, typically utilizing electromagnetic fields. In at least one example, wireless power transfer may refer to a method used to supply energy wirelessly to ultra-low power devices.

Here, “IQ generator” may generally refer to an electronic circuit or device that produces in-phase (I) and quadrature-phase (Q) signals, typically used in modulators and demodulators for radio frequency (RF) communication systems. In at least one example, an IQ generator includes a circuit component within an external circuit that drives both wireless power transfer (WPT) and backscattering links.

Here, “on-chip” may generally refer to components or functionalities that are integrated onto a single semiconductor substrate or microchip. In at least one example, an on-chip includes multiple functional units or components within a single integrated circuit (IC).

Here, “humidity sensor” may generally refer to a device that measures amount of moisture in air. In at least one example, a humidity sensor includes a component that quantifies the relative humidity (RH) in an ambient environment.

Here, “temperature sensor” may generally refer to a device that measures thermal energy levels. In at least one example, a temperature sensor includes a component powered by resonant wireless power transfer.

Here, “pressure sensor” may generally refer to a device that detects changes in pressure applied to a liquid or gas. In at least one example, a pressure sensor includes a component powered by resonant wireless power transfer.

Here, “AND”, “NAND”, “NOR”, “NOT”, “OR”, and “XOR” may generally refer to logic gates that perform their specific logic operations, such as gates or circuits that are powered using AC signals to perform their specific logic operations.

Here, terms “substantially,” “close,” “approximately,” “near,” and “about,” generally refer to being within +/−10% of a target value. For example, unless otherwise specified in explicit context of their use, terms “substantially equal,” “about equal,” and “approximately equal” mean that there is no more than incidental variation between among things so described. In at least one embodiment, such variation is typically no more than +/−10% of a predetermined target value.

Unless otherwise specified use of ordinal adjectives “first,” “second,” and “third,” etc., to describe a common object, merely indicate that different instances of like objects are being referred to and are not intended to imply that objects so described must be in a given sequence, either temporally, spatially, in ranking or in any other manner.

Here, “left,” “right,” “front,” “back,” “top,” “bottom,” “over,” “under,” and the like in description and in claims, if any, are used for descriptive purposes and not necessarily for describing permanent relative positions. In at least one embodiment, “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. In at least one embodiment, these terms are employed herein for descriptive purposes and predominantly within context of a device z-axis and therefore may be relative to an orientation of a device. In at least one embodiment, a first material “over” a second material in context of a figure provided herein may also be “under” second material if device is oriented upside-down relative to context of figure provided. In context of materials, one material disposed over or under another may be directly in contact or may have one or more intervening materials. Moreover, one material disposed between two materials may be directly in contact with two layers or may have one or more intervening layers. In at least one embodiment, a first material “on” a second material is in direct contact with that second material. Similar distinctions are to be made in context of component assemblies.

Here, “between” may be employed in context of z-axis, x-axis, or y-axis of a device. In at least one embodiment, a material that is between two other materials may be in contact with one or both of those materials or may be separated from both of other two materials by one or more intervening materials. In at least one embodiment, a material “between” two other materials may therefore be in contact with either of other two material, or may be coupled to other two materials through an intervening material. In at least one embodiment, a device that is between two other devices may be directly connected to one or both of those devices or may be separated from both of other two devices by one or more intervening devices.

Reference in specification to “an embodiment,” “one embodiment,” “in at least one embodiment,” “some embodiments,” or “other embodiments” means that a particular feature, structure, or characteristic described in connection with embodiments is included in at least some embodiments, but not necessarily all embodiments. Various appearances of “an embodiment,” “one embodiment,” “in at least one embodiment,” or “some embodiments” are not necessarily all referring to same embodiments. If specification states a component, feature, structure, or characteristic “may,” “might,” or “could” be included, that particular component, feature, structure, or characteristic is not required to be included. If specification or claim refers to “a” or “an” element, that does not mean there is only one of elements. If specification or claims refer to “an additional” element, that does not preclude there being more than one of additional elements.

Furthermore, particular features, structures, functions, or characteristics may be combined in any suitable manner in one or more embodiments. For example, a first embodiment may be combined with a second embodiment anywhere particular features, structures, functions, or characteristics associated with two embodiments are not mutually exclusive.

While at least one embodiment has been described in conjunction with specific embodiments thereof, many alternatives, modifications and variations of such embodiments will be apparent to those of ordinary skill in the art considering description herein. At least one embodiment is intended to embrace all such alternatives, modifications, and variations as to fall within broad scope of appended claims.

In addition, well-known power/ground connections to resonators and other components may or may not be shown within presented figures, for simplicity of illustration and discussion, and so as not to obscure any embodiment. Further, arrangements may be shown in block diagram form to avoid obscuring any embodiment, and in view of the fact that specifics with respect to implementation of such block diagram arrangements are dependent upon the platform within which an embodiment is to be implemented (e.g., such specifics should be well within purview of one skilled in art). Where specific details (e.g., dimensions) are set forth to describe example embodiments of disclosure, it should be apparent to one skilled in art that disclosure can be practiced without, or with variation of, these specific details. Description of an embodiment is thus to be regarded as illustrative instead of limiting.

In at least one embodiment, structures described herein can also be described as method(s) of forming those structures or apparatuses, and method(s) of operation of these structures or apparatuses. Following examples are provided that illustrate at least one embodiment. An example can be combined with any other example. As such, at least one example can be combined with at least another example without changing scope of an example.

Example 1 is a processor comprising: a first power supply line to receive a first quadrature phase supply signal; a second power supply line to receive a second quadrature phase supply signal; a third power supply line to receive a third quadrature phase supply signal; a fourth power supply line to receive a fourth quadrature phase supply signal, wherein the first, second, third, and fourth quadrature phase supply signals are 90 degrees out-of-phase relative to one another; and an AC powered logic circuit coupled to the first, second, third, and fourth power supply lines, wherein the AC powered logic circuit is to generate an output based on the first, second, third, and fourth quadrature phase supply signals.

Example 2 is a processor according to any examples herein, in particular example 1, wherein the first, second, third, and fourth power supply lines are coupled to an IQ power supply unit.

Example 3 is a processor according to any examples herein, in particular example 2, wherein the IQ power supply unit comprises: a first center tap inductor having a first center tap inductor terminal, a second center tap inductor terminal, and a first center tap terminal, wherein the first center tap terminal is coupled to a first ground; a first capacitor having a first capacitor terminal coupled to the first center tap inductor terminal and a second capacitor terminal coupled to the first center tap terminal, wherein the first capacitor terminal and the first center tap inductor terminal are coupled to the first power supply line; and a second capacitor having a third capacitor terminal coupled to the second center tap inductor terminal and a fourth capacitor terminal coupled to the first center tap terminal, wherein the third capacitor terminal and the second center tap inductor terminal are coupled to the second power supply line.

Example 4 is a processor according to any examples herein, in particular example 3, wherein the IQ power supply unit comprises: a second center tap inductor having a third center tap inductor terminal, a fourth center tap inductor terminal, and a second center tap terminal, wherein the second center tap terminal is coupled to a second ground; a third capacitor having a fifth capacitor terminal coupled to the third center tap inductor terminal and a sixth capacitor terminal coupled to the second center tap terminal, wherein the fifth capacitor terminal and the third center tap inductor terminal are coupled to the third power supply line; and a fourth capacitor having a seventh capacitor terminal coupled to the fourth center tap inductor terminal and an eighth capacitor terminal coupled to the second center tap terminal, wherein the seventh capacitor terminal and the fourth center tap inductor terminal are coupled to the fourth power supply line.

Example 5 is a processor according to any examples herein, in particular example 4, wherein the first and second center tap inductors are on-die inductors.

Example 6 is a processor according to any examples herein, in particular example 4, wherein the first and second center tap inductors are off-die inductors that are within a package containing the processor.

Example 7 is a processor according to any examples herein, in particular example 4, wherein the first center tap inductor is positioned at a first distance from a first resonant transmitter, and wherein the second center tap inductor is positioned at a second distance from a second resonant transmitter, wherein the first distance and the second distance are such that the first center tap inductor is resonantly coupled to the first resonant transmitter and the second center tap inductor is resonantly coupled to the second resonant transmitter.

Example 8 is a processor according to any examples herein, in particular example 1, wherein the AC powered logic circuit is configured to draw power in first, second, third, and fourth phases according to the first, second, third, and fourth quadrature phase supply signals, respectively.

Example 9 is a processor according to any examples herein, in particular example 8, wherein: the first phase is a pre-charge phase; the second phase is a first hold phase; the third phase is an evaluate phase; and the fourth phase is a second hold phase.

Example 10 is a processor according to any examples herein, in particular example 8, wherein the AC powered logic circuit includes a pull-up network comprising at least three transistors coupled in series and coupled to at least three of the first, second, third, and fourth power supply lines.

Example 11 is a processor according to any examples herein, in particular example 8, wherein the AC powered logic circuit includes a pull-up network comprising: a first transistor with p-type conductivity, wherein the first transistor has a source terminal coupled to the first power supply line, wherein first transistor has a gate terminal coupled to the second power supply line; and a second transistor with p-type conductivity and coupled in series with the first transistor, wherein the second transistor is controllable by the third power supply line; and a third transistor with p-type conductivity and coupled is series with the second transistor, wherein the third transistor is controllable by the third power supply line or the fourth power supply line.

Example 12 is a processor according to any examples herein, in particular example 11, wherein the AC powered logic circuit includes a logic gate having a power supply terminal coupled to a drain terminal of the third transistor.

Example 13 is a processor according to any examples herein, in particular example 12, wherein the logic gate is a first logic gate, wherein the AC powered logic circuit includes a second logic gate having a second power supply terminal coupled to the drain terminal of the third transistor.

Example 14 is a processor according to any examples herein, in particular example 1, wherein the AC powered logic circuit includes a wake-up circuit coupled to the first, second, third, and fourth power supply lines, wherein the wake-up circuit is configured to detect power levels of the first, second, third, and fourth power supply lines relative to one or more threshold and to provide an indication representative of valid or invalid power availability to the processor.

Example 15 is a processor comprising: a first power supply line to receive a first phase supply signal; a second power supply line to receive a second phase supply signal, wherein the first and second phase supply signals are 180 degrees out-of-phase relative to one another; and an AC powered logic circuit coupled to the first and second power supply lines, wherein the AC powered logic circuit is to generate an output based on the first and second phase supply signals.

Example 16 is a processor according to any examples herein, in particular example 15, wherein the first and second power supply lines are coupled to an IQ power supply unit.

Example 17 is a processor according to any examples herein, in particular example 15, wherein the AC powered logic circuit includes a pull-up network comprising: a first transistor with p-type conductivity, wherein the first transistor has a source terminal coupled to the first power supply line, wherein the first transistor has a gate terminal coupled to the first power supply line; and a second transistor with p-type conductivity and coupled in series with the first transistor, wherein the second transistor is controllable by the second power supply line.

Example 18 is a processor according to any examples herein, in particular example 17, wherein the AC powered logic circuit includes a logic gate having a power supply terminal coupled to a drain terminal of the second transistor.

Example 19 is a processor according to any examples herein, in particular example 18, wherein the logic gate is a first logic gate, wherein the AC powered logic circuit includes a second logic gate having a second power supply terminal coupled to the drain terminal of the second transistor.

Example 20 is an apparatus comprising: an IQ power supply including: one or more pull-up networks having a plurality of quadrature phase signals, wherein a first quadrature phase signal of the plurality of quadrature phase signals is a power signal and a second quadrature phase signal of the plurality of quadrature phase signals is a gating signal; and an AC logic circuit coupled to the IQ power supply, wherein the AC logic circuit is powered by the IQ power supply.

Example 21 is an apparatus according to any examples herein, in particular example 20, wherein the quadrature phase signals include three or more of a VI+ signal, a VI− signal, a VQ+ signal, or a VQ− signal.

Example 22 is an apparatus according to any examples herein, in particular example 20, wherein the quadrature phase signals are generated by and received from a plurality of power receiving and backscattering data transferring (PRBT) circuits coupled to the IQ power supply.

Example 23 is an apparatus according to any examples herein, in particular example 20, wherein the quadrature phase signals are generated by a plurality of PRBT circuits in response to reception of a plurality of wireless IQ voltage signals received from a device external to and separate from the apparatus.

Example 24 is an apparatus according to any examples herein, in particular example 20, wherein the AC logic circuit includes an AC-powered multiplexer comprising: one or more AC inverters, wherein an individual AC inverter of the one or more AC inverters receives an individual select signal of one or more select signals; a plurality of first AC NAND gates, wherein an individual first AC NAND gate of the plurality of first AC NAND gates receives an individual input data signal of a plurality of input data signals, and wherein the individual first AC NAND gate receives an output of the individual AC inverter; and a second AC NAND gate to receive a plurality of outputs of the plurality of first AC NAND gates as input thereto.

Example 25 is an apparatus according to any examples herein, in particular example 20, wherein the AC logic circuit includes an AC-powered demultiplexer comprising: one or more AC inverters, wherein an individual AC inverter of the one or more AC inverters receives an individual select signal of one or more select signals; a plurality of AC NAND gates, wherein an individual first AC NAND gate of the plurality of AC NAND gates receives an input data signal, and wherein the individual AC NAND gate receives an output of the individual AC inverter, and wherein the input data signal gets output by the individual AC NAND gate based on the one or more select signals.

Example 26 is an apparatus according to any examples herein, in particular example 20, wherein the AC logic circuit includes an AC-powered ring oscillator comprising: an odd number of AC inverters to generate a square wave signal, wherein the square wave signal is used as a clock signal.

Example 27 is an apparatus according to any examples herein, in particular example 20, wherein the AC logic circuit includes an AC-powered program counter comprising: an AC counter; an AC adder; a plurality of branch controlling AC-powered multiplexers; and a return register.

Example 28 is an apparatus according to any examples herein, in particular example 20, wherein the AC logic circuit includes an AC-powered full adder to add a first n-bit input and a second n-bit input, the AC-powered full adder comprising: a first AC XOR gate, wherein the first AC XOR gate receives the first n-bit input and the second n-bit input; a second AC XOR gate, wherein the second AC XOR gate receives a carry in signal and an output of the first AC XOR gate, wherein an output of the second XOR gate is a sum of the first n-bit input and the second n-bit input; a first AC NAND gate, wherein the first AC NAND gate receives the first n-bit input and the second n-bit input; a second AC NAND gate, wherein the second AC NAND gate receives the carry in signal and the output of the first AC XOR gate; and an AC NOR gate, wherein the AC NOR gate receives outputs of the first AC NAND gate and the second AC NAND gate, wherein an output of the AC NOR gate is a carry out signal.

Example 29 is an apparatus according to any examples herein, in particular example 20, wherein the AC logic circuit includes an AC-powered adder/subtractor to add or subtract a first input and a second input based on an add/sub signal, the AC-powered adder/subtractor comprising: a plurality of AC XOR gates, wherein an individual AC XOR gate of the plurality of AC XOR gates receives the add/sub signal and an individual bit of a plurality of bits of the first input; and a plurality of AC adders, wherein an individual AC adder of the plurality of AC adders is to add an individual bit of a plurality of bits of the second input and an output of the individual AC XOR gate.

Example 30 is an apparatus according to any examples herein, in particular example 20, wherein the AC logic circuit includes an AC-powered branch controlling circuit used for instruction jumping, wherein the AC-powered branch controlling circuit comprises: an AC XOR circuit receiving a first input signal and a second input signal; and a compare circuit receiving an output of the AC XOR circuit and an enable signal.

Example 31 is an apparatus according to any examples herein, in particular example 20, wherein the AC logic circuit includes an AC-powered arithmetic logic unit comprising: an AC adder/subtractor to add or subtract a first input and a second input based on an add/sub signal; an AC AND circuit receiving the first input and second input; an AC OR circuit receiving the first input and second input; an AC XOR circuit receiving the first input and second input; an AC-powered multiplexer, wherein the AC-powered multiplexer selects an output of the AC adder/subtractor, the AC AND circuit, the AC OR circuit, or the AC XOR circuit based on the one or more select signals; and an AC compare circuit receiving an output of the AC-powered multiplexer and an enable signal.

Example 32 is an apparatus according to any examples herein, in particular example 20, wherein the AC logic circuit includes an AC-powered read-only memory, wherein the read-only memory is to function as an instruction memory, wherein the read-only memory includes: a transistor circuit powered by one or more quadrature phase signals of the plurality of quadrature phase signals; and a plurality of bit-line capacitors, wherein an individual bit-line capacitor of the plurality of bit-line capacitors is charged or discharged by the transistor circuit.

Example 33 is an apparatus according to any examples herein, in particular example 20, wherein the AC logic circuit includes an AC-powered data memory comprising: a transistor circuit powered by one or more quadrature phase signals of the plurality of quadrature phase signals; and an AC SRAM data cell including: a cross-coupled pair of AC SRAM inverters to hold data; and a plurality of access transistors for data read/write operations.

Example 34 is an apparatus according to any examples herein, in particular example 20, wherein the AC logic circuit includes an AC-powered register file comprising: a plurality of AC registers, wherein an individual AC register of the plurality of AC registers includes a plurality of AC flip flops; and a plurality of AC-powered multiplexers to select the individual AC register during read/write operations.

Example 35 is an apparatus according to any examples herein, in particular example 20, wherein the AC logic circuit includes an AC-powered operation selector comprising: a first AC NOR gate receiving a first input signal and a second input signal; a second AC NOR gate to output a first operation select signal, wherein the second AC NOR gate receives the second input signal and an enable signal; and a third AC NOR gate to output a second operation select signal, wherein the third AC NOR gate receives the enable signal and an output of the first AC NOR gate.

Example 36 is an apparatus according to any examples herein, in particular example 20, wherein the AC logic circuit includes an AC-powered instruction memory to store an instruction set architecture, wherein the instruction set architecture includes instructions for addition, subtraction, branching, logical AND, logical OR, logical XOR, loading a constant in a temporary register, resetting one or more registers, returning to a previously stored address after branching, shifting left and shifting right.

Example 37 is an apparatus according to any examples herein, in particular example 20, wherein the AC logic circuit includes an AC-powered control circuit to generate a plurality of control signals, wherein the AC-powered control circuit comprises: a plurality of AC inverters; a plurality of AC NAND gates; and a plurality of AC NOR gates, wherein the plurality of AC inverters, the plurality of AC NAND gates and the plurality of AC NOR gates are to generate the plurality of control signals based on a plurality of trigger signals.

Example 38 is an apparatus according to any examples herein, in particular example 20, wherein the AC logic circuit includes an AC-powered data path circuit including a plurality of components comprising: an AC-powered ring oscillator; an AC-powered register file; an AC-powered arithmetic logic unit; an AC-powered data memory; an AC-powered instruction memory; an AC-powered program counter; a first AC-powered multiplexer to select an address of a write register; a second AC-powered multiplexer to select data of the write register; a third AC-powered multiplexer to select an input of an AC-powered; and an AC-powered control circuit to generate a plurality of control signals.

Example 39 is an apparatus according to any examples herein, in particular example 38, wherein each component of the plurality of components is powered by a separate pull up network or a common pull up network within the IQ power supply.

Example 40 is an AC logic gate structured and configured to be powered by three or more AC signals, the three or more AC signals comprising three quadrature AC signals, wherein a complete cycle of the three quadrature AC signals has a plurality of phases, the AC logic gate comprising: a plurality of transistors, each of a first one or more of the plurality of transistors being structured and configured to receive one or more of the three quadrature AC signals, and each of a second one or more of the plurality of transistors being structured and configured to receive one of a number of input signals; and a capacitance coupled to the plurality of transistors, wherein the capacitance is structured and configured to be pre-charged responsive to a first one of the phases, wherein the capacitance is structured and configured to be discharged responsive to a second one of the phases, and wherein the AC logic gate is structured and configured to, responsive to the number of input signals, generate and output an output signal, wherein a state of the output signal depends on a state of each of the number of input signals.

Example 41 is an AC logic gate according to any examples herein, in particular example 40, wherein the three quadrature AC signals comprise a V1+ signal, a VI− signal, and a VQ+ signal, wherein the V1+ signal and the VI signal are 180° out of phase with respect to one another, and wherein the VI+ signal and the VQ+ signal are 90° out of phase with respect to one another.

Example 42 is an AC logic gate according to any examples herein, in particular example 40, wherein the AC logic gate comprises an inverter, wherein the number of input signals is a single input signal, wherein the state of the output signal is an inverse of the state of the single input signal.

Example 43 is an AC logic gate according to any examples herein, in particular example 42, wherein the AC logic gate comprises a first branch and a second branch connected in series, wherein the first branch includes a first number of the first one or more of the plurality of transistors and the second branch includes the second one or more of the plurality of transistors and a second number of the first one or more of the plurality of transistors, wherein the capacitance is coupled to a point in between the first branch and the second branch, and wherein the AC logic gate is structured and configured such that during the first one of the phases the first branch conducts and during the second one of the phases the second branch conducts.

Example 44 is an AC logic gate according to any examples herein, in particular example 43, wherein each of the transistors of the first branch is a PMOS transistor and each of the transistors of the second branch is an NMOS transistor.

Example 45 is an AC logic gate according to any examples herein, in particular example 43, wherein the AC logic gate comprises a sample and hold circuit coupled to the capacitance for sampling an output signal from the capacitance during the second one of the phases, wherein an output of the sample and hold circuit is the output signal.

Example 46 is an AC logic gate according to any examples herein, in particular example 42, wherein the AC logic gate comprises a first branch and a second branch connected in series, wherein the first branch includes a first number of the first one or more of the plurality of transistors and a first number of the second one or more of the plurality of transistors and the second branch includes a second number of the second one or more of the plurality of transistors, wherein the capacitance is coupled to a point in between the first branch and the second branch, wherein the AC logic gate is structured and configured such that the first branch conducts responsive to the input signal being in a high state.

Example 47 is an AC logic gate according to any examples herein, in particular example 46, wherein each of the transistors of the first branch is a PMOS transistor and each of the transistors of the second branch is an NMOS transistor.

Example 48 is an AC logic gate according to any examples herein, in particular example 40, wherein the AC logic gate comprises a NAND gate, wherein the number of input signals is a first input signal and a second input signal, wherein the state of the output signal comprises a logical NAND of the state of the first input signal and the state of the second input signal.

Example 49 is an AC logic gate according to any examples herein, in particular example 48, wherein the AC logic gate comprises a first branch and a second branch connected in series, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive the first input signal and a second transistor structured and configure to receive the second input signal, wherein the capacitance is coupled to a point in between the first branch and the second branch, and wherein the AC logic gate is structured and configured such that the first transistor and the second transistor operate as a NAND gate during the second one of the phases such that the capacitance is discharged when the first input signal and the second input signal are high.

Example 50 is an AC logic gate according to any examples herein, in particular example 49, wherein each of the transistors of the first branch is a PMOS transistor and each of the transistors of the second branch is an NMOS transistor.

Example 51 is an AC logic gate according to any examples herein, in particular example 49, wherein the AC logic gate comprises a sample and hold circuit coupled to the capacitance for sampling an output signal from the capacitance during the second one of the phases, wherein an output of the sample and hold circuit is the output signal.

Example 52 is an AC logic gate according to any examples herein, in particular example 48, wherein the AC logic gate comprises a first branch and a second branch connected in series, wherein the first branch includes a first number of the first one or more of the plurality of transistors and a first number of the second one or more of the plurality of transistors and the second branch includes a second number of the second one or more of the plurality of transistors, wherein the capacitance is coupled to a point in between the first branch and the second branch, wherein the first number of the second one or more of the plurality of transistors comprises a first transistor structured and configure to receive the first input signal and a second transistor structured and configure to receive the second input signal, and the second number of the second one or more of the plurality of transistors comprises a third transistor structured and configure to receive the first input signal and a fourth transistor structured and configure to receive the second input signal.

Example 53 is an AC logic gate according to any examples herein, in particular example 52, wherein the first transistor and the second transistor are connected in parallel to one another.

Example 54 is an AC logic gate according to any examples herein, in particular example 52, wherein each of the transistors of the first branch is a PMOS transistor and each of the transistors of the second branch is an NMOS transistor.

Example 55 is an AC logic gate according to any examples herein, in particular example 40, wherein the AC logic gate comprises a NOR gate, wherein the number of input signals is a first input signal and a second input signal, wherein the state of the output signal comprises a logical NOR of the state of the first input signal and the state of the second input signal.

Example 56 is an AC logic gate according to any examples herein, in particular example 55, wherein the AC logic gate comprises a first branch and a second branch, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive the first input signal and a second transistor structured and configure to receive the second input signal, wherein the capacitance is coupled to a point in between the first branch and the second branch, and wherein the AC logic gate is structured and configured such that the first transistor and the second transistor operate as a NOR gate during the second one of the phases such that the capacitance is discharged when at least one of the first input signal and the second input signal is high.

Example 57 is an AC logic gate according to any examples herein, in particular example 56, wherein each of the transistors of the first branch is a PMOS transistor and each of the transistors of the second branch is an NMOS transistor.

Example 58 is an AC logic gate according to any examples herein, in particular example 56, further comprising a sample and hold circuit coupled to the capacitance for sampling an output signal from the capacitance during the second one of the phases, wherein an output of the sample and hold circuit is the output signal.

Example 59 is an AC logic gate according to any examples herein, in particular example 55, wherein the AC logic gate comprises a first branch and a second branch, wherein the first branch includes a first number of the first one or more of the plurality of transistors and a first number of the second one or more of the plurality of transistors and the second branch includes a second number of the second one or more of the plurality of transistors, wherein the capacitance is coupled to a point in between the first branch and the second branch, wherein the first number of the second one or more of the plurality of transistors comprises a first transistor structured and configure to receive the first input signal and a second transistor structured and configure to receive the second input signal, and the second number of the second one or more of the plurality of transistors comprises a third transistor structured and configure to receive the first input signal and a fourth transistor structured and configure to receive the second input signal.

Example 60 is an AC logic gate according to any examples herein, in particular example 59, wherein the third transistor and the fourth transistor are connected in parallel to one another.

Example 61 is an AC logic gate according to any examples herein, in particular example 59, wherein each of the transistors of the first branch is a PMOS transistor and each of the transistors of the second branch is an NMOS transistor.

Example 62 is an AC logic gate according to any examples herein in particular example 40, wherein the AC logic gate comprises an XOR gate, wherein the number of input signals is a first input signal and a second input signal, wherein the state of the output signal comprises a logical NOR of the state of the first input signal and the state of the second input signal.

Example 63 is an AC logic gate according to any examples herein, in particular example 62, wherein the AC logic gate comprises a first branch and a second branch, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive a compliment of the first input signal, a second transistor structured and configure to receive a compliment of the second input signal, a third transistor structured and configure to receive the first input signal, a fourth transistor structured and configure to receive the second input signal, wherein the capacitance is coupled to a point in between the first branch and the second branch, wherein the first and second transistors are connected in series with each other and the third and fourth transistors are connection in series with each other, and wherein the first and second transistors are connected in parallel with the third and fourth transistors.

Example 64 is an AC logic gate according to any examples herein, in particular example 63, wherein each of the transistors of the first branch is a PMOS transistor and each of the transistors of the second branch is an NMOS transistor.

Example 65 is an AC logic gate according to any examples herein, in particular example 63, wherein the AC logic gate comprises a sample and hold circuit coupled to the capacitance for sampling an output signal from the capacitance during the second one of the phases, wherein an output of the sample and hold circuit is the output signal.

Example 66 is an AC logic gate according to any examples herein, in particular example 62, wherein the AC logic gate comprises a first branch and a second branch, wherein the first branch includes a first number of the first one or more of the plurality of transistors and a first number of the second one or more of the plurality of transistors and the second branch includes a second number of the first one or more of the plurality of transistors and a second number of the second one or more of the plurality of transistors, wherein the first number of the second one or more of the plurality of transistors includes a first transistor structured and configure to receive a compliment of the first input signal, a second transistor structured and configure to receive the second input signal, a third transistor structured and configure to receive the first input signal, a fourth transistor structured and configure to receive a compliment of the second input signal, wherein the second number of the second one or more of the plurality of transistors includes a fifth transistor structured and configure to receive a compliment of the first input signal, a sixth transistor structured and configure to receive a compliment of the second input signal, a seventh transistor structured and configure to receive the first input signal, an eighth transistor structured and configure to receive the second input signal, wherein the capacitance is coupled to a point in between the first branch and the second branch, wherein the first and second transistor are connected in series with each other and the third and fourth transistors are connection in series with each other, and wherein the first and second transistor are connected in parallel with the third and fourth transistor, and wherein the fifth and sixth transistors are connected in series with each other and the seventh and eighth transistors are connection in series with each other, and wherein the fifth and sixth transistors are connected in parallel with the seventh and eighth transistors.

Example 67 is an AC logic gate according to any examples herein, in particular example 66, wherein each of the transistors of the first branch is a PMOS transistor and each of the transistors of the second branch is an NMOS transistor.

Examples 68 is an AC logic gate according to any examples herein, in particular example 62, wherein the AC logic gate comprises a first branch and a second branch, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive the first input signal, a second transistor structured and configure to receive the second input signal, a third transistor structured and configure to receive the first input signal, a fourth transistor structured and configure to receive the second input signal, wherein the capacitance is coupled to a point in between the first branch and the second branch, wherein the first and second transistors are connected in series with each other and the third and fourth transistors are connection in series with each other, and wherein the first and second transistors are connected in parallel with the third and fourth transistors.

Example 69 is an AC logic gate according to any examples herein, in particular example 68, wherein each of the transistors of the first branch is a PMOS transistor and each of the transistors of the second branch is an NMOS transistor.

Example 70 is an AC logic gate according to any examples herein, in particular example 68, wherein the AC logic gate comprises a sample and hold circuit coupled to the capacitance for sampling an output signal from the capacitance during the second one of the phases, wherein an output of the sample and hold circuit is the output signal.

Example 71 is an AC logic gate according to any examples herein, in particular example 62, wherein the AC logic gate comprises a first branch and a second branch, wherein the first branch includes a first number of the first one or more of the plurality of transistors and a first number of the second one or more of the plurality of transistors and the second branch includes a second number of the first one or more of the plurality of transistors and a second number of the second one or more of the plurality of transistors, wherein the first number of the second one or more of the plurality of transistors includes a first transistor structured and configure to receive the second input signal, a second transistor structured and configure to receive the first input signal, a third transistor structured and configure to receive the first input signal, a fourth transistor structured and configure to receive the second input signal, wherein the second number of the second one or more of the plurality of transistors includes a fifth transistor structured and configure to receive the first input signal, a sixth transistor structured and configure to receive the second input signal, a seventh transistor structured and configure to receive the first input signal, an eighth transistor structured and configure to receive the second input signal, wherein the capacitance is coupled to a point in between the first branch and the second branch, wherein the first and second transistor are connected in series with each other and the third and fourth transistors are connection in series with each other, and wherein the first and second transistor are connected in parallel with the third and fourth transistor, and wherein the fifth and sixth transistors are connected in series with each other and the seventh and eighth transistors are connection in series with each other, and wherein the fifth and sixth transistors are connected in parallel with the seventh and eighth transistors.

Example 72 is an AC logic gate according to any examples herein, in particular example 71, wherein each of the transistors of the first branch is a PMOS transistor and each of the transistors of the second branch is an NMOS transistor.

Example 73 is a method of performing digital logic operations, comprising: receiving three quadrature AC signals in a transistor circuit of an AC logic gate to power the AC logic gate, wherein a complete cycle of the three quadrature AC signals has a plurality of phases; receiving a number of input signals in the transistor circuit; pre-charging a capacitance of the AC logic gate responsive to a first one of the phases the capacitance being coupled to the transistor circuit; discharging the capacitance responsive to a second one of the phases; and responsive to the number of input signals, generating and outputting an output signal from the AC logic gate, wherein a state of the output signal depends on a state of each of the number of input signals.

Example 74 is a method according to any examples herein, in particular example 73, wherein the three quadrature AC signals comprise a VI+ signal, a VI− signal, and a VQ+ signal, wherein the VI+ signal and the VI signal are 1800 out of phase with respect to one another, and wherein the signal and the VQ+ signal are 90° out of phase with respect to one another.

What is claimed is:

1. A processor comprising:
a first power supply line to receive a first quadrature phase supply signal;
a second power supply line to receive a second quadrature phase supply signal;
a third power supply line to receive a third quadrature phase supply signal;
a fourth power supply line to receive a fourth quadrature phase supply signal, wherein the first, second, third, and fourth quadrature phase supply signals are 90 degrees out-of-phase relative to one another; and
an AC powered logic circuit coupled to the first, second, third, and fourth power supply lines, wherein the AC powered logic circuit is to generate an output based on the first, second, third, and fourth quadrature phase supply signals.

2. The processor of claim 1, wherein the first, second, third, and fourth power supply lines are coupled to an IQ power supply unit.

3. The processor of claim 2, wherein the IQ power supply unit comprises:
a first center tap inductor having a first center tap inductor terminal, a second center tap inductor terminal, and a first center tap terminal, wherein the first center tap terminal is coupled to a first ground;
a first capacitor having a first capacitor terminal coupled to the first center tap inductor terminal and a second capacitor terminal coupled to the first center tap terminal, wherein the first capacitor terminal and the first center tap inductor terminal are coupled to the first power supply line; and
a second capacitor having a third capacitor terminal coupled to the second center tap inductor terminal and a fourth capacitor terminal coupled to the first center tap terminal, wherein the third capacitor terminal and the second center tap inductor terminal are coupled to the second power supply line.

4. The processor of claim 3, wherein the IQ power supply unit comprises:
a second center tap inductor having a third center tap inductor terminal, a fourth center tap inductor terminal, and a second center tap terminal, wherein the second center tap terminal is coupled to a second ground;
a third capacitor having a fifth capacitor terminal coupled to the third center tap inductor terminal and a sixth capacitor terminal coupled to the second center tap terminal, wherein the fifth capacitor terminal and the third center tap inductor terminal are coupled to the third power supply line; and
a fourth capacitor having a seventh capacitor terminal coupled to the fourth center tap inductor terminal and an eighth capacitor terminal coupled to the second center tap terminal, wherein the seventh capacitor terminal and the fourth center tap inductor terminal are coupled to the fourth power supply line.

5. The processor of claim 4, wherein the first and second center tap inductors are on-die inductors.

6. The processor of claim 4, wherein the first and second center tap inductors are off-die inductors that are within a package containing the processor.

7. The processor of claim 4, wherein the first center tap inductor is positioned at a first distance from a first resonant transmitter, and wherein the second center tap inductor is positioned at a second distance from a second resonant transmitter, wherein the first distance and the second distance are such that the first center tap inductor is resonantly coupled to the first resonant transmitter and the second center tap inductor is resonantly coupled to the second resonant transmitter.

8. The processor of claim 1, wherein the AC powered logic circuit is configured to draw power in first, second, third, and fourth phases according to the first, second, third, and fourth quadrature phase supply signals, respectively.

9. The processor of claim 8, wherein:
the first phase is a pre-charge phase;
the second phase is a first hold phase;
the third phase is an evaluate phase; and
the fourth phase is a second hold phase.

10. The processor of claim 8, wherein the AC powered logic circuit includes a pull-up network comprising at least three transistors coupled in series and coupled to at least three of the first, second, third, and fourth power supply lines.

11. The processor of claim 8, wherein the AC powered logic circuit includes a pull-up network comprising:
a first transistor with p-type conductivity, wherein the first transistor has a source terminal coupled to the first power supply line, wherein the first transistor has a gate terminal coupled to the second power supply line;
a second transistor with p-type conductivity and coupled in series with the first transistor, wherein the second transistor is controllable by the third power supply line; and
a third transistor with p-type conductivity and coupled is series with the second transistor, wherein the third transistor is controllable by the third power supply line or the fourth power supply line.

12. The processor of claim 11, wherein the AC powered logic circuit includes a logic gate having a power supply terminal coupled to a drain terminal of the third transistor.

13. The processor of claim 12, wherein the logic gate is a first logic gate, wherein the AC powered logic circuit includes a second logic gate having a second power supply terminal coupled to the drain terminal of the third transistor.

14. The processor of claim 1, wherein the AC powered logic circuit includes a wake-up circuit coupled to the first, second, third, and fourth power supply lines, wherein the wake-up circuit is configured to detect power levels of the first, second, third, and fourth power supply lines relative to one or more threshold and to provide an indication representative of valid or invalid power availability to the processor.

15. A processor comprising:
a first power supply line to receive a first phase supply signal;
a second power supply line to receive a second phase supply signal, wherein the first and second phase supply signals are 180 degrees out-of-phase relative to one another; and
an AC powered logic circuit coupled to the first and second power supply lines, wherein the AC powered logic circuit is to generate an output based on the first and second phase supply signals.

16. The processor of claim 15, wherein the first and second power supply lines are coupled to an IQ power supply unit.

17. The processor of claim 15, wherein the AC powered logic circuit includes a pull-up network comprising:
a first transistor with p-type conductivity, wherein the first transistor has a source terminal coupled to the first power supply line, wherein the first transistor has a gate terminal coupled to the first power supply line; and
a second transistor with p-type conductivity and coupled in series with the first transistor, wherein the second transistor is controllable by the second power supply line.

18. The processor of claim 17, wherein the AC powered logic circuit includes a logic gate having a power supply terminal coupled to a drain terminal of the second transistor.

19. The processor of claim 18, wherein the logic gate is a first logic gate, wherein the AC powered logic circuit includes a second logic gate having a second power supply terminal coupled to the drain terminal of the second transistor.

20. An apparatus comprising:
an IQ power supply including:
one or more pull-up networks having a plurality of quadrature phase signals, wherein a first quadrature phase signal of the plurality of quadrature phase signals is a power signal and a second quadrature phase signal of the plurality of quadrature phase signals is a gating signal; and
an AC logic circuit coupled to the IQ power supply, wherein the AC logic circuit is powered by the IQ power supply.
